(19) United States
(12) Patent Application Publication
(10) Pub. No.: US 2024/0317787 A1
(43) Pub. Date: Sep. 26, 2024

(54) ORGANIC ELECTROLUMINESCENT DEVICE

(71) Applicant: BEIJING SUMMER SPROUT TECHNOLOGY CO., LTD., Beijing (CN)

(72) Inventors: Liuhuan Cai, Beijing (CN); Chunliang Zhao, Beijing (CN); Ming Sang, Beijing (CN); Xuechao Tian, Beijing (CN); Zhihao Cui, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/610,691

(22) Filed: Mar. 20, 2024

(30) Foreign Application Priority Data
Mar. 24, 2023 (CN) 202310299352.0

(51) Int. Cl. C07F 15/00; C09K 11/06; H10K 50/11; H10K 85/30

(52) U.S. Cl. CPC C07F 15/0086; C07F 15/006; C09K 11/06; H10K 50/11; H10K 85/346; C09K 2211/185

(57) ABSTRACT

Provided is an organic electroluminescent device. The organic electroluminescent device includes an anode, a cathode and a first organic layer and a second organic layer disposed between the anode and the cathode, where the first organic layer comprises a first compound having a structure of Formula 1, and the second organic layer comprises a second compound having a structure of Formula 3. The electroluminescent device exhibits excellent device performance, for example, higher efficiency and an extremely narrow full width at half maximum. Further provided is a display assembly comprising the organic electroluminescent device.

### CROSS-REFERENCE TO RELATED APPLICATION(S)

This application claims priority to Chinese Patent Application No. 202310299352.0 filed on Mar. 24, 2023, the disclosure of which is incorporated herein by reference in its entirety.

### TECHNICAL FIELD

The present disclosure relates to organic electronic devices, for example, organic electroluminescent devices. In particular, the present disclosure relates to an organic electroluminescent device comprising a first compound having a structure represented by Formula 1 in a first organic layer and a second compound having a structure represented by

Formula 3 in a second organic layer and a display assembly comprising the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting

mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN115472756A discloses an electroluminescent device comprising a first organic layer and a second organic layer, wherein a general structure formula of the compound in the first organic layer comprises

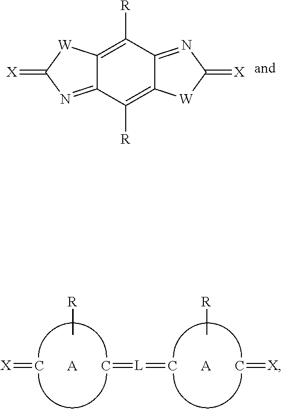

and a general structure formula of the compound in the second organic layer comprises

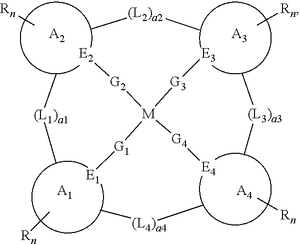

wherein Rₙ represents mono-substitution, multiple substitutions or non-substitution, and the ring A₁ to the ring A₄ are aromatic rings or heteroaromatic rings. Although this application discloses

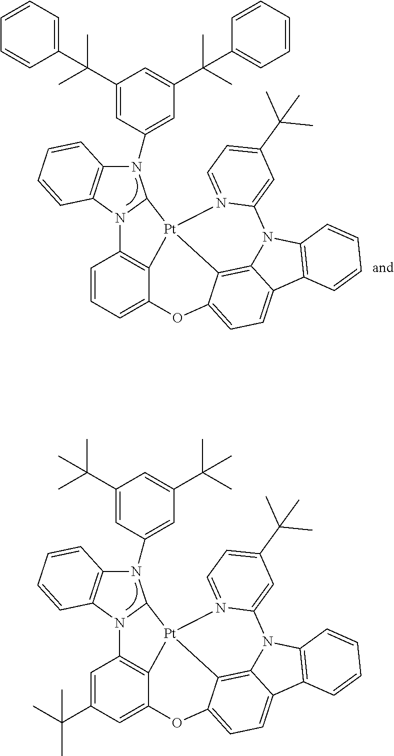

in the specific structures and selects

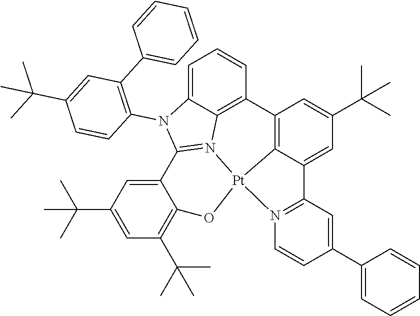

as a green light-emitting material in a device example, this application has not disclosed a metal complex having a structure of a particular multi-substituted aromatic group at an N position of imidazole and has neither disclosed nor taught that device performance can be improved when the metal complex having the structure of the particular multi-substituted aromatic group at the N position of imidazole and a particular p-type doping material are used in combination.

At present, the performance of a blue phosphorescent device still needs to be improved, for example, relatively high quantum efficiency and a relatively narrow full width at half maximum. After intensive research, the inventors of the present disclosure have discovered a new material combination. Using a metal complex having a particular multi-substituted aromatic group at a particular N position of imidazole and a p-type doping material having a particular structure in combination in a blue phosphorescent device can unexpectedly obtain more excellent device performance.

### SUMMARY

The present disclosure aims to provide a new organic electroluminescent device to solve at least part of the above-mentioned problems. The new organic electroluminescent device comprises an anode, a cathode and a first organic layer and a second organic layer disposed between the anode and the cathode, wherein the first organic layer comprises a first compound having a structure represented by Formula 1, and the second organic layer comprises a second compound having a structure represented by Formula 3. This new organic electroluminescent device has an extremely narrow full width at half maximum, higher external quantum efficiency and better device performance.

According to an embodiment of the present disclosure, disclosed is an organic electroluminescent device, the organic electroluminescent device comprises:
an anode,
a cathode, and
a first organic layer and a second organic layer disposed between the anode and the cathode;
wherein the first organic layer comprises a first compound, wherein the first compound has a structure represented by Formula 1:

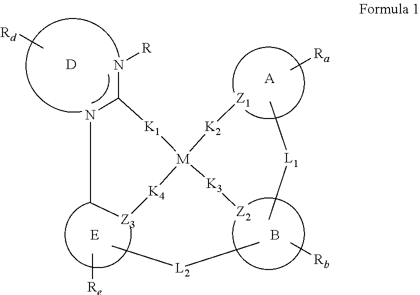

wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 1 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof;
y is 1, 2, 3, 4 or 5;
K₁ to K₄ are, at each occurrence identically or differently, selected from a single bond, O or S;
Z₁ to Z₃ are, at each occurrence identically or differently, selected from C or N;
R in Formula 1 has a structure represented by Formula 2:

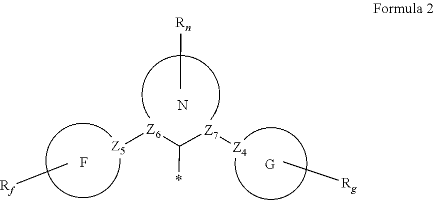

wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof;
Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined; and
adjacent substituents R″, Rₐ, R_{b}, R_{d}, Rₑ, R_{f}, R_{g} and Rₙ can be optionally joined to form a ring;
wherein the second organic layer comprises a second compound, wherein the second compound has a structure represented by Formula 3:

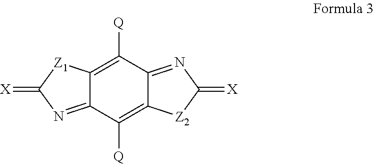

wherein in Formula 3,
X and Y are, at each occurrence identically or differently, selected from NQ′, CQ″Q′″, O, S or Se;
Z₁ and Z₂ are, at each occurrence identically or differently, selected from O, S or Se;
Q, Q′, Q″ and Q′″ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof;
at least one of Q, Q′, Q″ and Q′″ is a group having at least one electron withdrawing group; and
adjacent substituents Q″ and Q′″ can be optionally joined to form a ring.

According to another embodiment of the present disclosure, further disclosed is a display assembly, the display assembly comprises the organic electroluminescent device described above.

The new organic electroluminescent device disclosed in the present disclosure comprises the anode, the cathode and the first organic layer and the second organic layer disposed between the anode and the cathode, wherein the first organic layer comprises the first compound having the structure represented by Formula 1, and the second organic layer comprises the second compound having the structure represented by Formula 3. This new organic electroluminescent device has an extremely narrow full width at half maximum, higher external quantum efficiency and better device performance.

### BRIEF DESCRIPTION OF DRAWINGS

FIG. 1 is a schematic diagram of an organic light-emitting apparatus that may comprise an organic electroluminescent device disclosed herein.

FIG. 2 is a schematic diagram of another organic light-emitting apparatus that may comprise an organic electroluminescent device disclosed herein.

### DETAILED DESCRIPTION

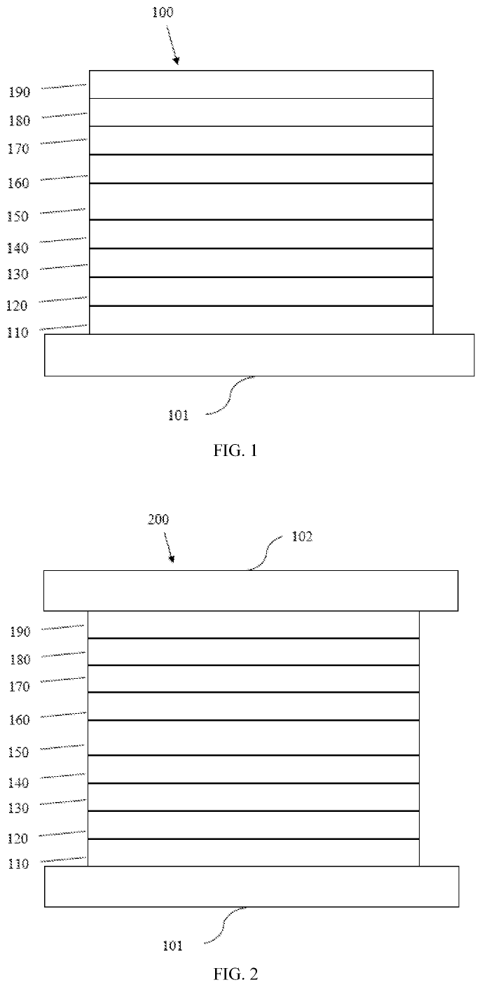

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino-or carbazole-derivatives and an electron acceptor moiety such as N-containing six-membered aromatic rings.

### Definition of Terms of Substituents

Halogen or halide−as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, tripropylgermanyl, tributylgermanyl, methyldiethylgermanyl, ethyldimethylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

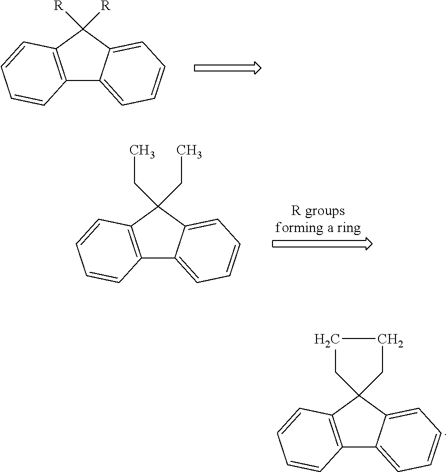

The expression that adjacent substituents can be optionally joined to form a ring is also intended to mean that two substituents bonded to carbon atoms which are directly bonded to each other are joined to each other via a chemical bond to form a ring, which can be exemplified by the following formula:

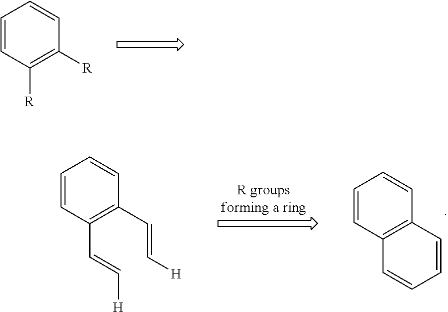

The expression that adjacent substituents can be optionally joined to form a ring is also intended to mean that two substituents bonded to further distant carbon atoms are joined to each other via a chemical bond to form a ring, which can be exemplified by the following formula:

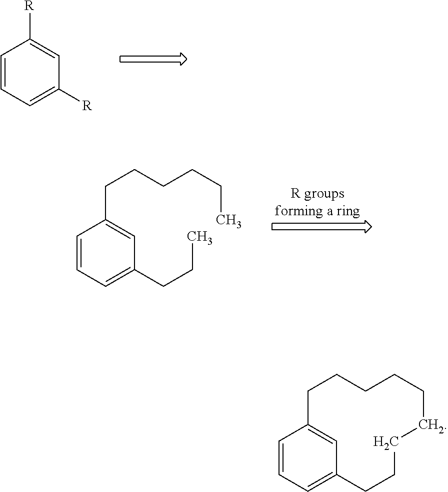

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

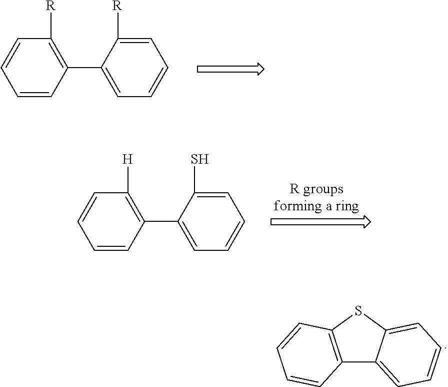

According to an embodiment of the present disclosure, disclosed is an organic electroluminescent device, the organic electroluminescent device comprises:
an anode,
a cathode, and
a first organic layer and a second organic layer disposed between the anode and the cathode;
wherein the first organic layer comprises a first compound, wherein the first compound has a structure represented by Formula 1:

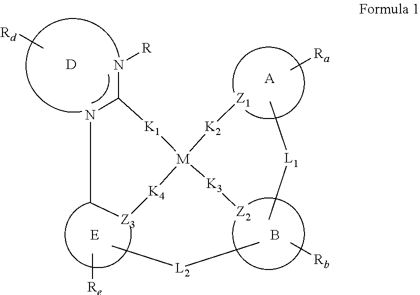

wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 1 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof;
y is 1, 2, 3, 4 or 5;
K₁ to K₄ are, at each occurrence identically or differently, selected from a single bond, O or S:
Z₁ to Z₃ are, at each occurrence identically or differently, selected from C or N;
R in Formula 1 has a structure represented by Formula 2:

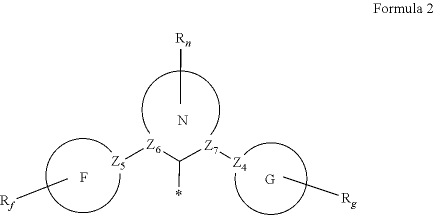

wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof;
Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined; and
adjacent substituents R″, Rₐ, R_{b}, R_{d}, Rₑ, R_{f}, R_{g} and Rₙ can be optionally joined to form a ring;
wherein the second organic layer comprises a second compound, wherein the second compound has a structure represented by Formula 3:

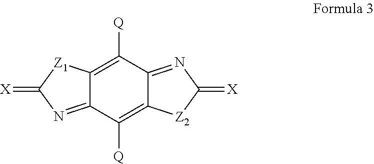

wherein in Formula 3,
X and Y are, at each occurrence identically or differently, selected from NQ′, CQ″Q′″, O, S or Se;
Z₁ and Z₂ are, at each occurrence identically or differently, selected from O, S or Se;

Q, Q′, Q″ and Q′″ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof;
at least one of Q, Q′, Q″ and Q′″ is a group having at least one electron withdrawing group; and
adjacent substituents Q″ and Q′″ can be optionally joined to form a ring.

Herein, “an unsaturated carbocyclic ring having 5 to 30 carbon atoms” comprises an aromatic unsaturated carbocyclic ring and a non-aromatic unsaturated carbocyclic ring each having 5 to 30 carbon atoms; “an unsaturated heterocyclic ring having 3 to 30 carbon atoms” comprises an aromatic unsaturated heterocyclic ring and a non-aromatic unsaturated heterocyclic ring each having 3 to 30 carbon atoms.

Herein, the expression that adjacent substituents R″, Rₐ, R_{b}, R_{d}, Rₑ, R_{f}, R_{g} and Rₙ can be optionally joined to form a ring is intended to mean that any one or more of groups of adjacent substituents, such as adjacent substituents R″, adjacent substituents Rₐ, adjacent substituents R_{b}, adjacent substituents R_{d}, adjacent substituents Rₑ, adjacent substituents R_{f}, adjacent substituents R_{g}, adjacent substituents Rₙ, adjacent substituents R_{d} and Rₑ, and adjacent substituents Rₐ and R_{b}, can be joined to form a ring. Obviously, it is also possible that none of these groups of adjacent substituents are joined to form a ring.

Herein, the expression that adjacent substituents Q″ and Q′″ can be optionally joined to form a ring is intended to mean that a group of adjacent substituents, such as adjacent substituents Q″ and Q′″, can be joined to form a ring. Obviously, it is also possible that none of these groups of adjacent substituents are joined to form a ring.

According to an embodiment of the present disclosure, M is selected from Cu, Ag, Au, Ru, Rh, Pd, Os, Ir or Pt.

According to an embodiment of the present disclosure, M is selected from Pt or Pd.

According to an embodiment of the present disclosure, M is selected from Pt.

According to an embodiment of the present disclosure, the ring A, the ring B, the ring E, the ring F and the ring G are, at each occurrence identically or differently, selected from a five-membered unsaturated carbocyclic ring, an aromatic ring having 6 to 30 carbon atoms, a heteroaromatic ring having 3 to 30 carbon atoms or a combination thereof.

According to an embodiment of the present disclosure, the ring A, the ring B, the ring E, the ring F, the ring G and the ring N are, at each occurrence identically or differently, selected from a five-membered unsaturated carbocyclic ring, an aromatic ring having 6 to 30 carbon atoms, a heteroaromatic ring having 3 to 30 carbon atoms or a combination thereof; the ring D is, at each occurrence identically or differently, selected from an unsaturated heterocyclic ring having 1 to 18 carbon atoms.

According to an embodiment of the present disclosure, the ring A, the ring B, the ring E, the ring F, the ring G and the ring N are, at each occurrence identically or differently, selected from a five-membered unsaturated carbocyclic ring, an aromatic ring having 6 to 18 carbon atoms, a heteroaromatic ring having 3 to 18 carbon atoms or a combination thereof; the ring D is, at each occurrence identically or differently, selected from a heteroaromatic ring having 3 to 18 carbon atoms.

According to an embodiment of the present disclosure, the ring A, the ring B, the ring E, the ring F, the ring G and the ring N are, at each occurrence identically or differently, selected from a benzene ring, a pyridine ring, an indene ring, a fluorene ring, an indole ring, a carbazole ring, an indolocarbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring, an imidazole ring, a benzimidazole ring or a combination thereof; the ring D is, at each occurrence identically or differently, selected from an imidazolecarbene ring or a benzimidazolecarbene ring.

According to an embodiment of the present disclosure, L₁ is selected from a single bond, O, S, (SiR″R″)_{y}, NR″ or a combination thereof, wherein y is 1 or 2.

According to an embodiment of the present disclosure, L₁ is selected from a single bond, O or S.

According to an embodiment of the present disclosure, L₁ is selected from a single bond.

According to an embodiment of the present disclosure, K₁ to K₄ are selected from a single bond.

According to an embodiment of the present disclosure, the first compound has a structure represented by one of Formula 1-1 to Formula 1-20:

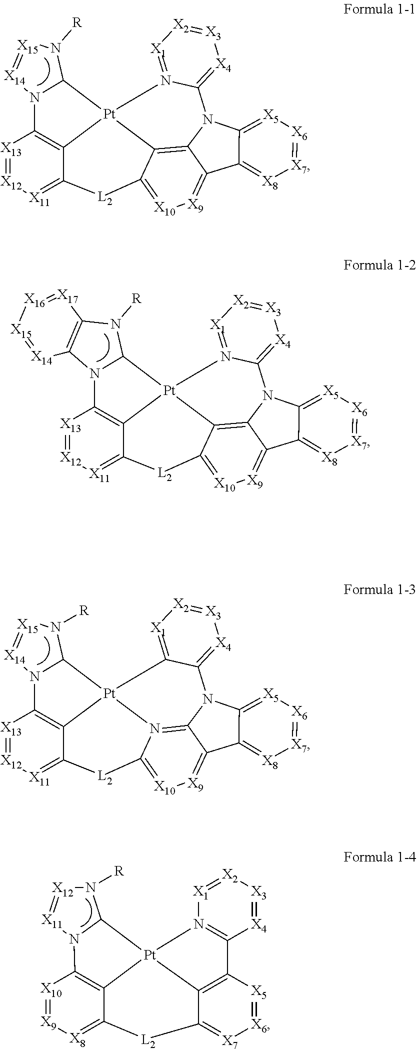

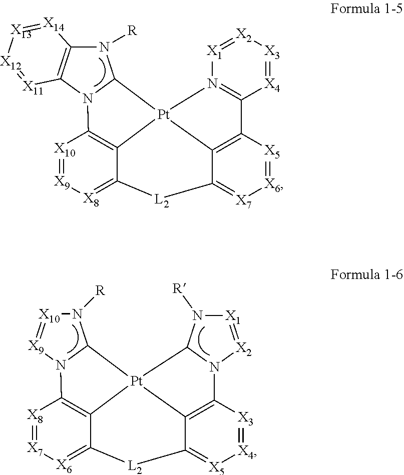

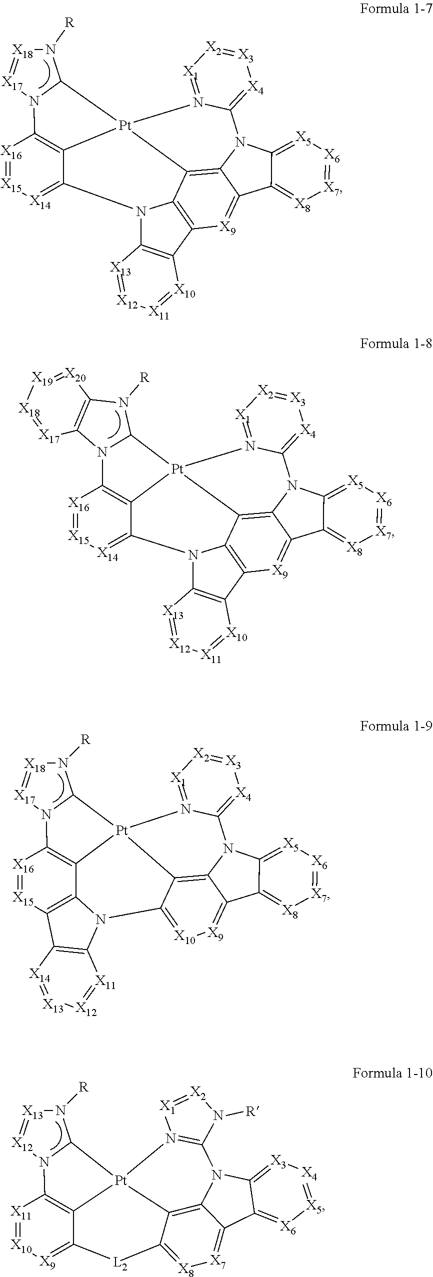

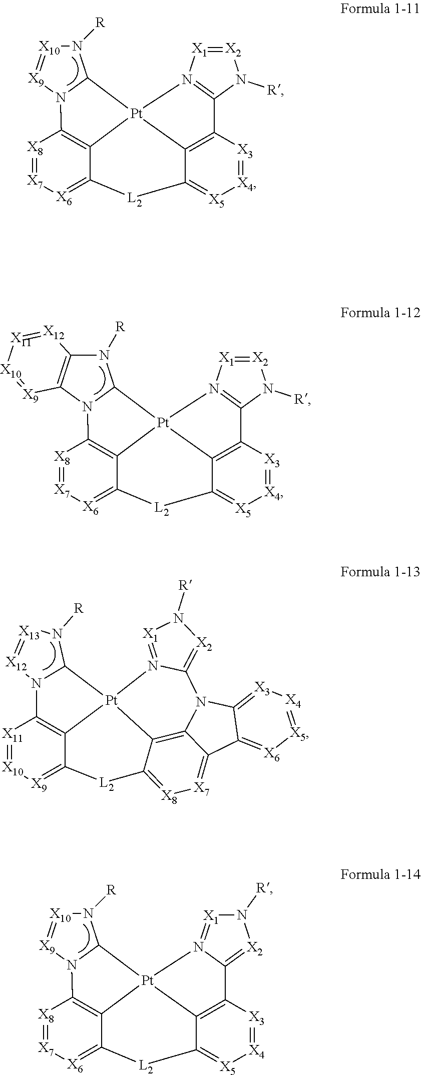

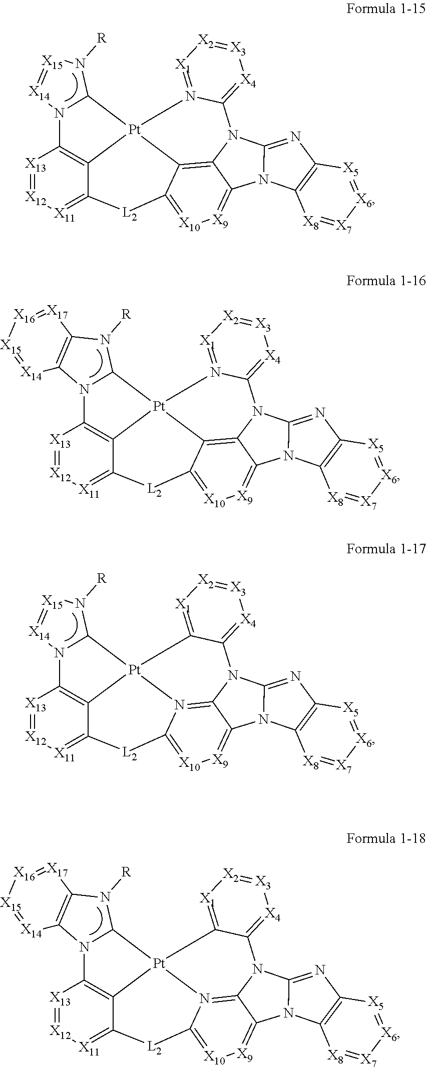

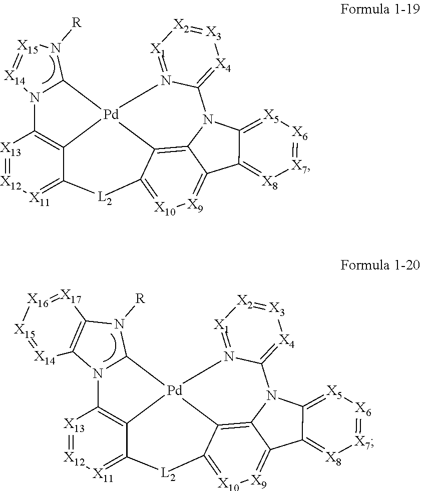

wherein in Formula 1-1 to Formula 1-20,
L₂ is, at each occurrence identically or differently, selected from a single bond, O, S, Se, (SiR″R″)_{y}, PR″, NR″, substituted or unsubstituted arylene having 6 to 30 carbon atoms or a combination thereof;
y is, at each occurrence identically or differently, selected from 1, 2, 3, 4 or 5;
X₁ to X₂₀ are, at each occurrence identically or differently, selected from CRₓ or N;
R has a structure represented by Formula 2-1:

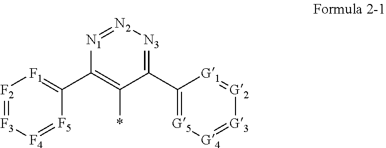

wherein in Formula 2-1, F₁ to F₅ are each independently selected from CR_{f} or N; G′₁ to G′₅ are each independently selected from CR_{g} or N; N₁ to N₃ are each independently selected from CRₙ or N;

R′, R″, Rₓ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of N₁ to N₃ is CRₙ, wherein the Rₙ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R′, R″, Rₓ, Rᵣ, R_{g} and Rₙ can be optionally joined to form a ring.

Herein, the expression that adjacent substituents R′, R″, Rₓ, R_{f}, R_{g} and Rₙ can be optionally joined to form a ring is intended to mean that any one or more of groups of adjacent substituents, such as adjacent substituents R″, adjacent substituents Rₓ, adjacent substituents R_{f}, adjacent substituents R_{g}, and adjacent substituents Rₙ, can be joined to form a ring. Obviously, it is also possible that none of these groups of adjacent substituents are joined to form a ring.

According to an embodiment of the present disclosure, the first compound has a structure represented by Formula 1-1 or Formula 1-2.

According to an embodiment of the present disclosure, N₂ is selected from CRₙ, wherein the Rₙ is, at each occurrence identically or differently, selected from the group consisting of: deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof.

According to an embodiment of the present disclosure, N₂ is selected from CRₙ, wherein the Rₙ is, at each occurrence identically or differently, selected from the group consisting of: deuterium, fluorine, a cyano group, substituted or unsubstituted alkyl having 1 to 7 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms and combinations thereof.

According to an embodiment of the present disclosure, N₂ is selected from CRₙ, wherein the Rₙ is, at each occurrence identically or differently, selected from deuterium, substituted or unsubstituted alkyl having 1 to 7 carbon atoms, substituted or unsubstituted cycloalkyl having 3 to 6 ring carbon atoms or a combination thereof.

According to an embodiment of the present disclosure, N₂ is selected from CRₙ, wherein the Rₙ is, at each occurrence identically or differently, selected from the group consisting of: methyl, partially or fully deuterated methyl, ethyl, partially or fully deuterated ethyl, n-propyl, partially or fully deuterated n-propyl, isopropyl, partially or fully deuterated isopropyl, cyclopropyl, partially or fully deuterated cyclopropyl, n-butyl, partially or fully deuterated n-butyl, isobutyl, partially or fully deuterated isobutyl, t-butyl, partially or fully deuterated t-butyl, cyclopentyl, partially or fully deuterated cyclopentyl, cyclohexyl, partially or fully deuterated cyclohexyl, partially or fully deuterated 2,3,3-trimethylbutan-2-yl, 2,3,3-trimethylbutan-2-yl and combinations thereof.

According to an embodiment of the present disclosure, X₁ to X₂₀ are, at each occurrence identically or differently, selected from CRₓ.

According to an embodiment of the present disclosure, F₁ to F₅ are each independently selected from CR_{f}.

According to an embodiment of the present disclosure, G′₁ to G′₅ are each independently selected from CR_{g}.

According to an embodiment of the present disclosure, N₁ to N₃ are each independently selected from CRₙ.

According to an embodiment of the present disclosure, L₂ is selected from a single bond, O, S, (SiR″R″)_{y}, NR″ or a combination thereof.

According to an embodiment of the present disclosure, L₂ is selected from a single bond, O or S.

According to an embodiment of the present disclosure, L₂ is selected from O.

According to an embodiment of the present disclosure, Rₓ, R′, R″, R_{f} and R_{g}are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, Rₓ, R′, R″, R_{f} and R_{g} are, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl, 2,3,3-trimethylbutan-2-yl and combinations thereof.

According to an embodiment of the present disclosure, at least one R_{f} is selected from deuterium, halogen or substituted or unsubstituted alkyl having 1 to 20 carbon atoms.

According to an embodiment of the present disclosure, at least one R_{g} is selected from deuterium, halogen or substituted or unsubstituted alkyl having 1 to 20 carbon atoms.

According to an embodiment of the present disclosure, R_{f} is, at each occurrence, selected from deuterium.

According to an embodiment of the present disclosure, R_{g} is, at each occurrence, selected from deuterium.

According to an embodiment of the present disclosure, R is, at each occurrence identically or differently, selected from the group consisting of An-1 to An-48, wherein the specific structures of An-1 to An-48 are referred to claim 9.

According to an embodiment of the present disclosure, hydrogens in the structures of An-1 to An-48 can be partially or fully substituted with deuterium.

According to an embodiment of the present disclosure, the first compound has a structure represented by Pt(Lₐ)(L_{b}), wherein Lₐ and L_{b} are a first ligand and a second ligand coordinated to the metal Pt, respectively, Lₐ is selected from the group consisting of Lₐ1-1 to Lₐ1-29, Lₐ2-1 to Lₐ2-20 and Lₐ3-1 to Lₐ3-7, and Lb is selected from the group consisting of L_{b}1-1 to L_{b}1-8, L_{b}2-1 to L_{b}2-22 and L_{b}3-1 to L_{b}3-8, wherein the specific structures of Lₐ1-1 to Lₐ1-29, Lₐ2-1 to Lₐ2-20, Lₐ3-1 to Lₐ3-7, L_{b}1-1 to L_{b}1-8, L_{b}2-1 to L_{b}2-22 and L_{b}3-1 to L_{b}3-8 are referred to claim 10.

According to an embodiment of the present disclosure, the first compound is selected from the group consisting of Compound Pt1 to Compound Pt166, wherein the specific structures of Compound Pt1 to Compound Pt166 are referred to claim 10.

According to an embodiment of the present disclosure, the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, an aza-aromatic ring group and any one of the following groups substituted by one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the electron withdrawing group is selected from the group consisting of: F, CF₃, OCF₃, SF₅, SO₂CF₃, a cyano group, an isocyano group, SCN, OCN, pyrimidinyl, triazinyl and combinations thereof.

According to an embodiment of the present disclosure, X and Y are, at each occurrence identically or differently, selected from CQ″Q′″.

According to an embodiment of the present disclosure, Z₁ and Z₂ are, at each occurrence identically or differently, selected from O or S.

According to an embodiment of the present disclosure, Z₁ and Z₂ are selected from O.

According to an embodiment of the present disclosure, X and Y are, at each occurrence identically or differently, selected from the group consisting of the following structures: O, S, Se,

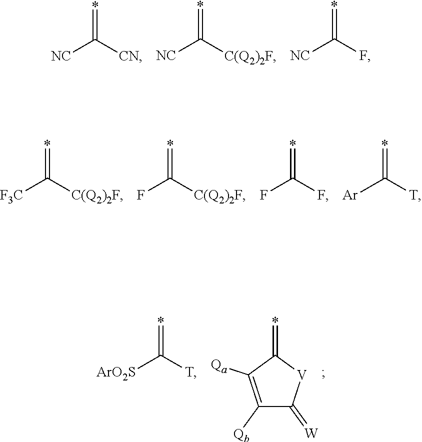

wherein V and W are, at each occurrence identically or differently, selected from CQᵥQ_{w}, NQᵥ, O, S or Se;
Ar is, at each occurrence identically or differently, selected from substituted or unsubstituted aryl having 6 to 30 carbon atoms or substituted or unsubstituted heteroaryl having 3 to 30 carbon atoms;
T, Q₂, Qₐ, Q_{b}, Qᵥ and Q_{w} are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof;
T is a group having at least one electron withdrawing group, and for any one of the structures, when one or more of Qₐ, Q_{b}, Qᵥ and Q_{w} are present, at least one of Qₐ, Q_{b}, Qᵥ and Q_{w} is a group having at least one electron withdrawing group; and
“ [symbol] ” represents a position where each of the groups X and Y is joined to the five-membered ring shown in Formula 3.

According to an embodiment of the present disclosure, the group having the at least one electron withdrawing group is selected from the group consisting of: F, CF₃, OCF₃, SF₅, SO₂CF₃, a cyano group, an isocyano group, SCN, OCN, pentafluorophenyl, 4-cyanotetrafluorophenyl, tetrafluoropyridyl, pyrimidinyl, triazinyl and combinations thereof.

According to an embodiment of the present disclosure, Q₂is, at each occurrence identically or differently, selected from the group consisting of: F, CF₃, OCF₃, SF₅, SO₂CF₃, a cyano group, an isocyano group, SCN, OCN, pentafluorophenyl, 4-cyanotetrafluorophenyl, tetrafluoropyridyl, pyrimidinyl, triazinyl and combinations thereof.

According to an embodiment of the present disclosure, X and Y are, at each occurrence identically or differently, selected from the group consisting of the following structures:
O, S, Se,

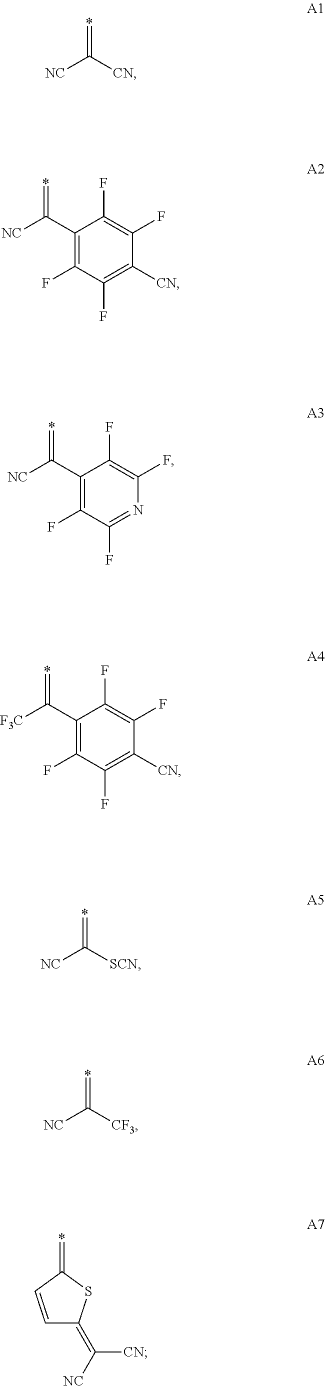

wherein “ [symbol] ” represents a position where each of the groups X and Y is joined to the five-membered ring shown in Formula 3.

According to an embodiment of the present disclosure, X and Y are

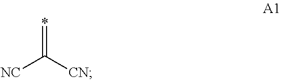 [SMILES: *=C(C#N)C#N]

“ [symbol] ” represents a position where each of the groups X and Y is joined to the five-membered ring shown in Formula 3.

According to an embodiment of the present disclosure, Q is, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, unsubstituted alkyl having 1 to 20 carbon atoms, unsubstituted cycloalkyl having 3 to 20 ring carbon atoms, unsubstituted alkoxy having 1 to 20 carbon atoms, unsubstituted alkenyl having 2 to 20 carbon atoms, unsubstituted aryl having 6 to 30 carbon atoms, unsubstituted heteroaryl having 3 to 30 carbon atoms and any one of the following groups substituted by one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group and a phosphoroso group: alkyl having 1 to 20 carbon atoms, cycloalkyl having 3 to 20 ring carbon atoms, alkoxy having 1 to 20 carbon atoms, alkenyl having 2 to 20 carbon atoms, alkynyl having 2 to 20 carbon atoms, aryl having 6 to 30 carbon atoms, heteroaryl having 3 to 30 carbon atoms and combinations thereof.

According to an embodiment of the present disclosure, Q is, at each occurrence identically or differently, selected from the group consisting of: hydrogen, deuterium, methyl, isopropyl, NO₂, SO₂CH₃, SCF₃, C₂F₅, OC₂F₅, OCH₃, diphenylmethylsilyl, phenyl, methoxyphenyl, p-methylphenyl, 2,6-diisopropylphenyl, polyfluorophenyl, difluoropyridyl, nitrophenyl, dimethylthiazolyl, vinyl substituted by one or more of CN or CF₃, acetenyl substituted by one of CN or CF₃, dimethylphosphoroso, diphenylphosphoroso, F, CF₃, OCF₃, SF₅, SO₂CF₃, a cyano group, an isocyano group, SCN, OCN, trifluoromethylphenyl, trifluoromethoxyphenyl, bis(trifluoromethyl)phenyl, bis(trifluoromethoxy)phenyl, 4-cyanotetrafluorophenyl, phenyl or biphenyl substituted by one or more of F, CN or CF₃, tetrafluoropyridyl, pyrimidinyl, triazinyl, diphenylboryl, oxaboraanthryl and combinations thereof.

According to an embodiment of the present disclosure, Q is, at each occurrence identically or differently, selected from the group consisting of B-1 to B-90, wherein the specific structures of B-1 to B-90 are referred to claim 14.

According to an embodiment of the present disclosure, two Q in the second compound represented by Formula 3 are the same.

According to an embodiment of the present disclosure, the first compound is selected from the group consisting of Compound 1 to Compound 184, wherein the specific structures of Compound 1 to Compound 184 are referred to claim 15.

According to an embodiment of the present disclosure, the first organic layer is a light-emitting layer, the first compound is a phosphorescent material, the second organic layer is a hole injection layer, and the second compound is a hole injection material.

According to an embodiment of the present disclosure, the second organic layer is a hole injection layer, and the hole injection layer further comprises at least one hole transporting material, wherein the hole transporting material has a structure represented by Formula 4:

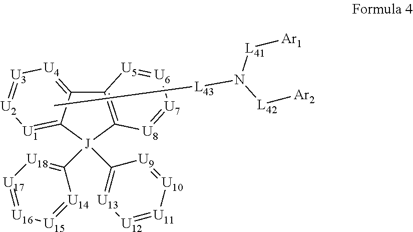

wherein in Formula 4,
U₁ to U₈ are, at each occurrence identically or differently, selected from C, CR₁ or N; U₉ to U₁₈ are, at each occurrence identically or differently, selected from CR₁ or N;
J is selected from C, Si or Ge;
L₄₁ to L₄₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are, at each occurrence identically or differently, selected from substituted or unsubstituted aryl having 6 to 30 carbon atoms or substituted or unsubstituted heteroaryl having 3 to 30 carbon atoms;
R₁ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents L₄₁, L₄₂, L₄₃, R₁, Ar₁ and Ar₂ can be optionally joined to form a ring.

Herein, the expression that adjacent substituents L₄₁, L₄₂, L₄₃, R₁, Ar₁ and Ar₂ can be optionally joined to form a ring is intended to mean that in Formula 4, any one or more of groups of adjacent substituents, such as adjacent substituents R₁, adjacent substituents R₁ and L₄₃, adjacent substituents L₄₁ and L₄₂, adjacent substituents L₄₁ and L₄₃, adjacent substituents L42 and L₄₃, adjacent substituents Ar₁ and Ar₂, adjacent substituents Ar₁ and L₄₃, adjacent substituents Ar₂ and L₄₃, adjacent substituents Ar₁ and R₁, and adjacent substituents Ar₂ and R₁, can be joined to form a ring. Obviously, it is also possible that none of these groups of adjacent substituents are joined to form a ring.

According to an embodiment of the present disclosure, U₁ to U₈ are, at each occurrence identically or differently, selected from C or CR₁.

According to an embodiment of the present disclosure, in Formula 4, at least one of U₁ to U₁₈ is N.

According to an embodiment of the present disclosure, the hole transporting material has a structure represented by any one of Formula 4-1 to Formula 4-4:

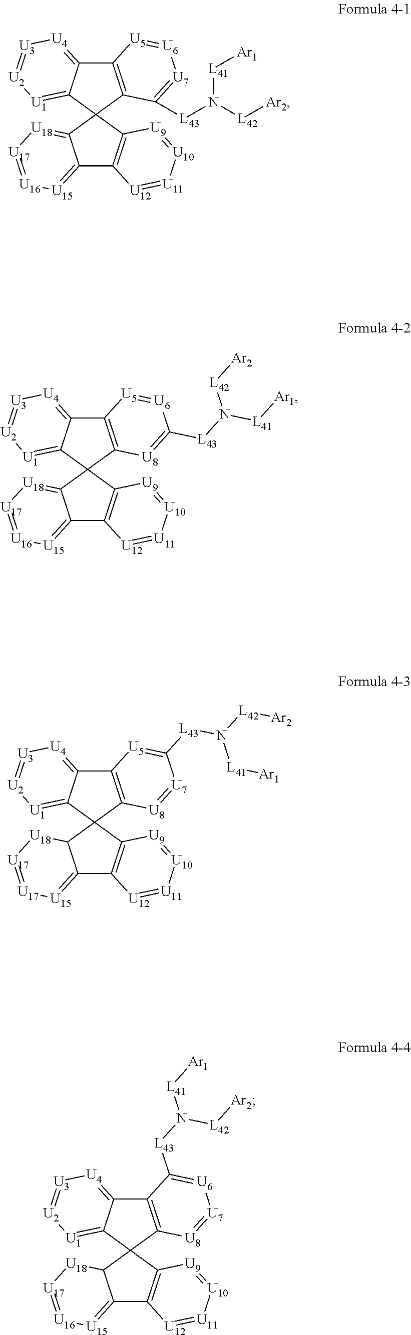

wherein U₁ to U₁₂, U₁₅ to U₁₈ are, at each occurrence identically or differently, selected from CR₁ or N;
L₄₁ to L₄₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are, at each occurrence identically or differently, selected from substituted or unsubstituted aryl having 6 to 30 carbon atoms or substituted or unsubstituted heteroaryl having 3 to 30 carbon atoms;
R₁ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents L₄₁, L₄₂, L₄₃, R₁, Ar₁ and Ar₂ can be optionally joined to form a ring.

According to an embodiment of the present disclosure, in Formula 4-1 to Formula 4-4, U₁ to U₁₂, U₁₅ to U₁₈ are, at each occurrence identically or differently, selected from CR₁.

According to an embodiment of the present disclosure, L₄₁ to L₄₃ are, at each occurrence identically or differently, selected from a single bond, substituted or unsubstituted arylene having 6 to 24 carbon atoms, substituted or unsubstituted heteroarylene having 3 to 24 carbon atoms or a combination thereof.

According to an embodiment of the present disclosure, L₄₁ to L₄₃ are, at each occurrence identically or differently, selected from a single bond, substituted or unsubstituted phenylene, substituted or unsubstituted biphenylylene, substituted or unsubstituted terphenylene, substituted or unsubstituted naphthylene, substituted or unsubstituted fluorenylidene, substituted or unsubstituted silafluorenylidene, substituted or unsubstituted carbazolylene, substituted or unsubstituted dibenzofuranylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted spirobifluorenylene, substituted or unsubstituted anthrylene, substituted or unsubstituted pyrenylene or a combination thereof.

According to an embodiment of the present disclosure, L₄₁ to L₄₃ are, at each occurrence identically or differently, selected from the group consisting of:

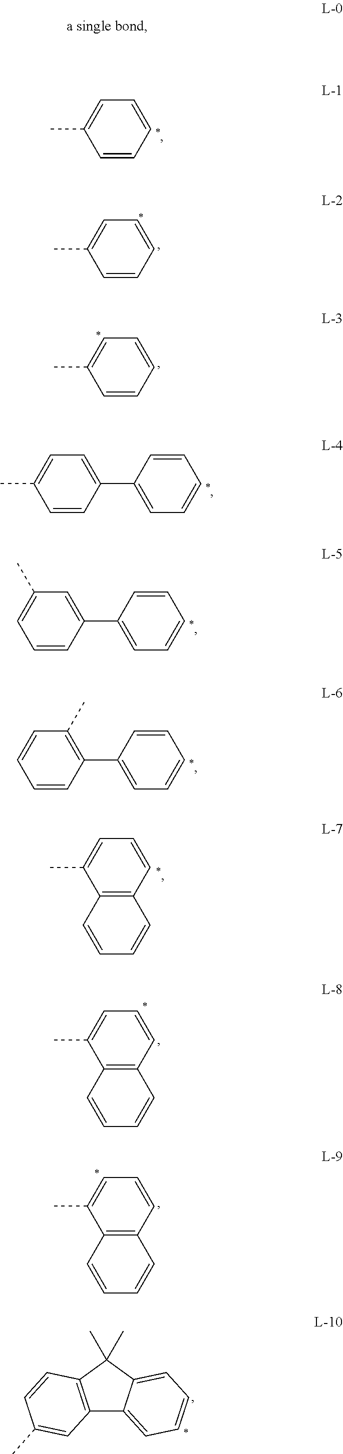

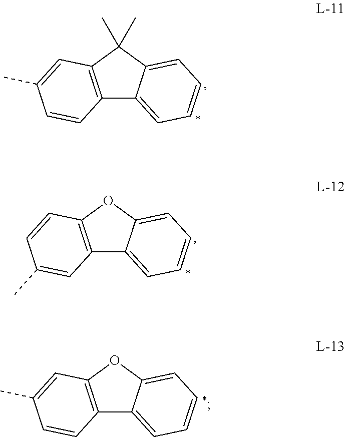

wherein “ [symbol] ” represents a position where nitrogen in Formula 4 is bonded in L-1 to L-13, and the dashed line represents a position where Ar₁, Ar₂ or any one of U₁ to U₈ in Formula 4 is bonded in L-1 to L-13.

According to an embodiment of the present disclosure, Ar₁ and Ar₂ each have, at each occurrence identically or differently, a structure represented by any one of Formula Ar-1 to Formula Ar-4:

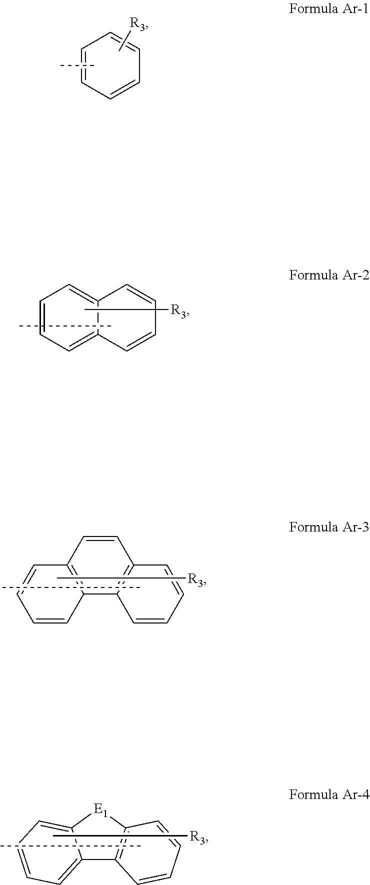

wherein E₁ is, at each occurrence identically or differently, selected from O, S, Se, C(R₄)₂, Si(R₄)₂ or Ge(R₄)₂;
R₃ represents, at each occurrence identically or differently, mono-substitution, multiple substitutions or non-substitution;
R₃ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₃ can be optionally joined to form a ring; and
the dashed line represents a position where L₄₁ is joined in the structure of Ar₁; the dashed line also represents a position where L₄₂ is joined in the structure of Ar₂.

Herein, the expression that adjacent substituents R₃ can be optionally joined to form a ring is intended to mean that any adjacent substituents R₃ can be joined to form a ring. Obviously, it is also possible that any adjacent substituents R₃ are not joined to form a ring.

According to an embodiment of the present disclosure, R₃ is, at each occurrence identically or differently, selected from hydrogen, deuterium, halogen, substituted or unsubstituted alkyl having 1 to 20 carbon atoms, substituted or unsubstituted aryl having 6 to 30 carbon atoms, substituted or unsubstituted heteroaryl having 3 to 30 carbon atoms or a combination thereof.

According to an embodiment of the present disclosure, Ar₁ and Ar₂ are, at each occurrence identically or differently, selected from the group consisting of G1 to G37:

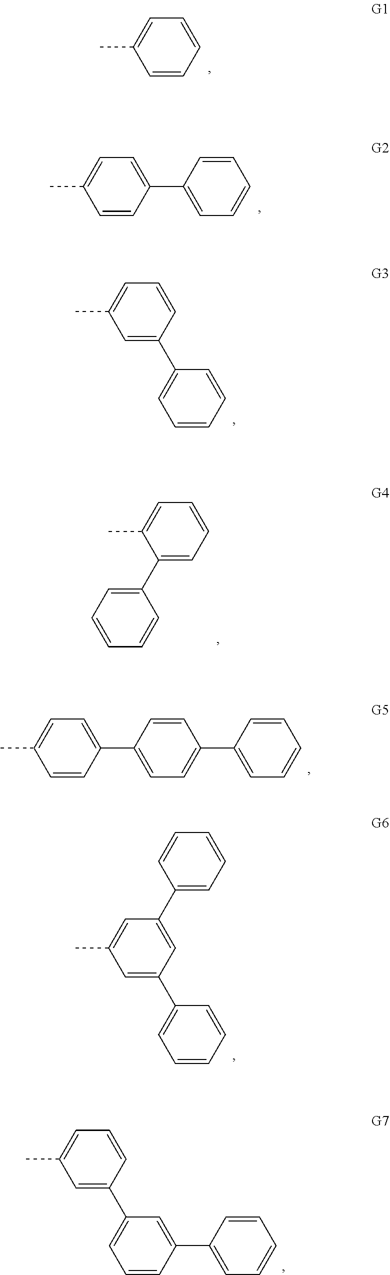

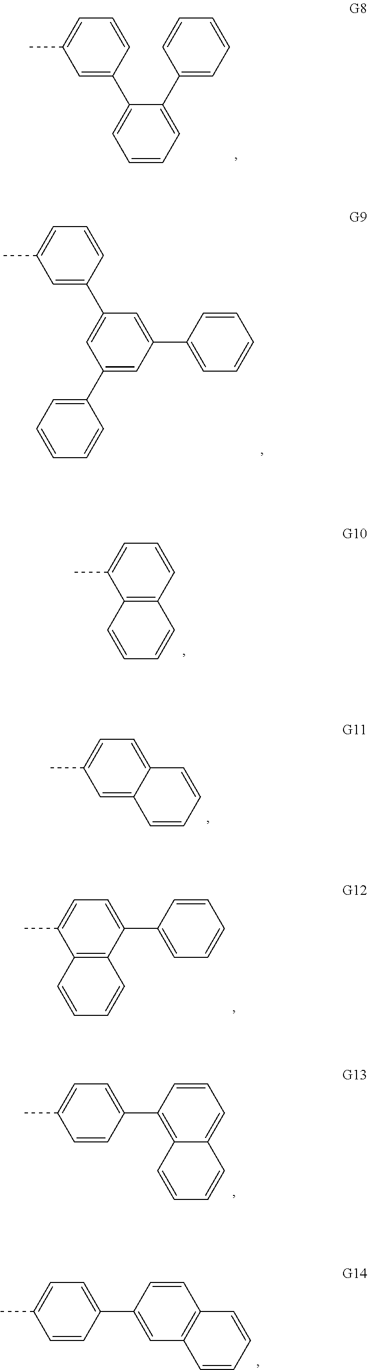

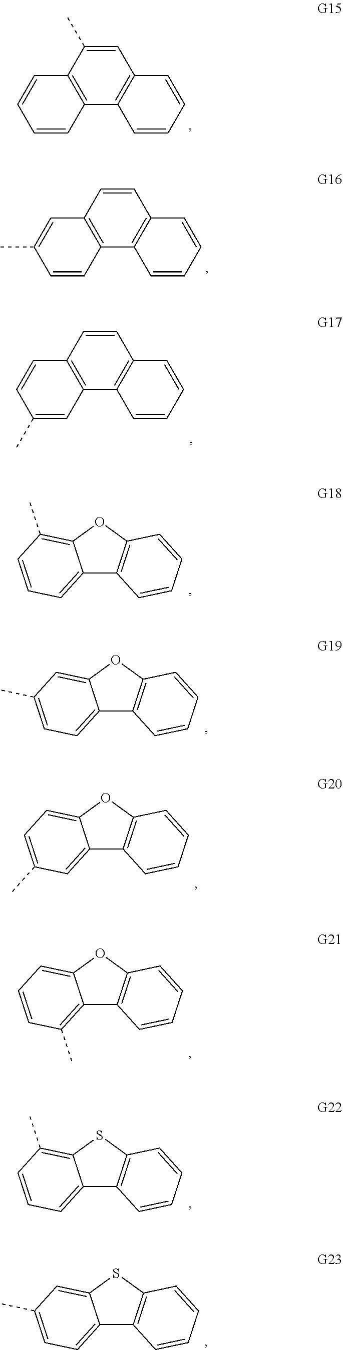

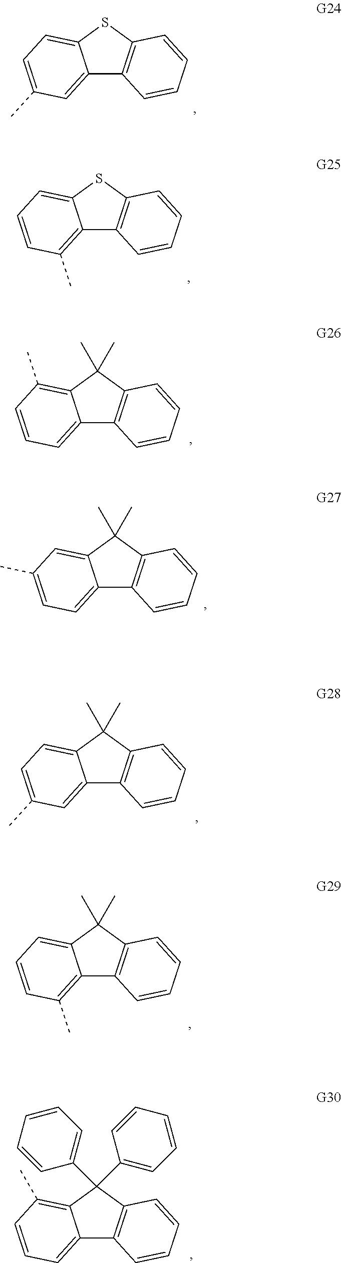

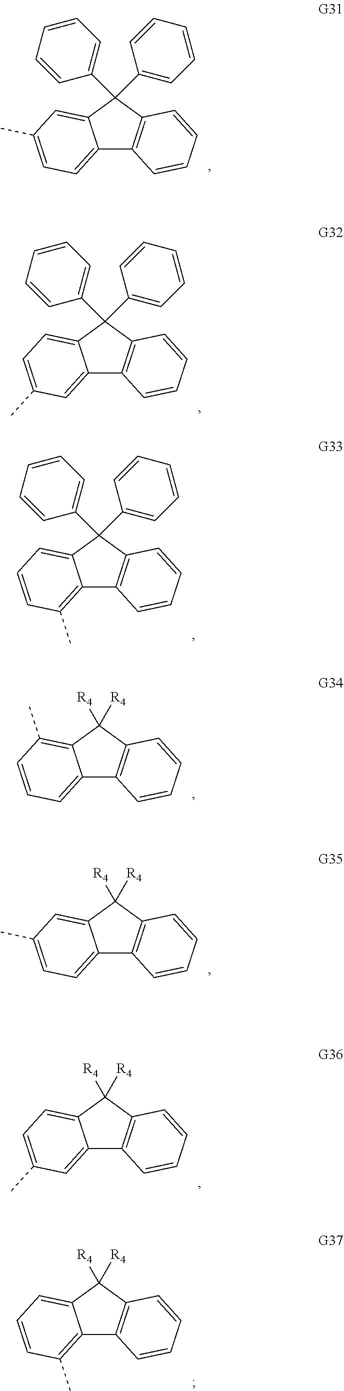

wherein R₄ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₄ can be optionally joined to form a ring.

Herein, the expression that adjacent substituents R₄ can be optionally joined to form a ring is intended to mean that any adjacent substituents R₄ can be joined to form a ring. Obviously, it is also possible that any adjacent substituents R₄ are not joined to form a ring.

According to an embodiment of the present disclosure, R₄ is, at each occurrence identically or differently, selected from hydrogen, deuterium, substituted or unsubstituted alkyl having 1 to 20 carbon atoms, substituted or unsubstituted aryl having 6 to 30 carbon atoms, substituted or unsubstituted heteroaryl having 3 to 30 carbon atoms or a combination thereof.

According to an embodiment of the present disclosure, R₄ is, at each occurrence identically or differently, selected from hydrogen, deuterium, methyl, ethyl, isopropyl, fluorene, phenyl, biphenyl, naphthyl or a combination thereof.

According to an embodiment of the present disclosure, R₁ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms or a combination thereof.

According to an embodiment of the present disclosure, R₁ is, at each occurrence identically or differently, selected from hydrogen, deuterium, fluorine, methyl, n-propyl, isopropyl, n-butyl, isobutyl, sec-butyl, t-butyl, 2-methylbutyl, n-pentyl, sec-pentyl, neopentyl, cyclopentyl, n-hexyl, neohexyl, cyclohexyl, n-heptyl, phenyl, biphenyl, terphenyl, naphthyl, fluorenyl or a combination thereof.

According to an embodiment of the present disclosure, the hole transporting material is selected from the group consisting of Compound II-1 to Compound II-162 and Compound IV-1 5 to Compound IV-273;
wherein Compound II-1 to Compound II-162 are shown as follows:

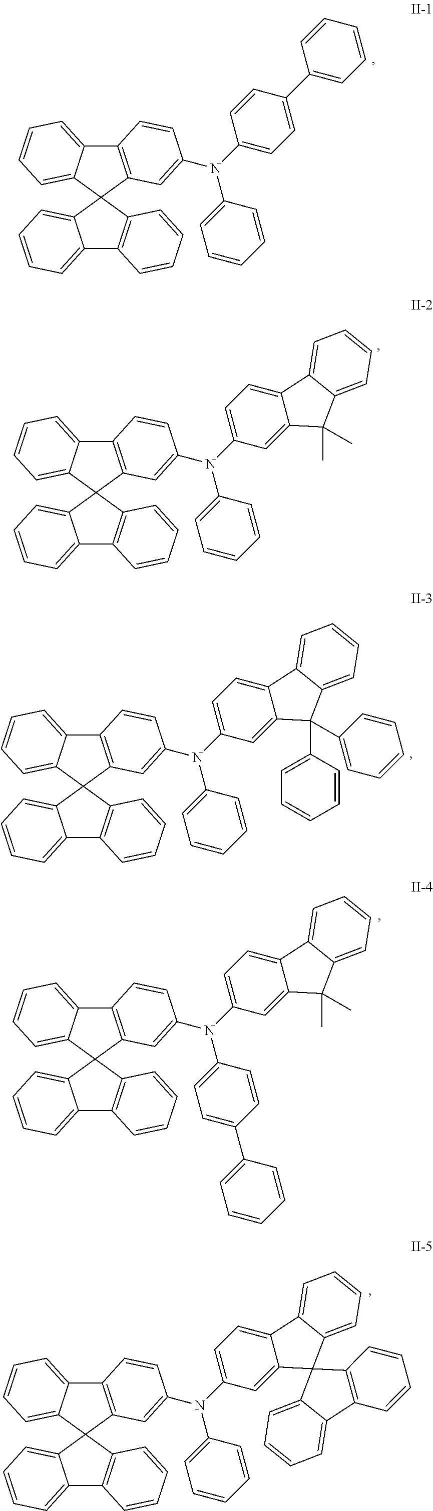 [SMILES: c1ccc(-c2ccc(N(c3ccccc3)c3ccc4c(c3)C3(c5ccccc5-c5ccccc53)c3ccccc3-4)cc2)cc1 ; CC1(C)c2ccccc2-c2ccc(N(c3ccccc3)c3ccc4c(c3)C3(c5ccccc5-c5ccccc53)c3ccccc3-4)cc21 ; c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(N(c2ccc3c(c2)C2(c4ccccc4-c4ccccc42)c2ccccc2-3)c2ccc3c(c2)C2(c4ccccc4-c4ccccc42)c2ccccc2-3)cc1]

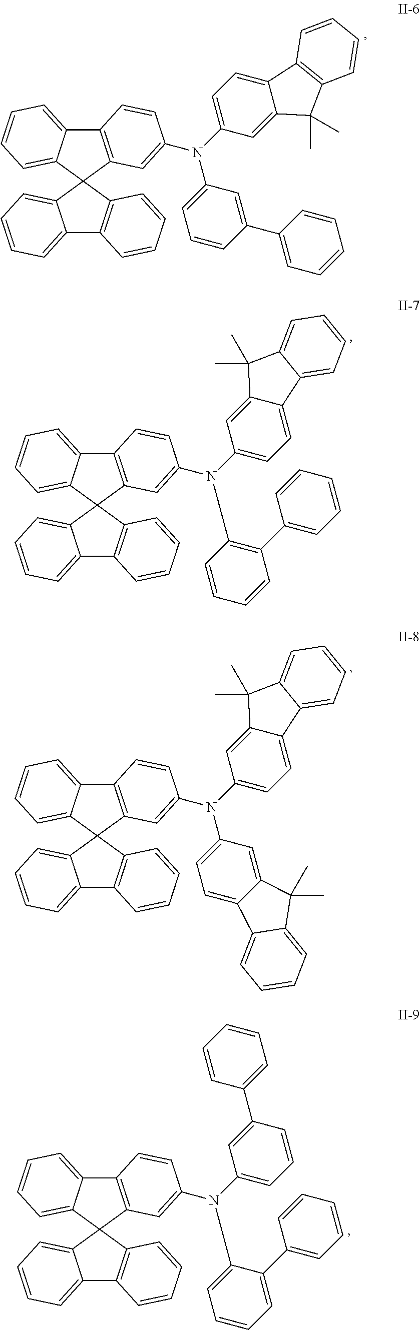

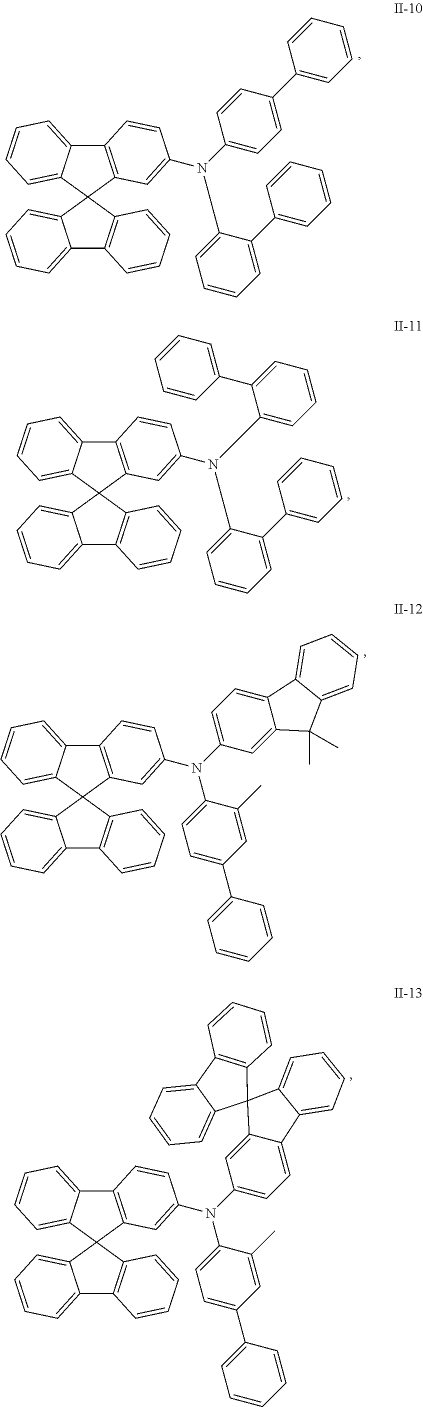

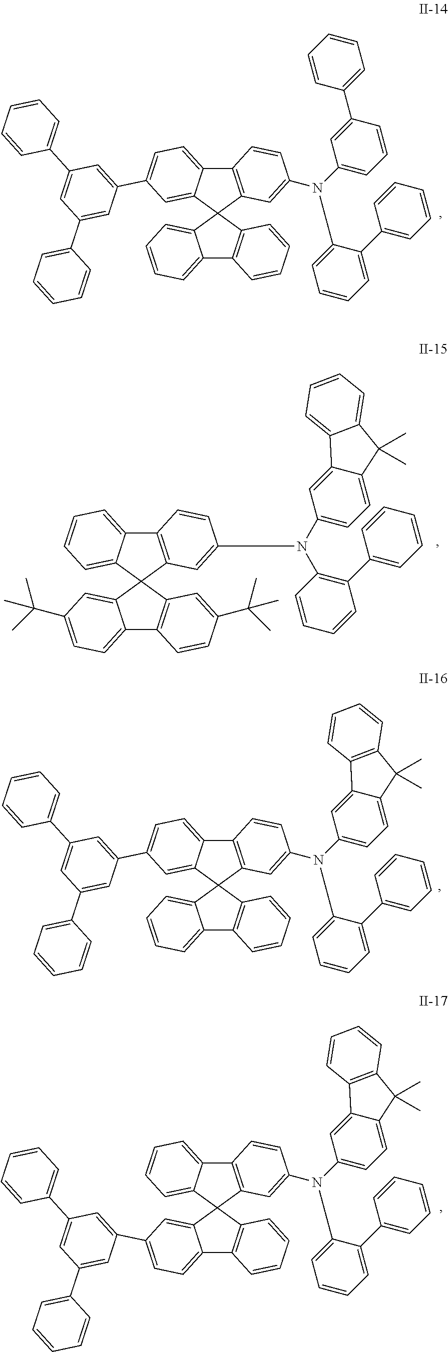 [SMILES: c1ccc(-c2cc(-c3ccccc3)cc(-c3ccc4c(c3)C3(c5ccccc5-c5ccccc53)c3cc(N(Cc5ccccc5-c5ccccc5)c5cccc(-c6ccccc6)c5)ccc3-4)c2)cc1 ; CC(C)(C)c1ccc2c(c1)C1(c3ccccc3-c3ccc(N(c4ccc5c(c4)-c4ccccc4C5(C)C)c4ccccc4-c4ccccc4)cc31)c1cc(C(C)(C)C)ccc1-2 ; CC1(C)c2ccccc2-c2cc(N(Cc3ccccc3-c3ccccc3)c3ccc4c(c3)C3(c5ccccc5-c5ccccc53)c3cc(-c5cc(-c6ccccc6)cc(-c6ccccc6)c5)ccc3-4)ccc21 ; CC1(C)c2ccccc2-c2cc(N(Cc3ccccc3-c3ccccc3)c3ccc4c(c3)C3(c5ccccc5-c5ccc(-c6cc(-c7ccccc7)cc(-c7ccccc7)c6)cc53)c3ccccc3-4)ccc21]

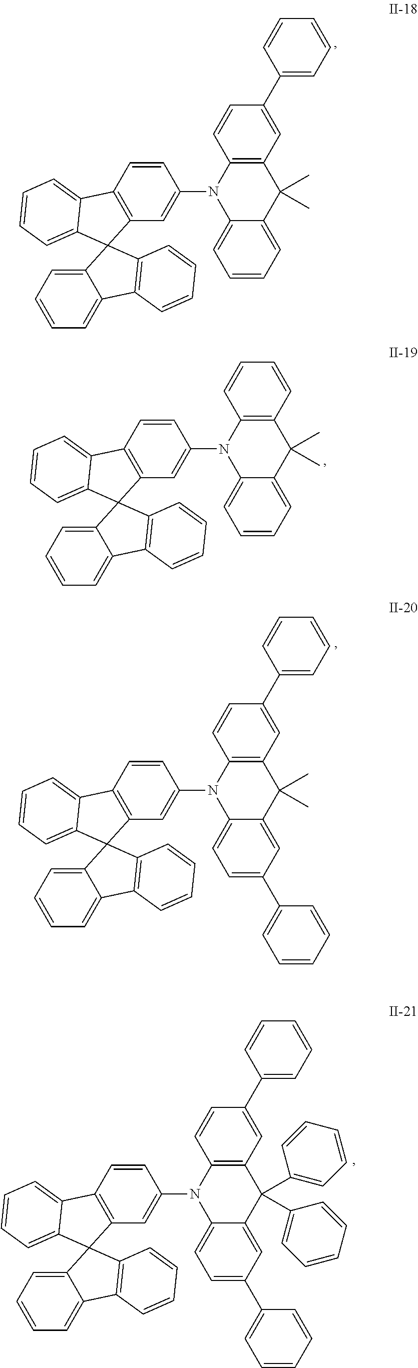 [SMILES: CC1(C)c2ccccc2N(c2ccc3c(c2)C2(c4ccccc4-c4ccccc42)c2ccccc2-3)c2ccc(-c3ccccc3)cc21 ; CC1(C)c2ccccc2N(c2ccc3c(c2)C2(c4ccccc4-c4ccccc42)c2ccccc2-3)c2ccccc21 ; CC1(C)c2cc(-c3ccccc3)ccc2N(c2ccc3c(c2)C2(c4ccccc4-c4ccccc42)c2ccccc2-3)c2ccc(-c3ccccc3)cc21 ; c1ccc(-c2ccc3c(c2)C(c2ccccc2)(c2ccccc2)c2cc(-c4ccccc4)ccc2N3c2ccc3c(c2)C2(c4ccccc4-c4ccccc42)c2ccccc2-3)cc1]

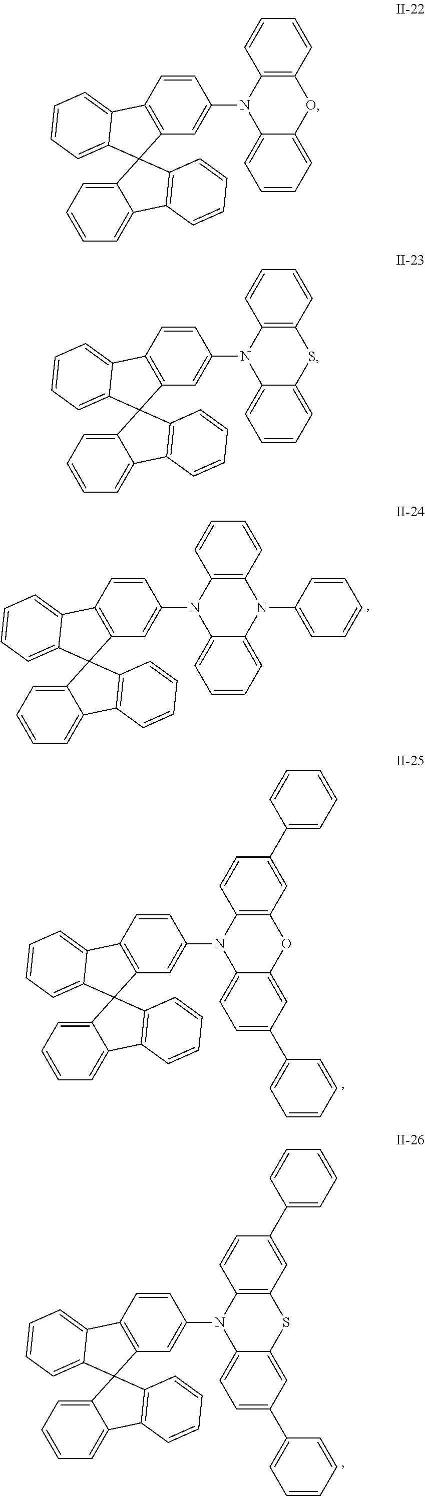

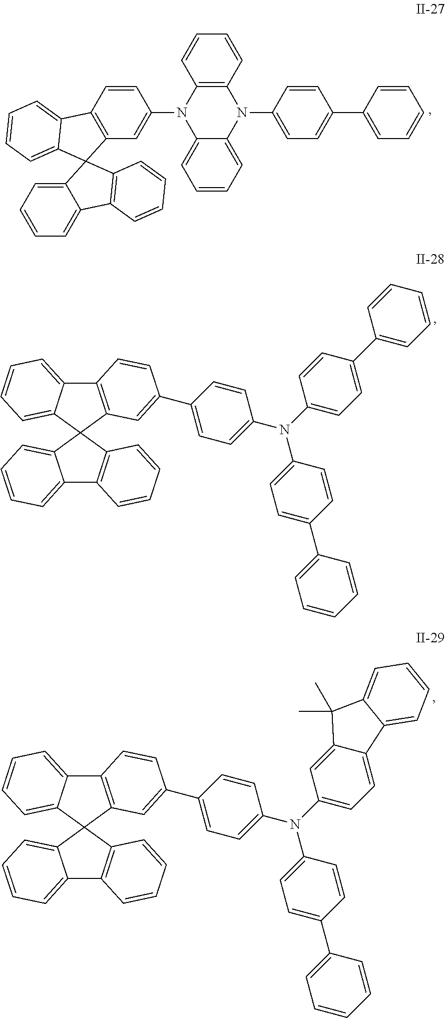 [SMILES: c1ccc(-c2ccc(N3c4ccccc4N(c4ccc5c(c4)C4(c6ccccc6-c6ccccc64)c4ccccc4-5)c4ccccc43)cc2)cc1 ; c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

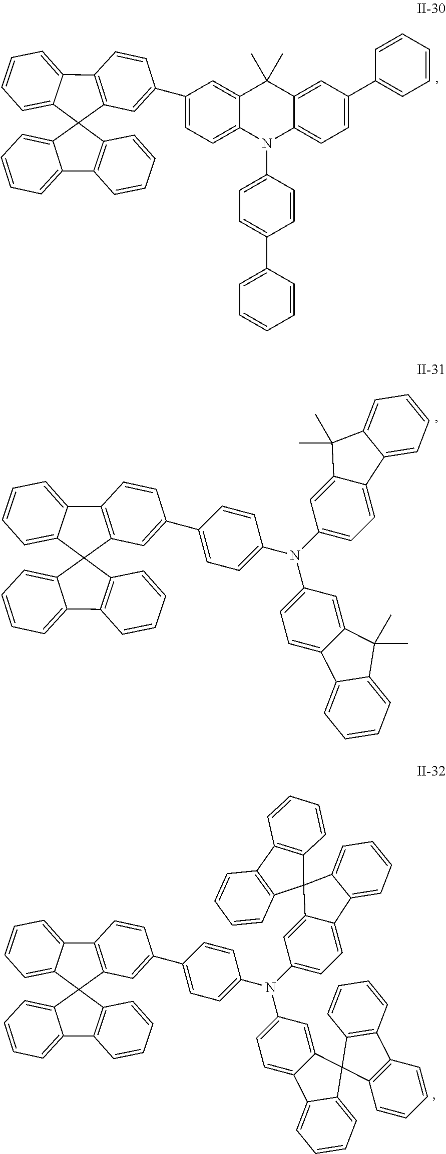 [SMILES: CC1(C)c2cc(-c3ccccc3)ccc2N(c2ccc(-c3ccccc3)cc2)c2ccc(-c3ccc4c(c3)C3(c5ccccc5-c5ccccc53)c3ccccc3-4)cc21 ; CC1(C)c2ccccc2-c2ccc(N(c3ccc(-c4ccc5c(c4)C4(c6ccccc6-c6ccccc64)c4ccccc4-5)cc3)c3ccc4c(c3)C(C)(C)c3ccccc3-4)cc21 ; c1ccc2c(c1)-c1ccccc1C21c2ccccc2-c2ccc(-c3ccc(N(c4ccc5c(c4)C4(c6ccccc6-c6ccccc64)c4ccccc4-5)c4ccc5c(c4)C4(c6ccccc6-c6ccccc64)c4ccccc4-5)cc3)cc21]

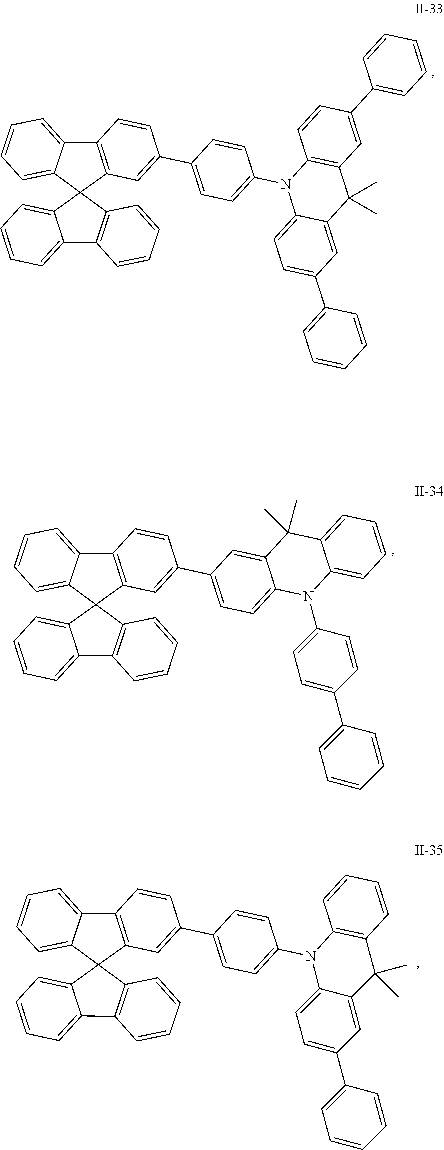 [SMILES: CC1(C)c2cc(-c3ccccc3)ccc2N(c2ccc(-c3ccc4c(c3)C3(c5ccccc5-c5ccccc53)c3ccccc3-4)cc2)c2ccc(-c3ccccc3)cc21 ; CC1(C)c2ccccc2N(c2ccc(-c3ccccc3)cc2)c2ccc(-c3ccc4c(c3)C3(c5ccccc5-c5ccccc53)c3ccccc3-4)cc21 ; CC1(C)c2ccccc2N(c2ccc(-c3ccc4c(c3)C3(c5ccccc5-c5ccccc53)c3ccccc3-4)cc2)c2ccc(-c3ccccc3)cc21]

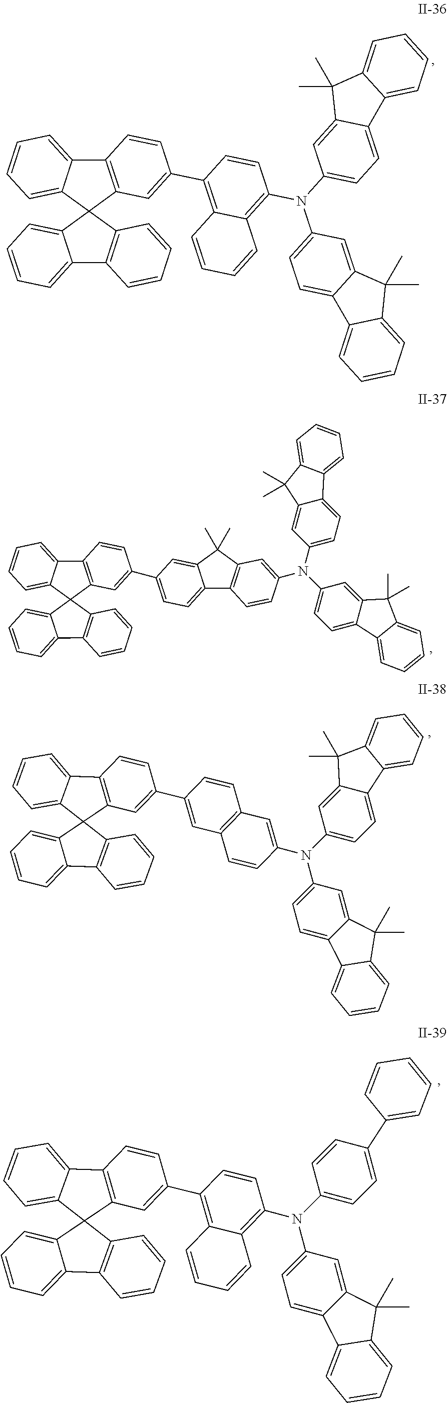 [SMILES: CC1(C)c2ccccc2-c2ccc(N(c3ccc4c(c3)C(C)(C)c3ccccc3-4)c3ccc(-c4ccc5c(c4)C4(c6ccccc6-c6ccccc64)c4ccccc4-5)c4ccccc34)cc21 ; CC1(C)c2ccccc2-c2ccc(N(c3ccc4c(c3)C(C)(C)c3ccccc3-4)c3ccc4c(c3)C(C)(C)c3cc(-c5ccc6c(c5)C5(c7ccccc7-c7ccccc75)c5ccccc5-6)ccc3-4)cc21 ; CC1(C)c2ccccc2-c2ccc(N(c3ccc4c(c3)C(C)(C)c3ccccc3-4)c3ccc4cc(-c5ccc6c(c5)C5(c7ccccc7-c7ccccc75)c5ccccc5-6)ccc4c3)cc21 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21]

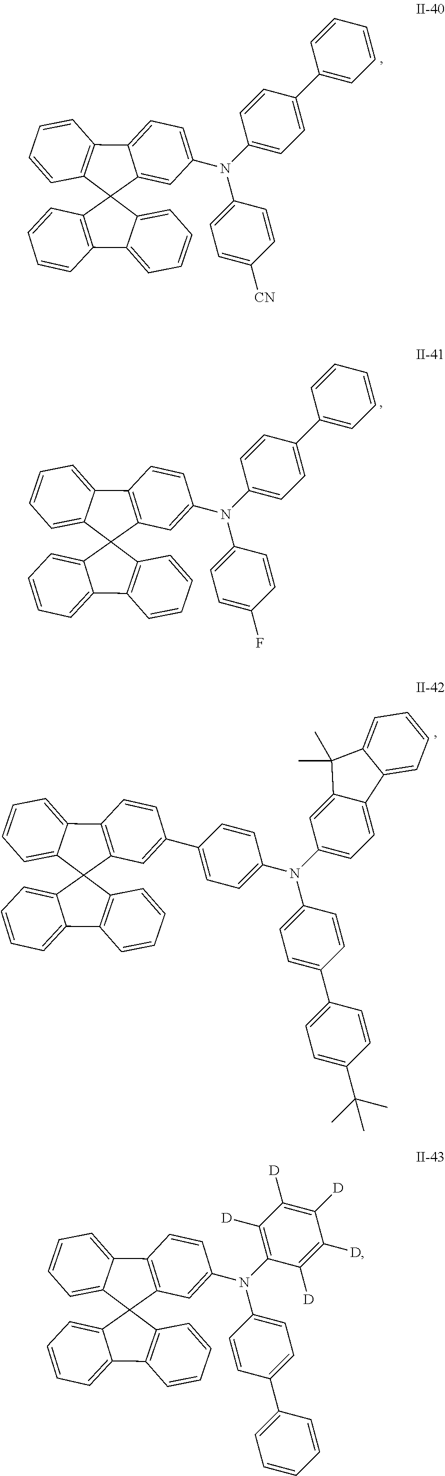

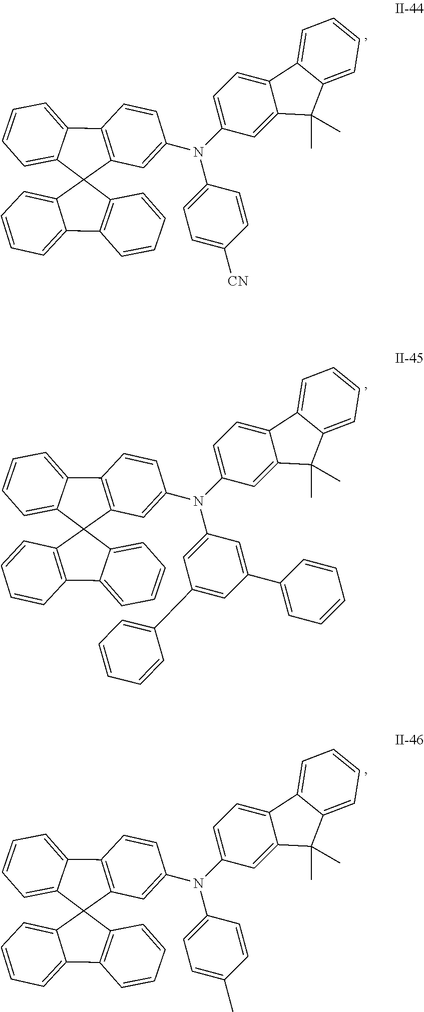 [SMILES: CC1(C)c2ccccc2-c2ccc(N(c3ccc(C#N)cc3)c3ccc4c(c3)C3(c5ccccc5-c5ccccc53)c3ccccc3-4)cc21 ; CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21 ; Cc1ccc(N(c2ccc3c(c2)C(C)(C)c2ccccc2-3)c2ccc3c(c2)C2(c4ccccc4-c4ccccc42)c2ccccc2-3)cc1]

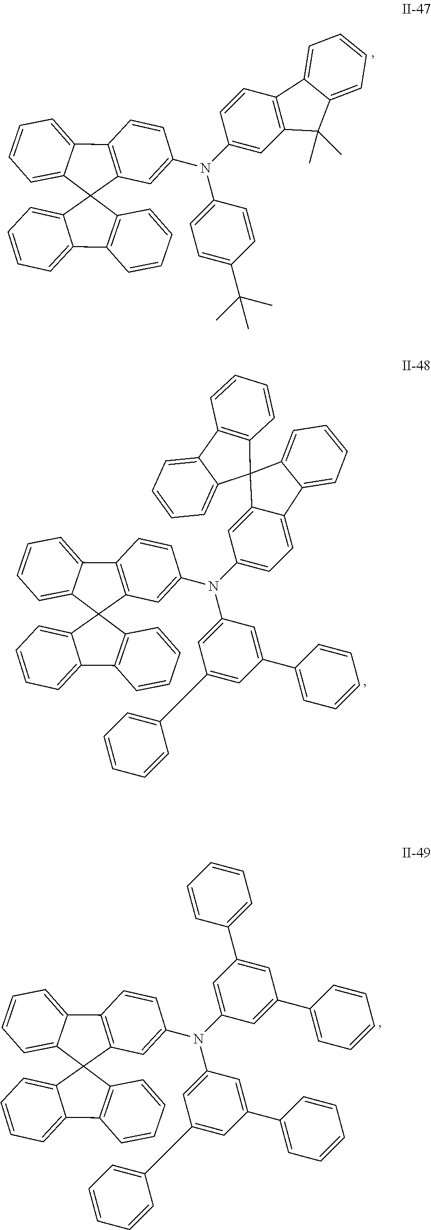 [SMILES: CC(C)(C)c1ccc(N(c2ccc3c(c2)C(C)(C)c2ccccc2-3)c2ccc3c(c2)C2(c4ccccc4-c4ccccc42)c2ccccc2-3)cc1 ; c1ccc(Cc2cc(-c3ccccc3)cc(N(c3ccc4c(c3)C3(c5ccccc5-c5ccccc53)c3ccccc3-4)c3ccc4c(c3)C3(c5ccccc5-c5ccccc53)c3ccccc3-4)c2)cc1 ; c1ccc(Cc2cc(-c3ccccc3)cc(N(c3cc(-c4ccccc4)cc(-c4ccccc4)c3)c3ccc4c(c3)C3(c5ccccc5-c5ccccc53)c3ccccc3-4)c2)cc1]

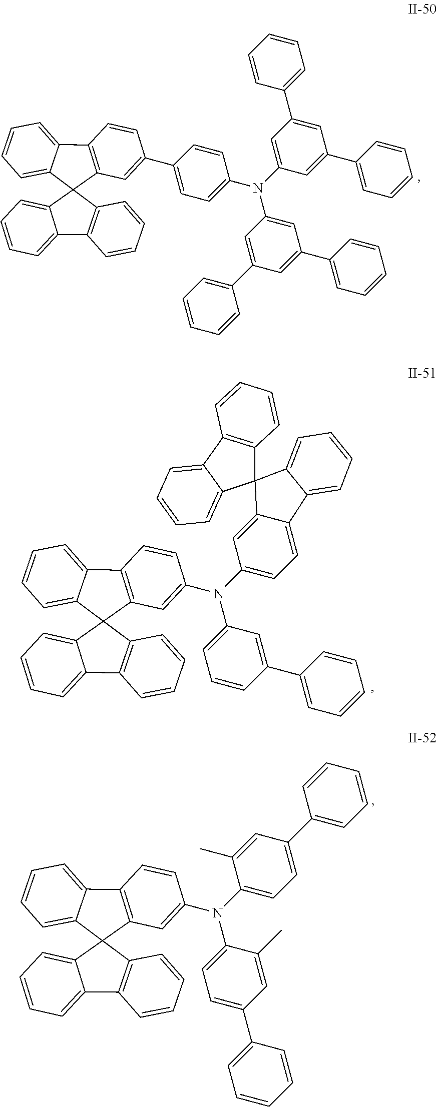 [SMILES: c1ccc(-c2cc(-c3ccccc3)cc(N(c3ccc(-c4ccc5c(c4)C4(c6ccccc6-c6ccccc64)c4ccccc4-5)cc3)c3cc(-c4ccccc4)cc(-c4ccccc4)c3)c2)cc1 ; c1ccc(-c2cccc(N(c3ccc4c(c3)C3(c5ccccc5-c5ccccc53)c3ccccc3-4)c3ccc4c(c3)C3(c5ccccc5-c5ccccc53)c3ccccc3-4)c2)cc1 ; Cc1cc(-c2ccccc2)ccc1N(c1ccc2c(c1)C1(c3ccccc3-c3ccccc31)c1ccccc1-2)c1ccc(-c2ccccc2)cc1C]

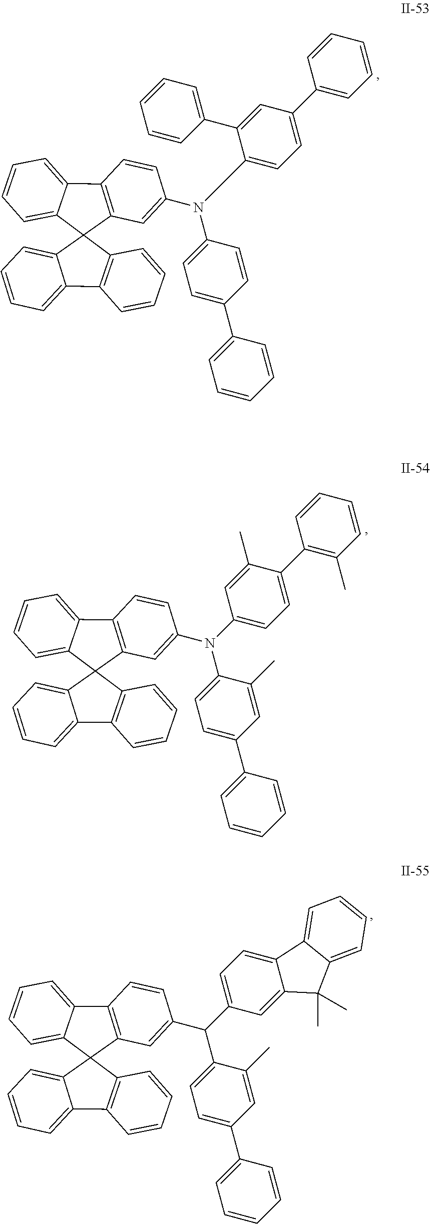

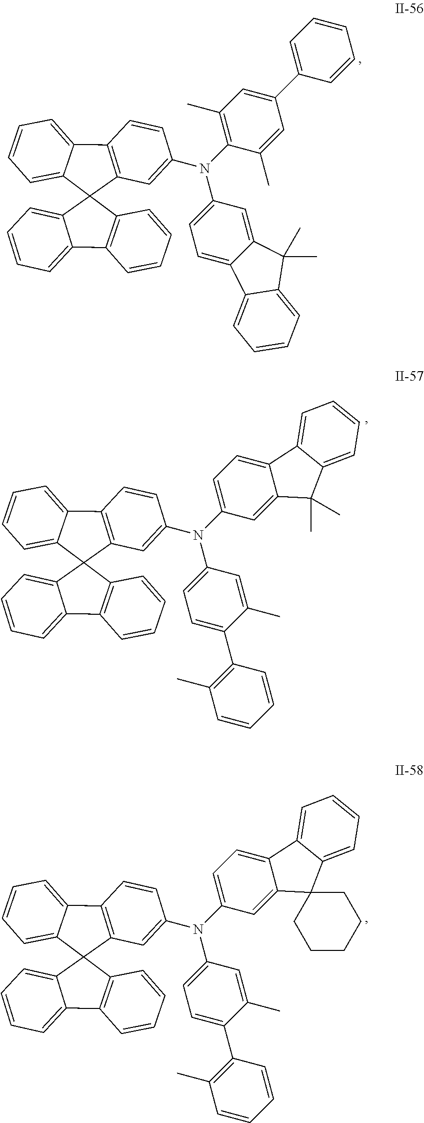 [SMILES: Cc1cc(-c2ccccc2)cc(C)c1N(c1ccc2c(c1)C(C)(C)c1ccccc1-2)c1ccc2c(c1)C1(c3ccccc3-c3ccccc31)c1ccccc1-2 ; Cc1ccccc1-c1ccc(N(c2ccc3c(c2)C(C)(C)c2ccccc2-3)c2ccc3c(c2)C2(c4ccccc4-c4ccccc42)c2ccccc2-3)cc1C ; Cc1ccccc1-c1ccc(N(c2ccc3c(c2)C2(CCCCC2)c2ccccc2-3)c2ccc3c(c2)C2(c4ccccc4-c4ccccc42)c2ccccc2-3)cc1C]

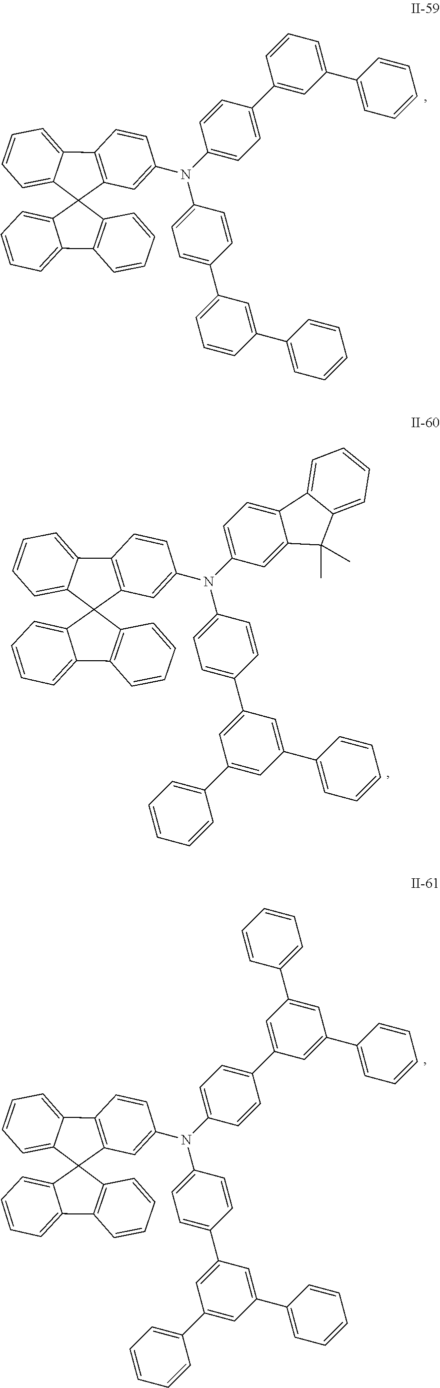 [SMILES: c1ccc(-c2cccc(-c3ccc(N(c4ccc(-c5cccc(-c6ccccc6)c5)cc4)c4ccc5c(c4)C4(c6ccccc6-c6ccccc64)c4ccccc4-5)cc3)c2)cc1 ; CC1(C)c2ccccc2-c2ccc(N(c3ccc(-c4cc(-c5ccccc5)cc(-c5ccccc5)c4)cc3)c3ccc4c(c3)C3(c5ccccc5-c5ccccc53)c3ccccc3-4)cc21 ; c1ccc(-c2cc(-c3ccccc3)cc(-c3ccc(N(c4ccc(-c5cc(-c6ccccc6)cc(-c6ccccc6)c5)cc4)c4ccc5c(c4)C4(c6ccccc6-c6ccccc64)c4ccccc4-5)cc3)c2)cc1]

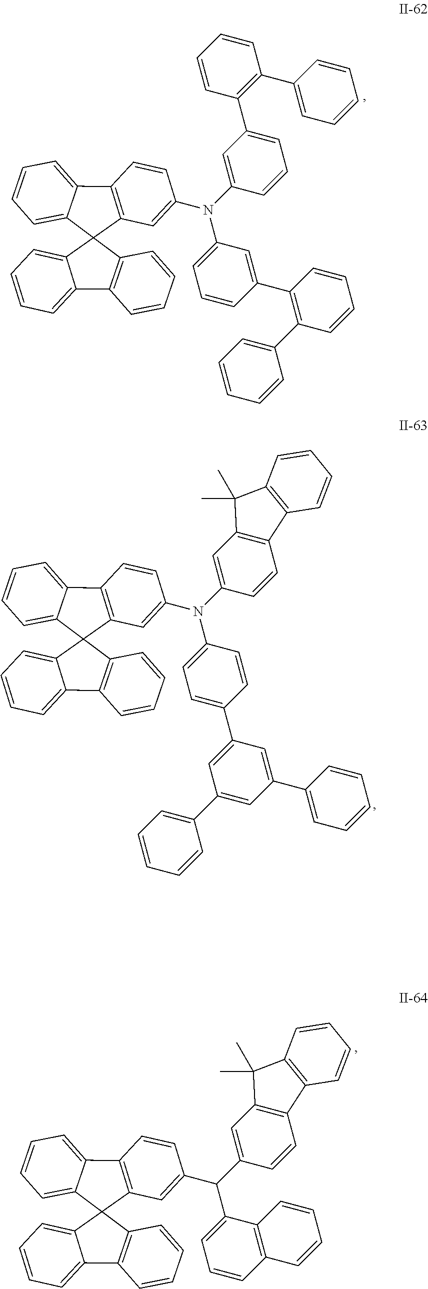

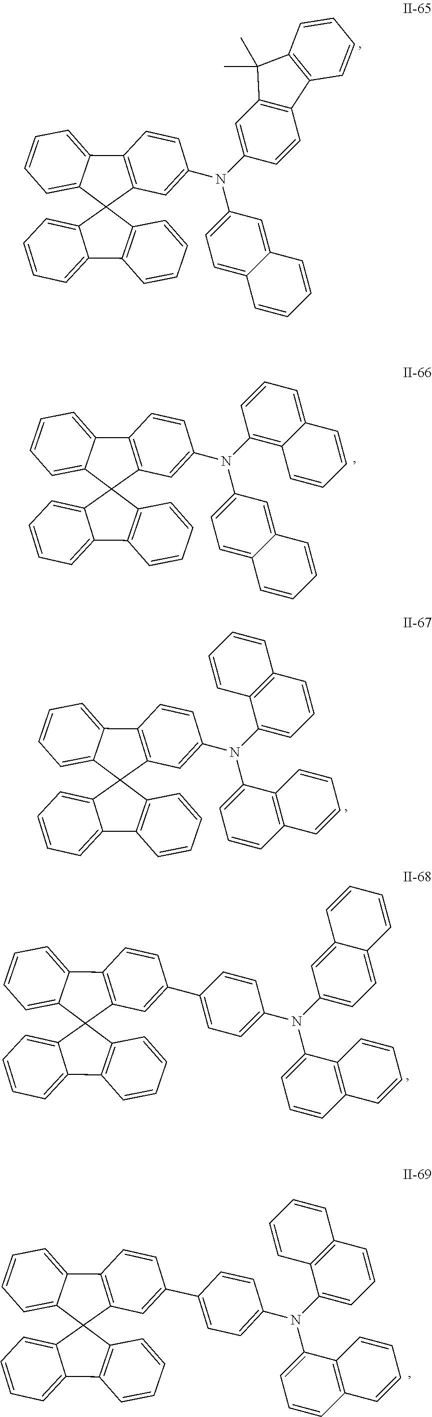 [SMILES: CC1(C)c2ccccc2-c2ccc(N(c3ccc4c(c3)C3(c5ccccc5-c5ccccc53)c3ccccc3-4)c3ccc4ccccc4c3)cc21 ; c1ccc2c(c1)-c1ccccc1C21c2ccccc2-c2ccc(N(c3ccc4ccccc4c3)c3cccc4ccccc34)cc21 ; c1ccc2c(c1)-c1ccccc1C21c2ccccc2-c2ccc(N(c3cccc4ccccc34)c3cccc4ccccc34)cc21 ; c1ccc2c(c1)-c1ccccc1C21c2ccccc2-c2ccc(-c3ccc(N(c4ccc5ccccc5c4)c4cccc5ccccc45)cc3)cc21 ; c1ccc2c(c1)-c1ccccc1C21c2ccccc2-c2ccc(-c3ccc(N(c4cccc5ccccc45)c4cccc5ccccc45)cc3)cc21]

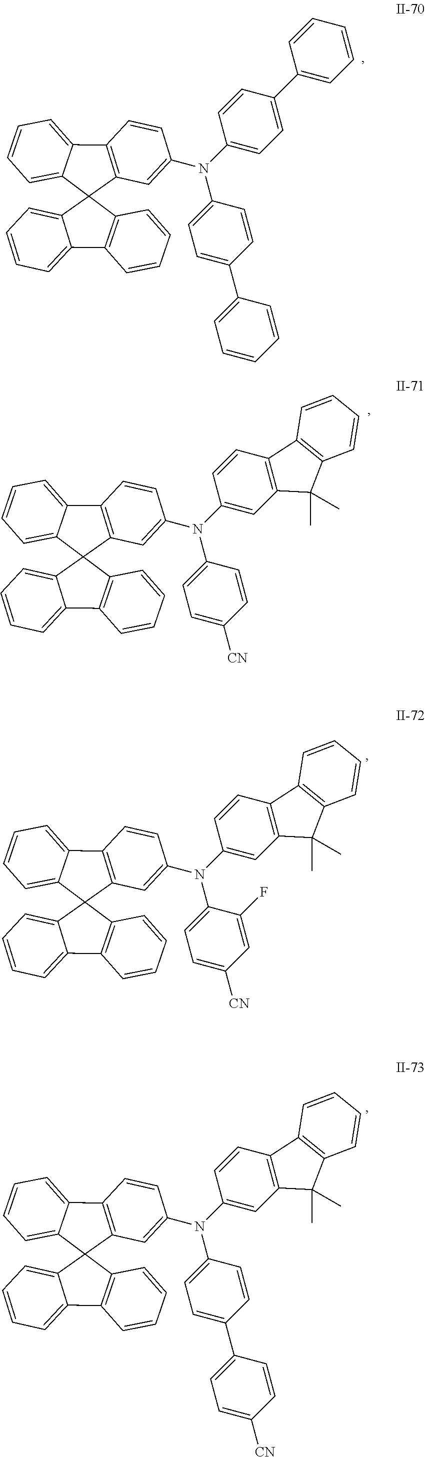 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(C#N)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccc(C#N)cc3F)cc21 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21]

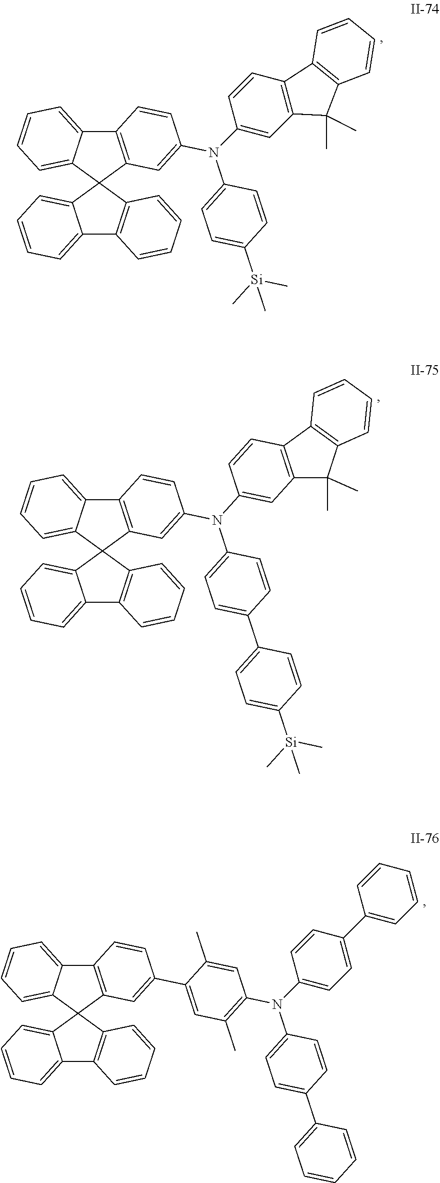 [SMILES: CC1(C)c2ccccc2-c2ccc(N(c3ccc([Si](C)(C)C)cc3)c3ccc4c(c3)C3(c5ccccc5-c5ccccc53)c3ccccc3-4)cc21 ; CC1(C)c2ccccc2-c2ccc(N(c3ccc(-c4ccc([Si](C)(C)C)cc4)cc3)c3ccc4c(c3)C3(c5ccccc5-c5ccccc53)c3ccccc3-4)cc21 ; Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2]

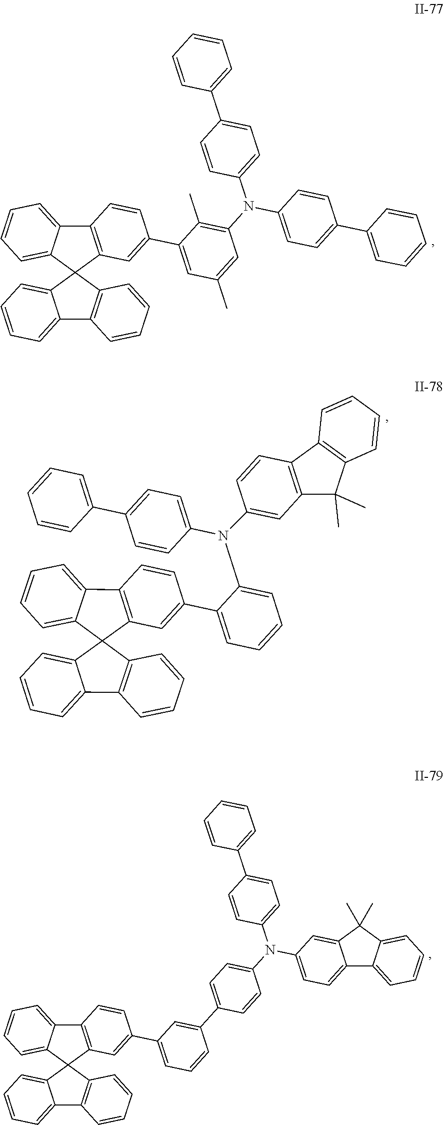 [SMILES: Cc1cc(-c2ccc3c(c2)C2(c4ccccc4-c4ccccc42)c2ccccc2-3)c(C)c(N(c2ccc(-c3ccccc3)cc2)c2ccc(-c3ccccc3)cc2)c1 ; CC1(C)c2ccccc2-c2ccc(N(c3ccc(-c4ccccc4)cc3)c3ccccc3-c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc(-c4cccc(-c5ccc6c(c5)C5(c7ccccc7-c7ccccc75)c5ccccc5-6)c4)cc3)cc21]

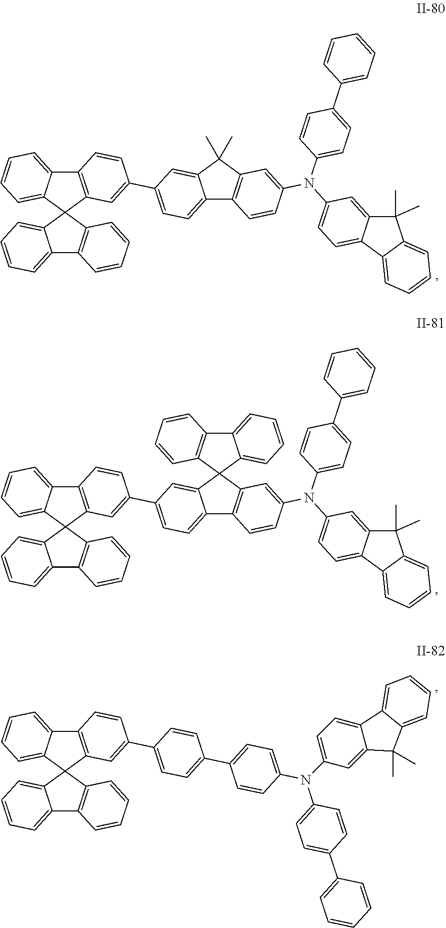 [SMILES: CC1(C)c2ccccc2-c2ccc(N(c3ccc(-c4ccccc4)cc3)c3ccc4c(c3)C(C)(C)c3cc(-c5ccc6c(c5)C5(c7ccccc7-c7ccccc75)c5ccccc5-6)ccc3-4)cc21 ; CC1(C)c2ccccc2-c2ccc(N(c3ccc(-c4ccccc4)cc3)c3ccc4c(c3)C3(c5ccccc5-c5ccccc53)c3cc(-c5ccc6c(c5)C5(c7ccccc7-c7ccccc75)c5ccccc5-6)ccc3-4)cc21 ; CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21]

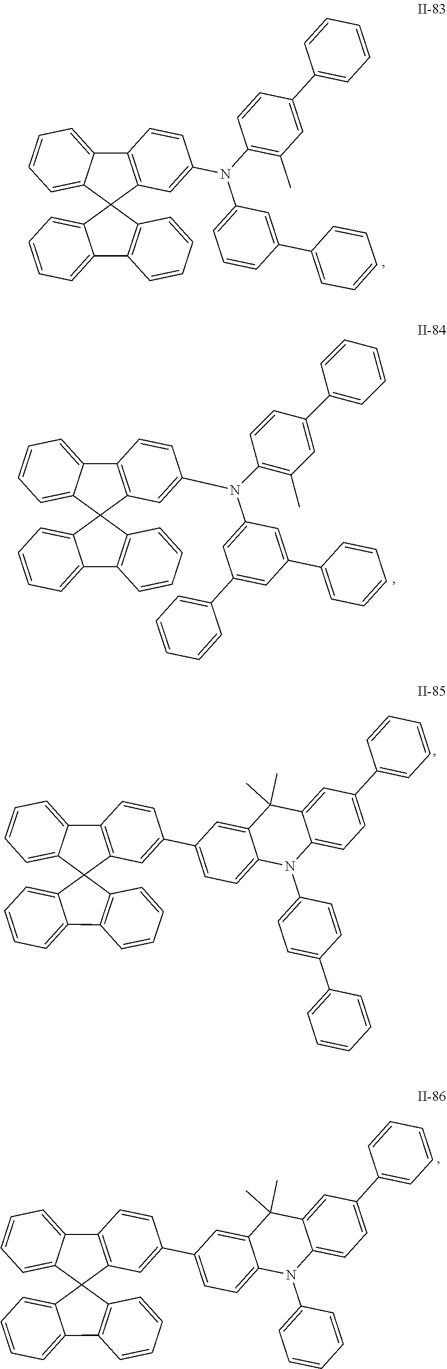 [SMILES: Cc1cc(-c2ccccc2)ccc1N(c1cccc(-c2ccccc2)c1)c1ccc2c(c1)C1(c3ccccc3-c3ccccc31)c1ccccc1-2 ; Cc1cc(-c2ccccc2)ccc1N(c1cc(-c2ccccc2)cc(-c2ccccc2)c1)c1ccc2c(c1)C1(c3ccccc3-c3ccccc31)c1ccccc1-2 ; CC1(C)c2cc(-c3ccccc3)ccc2N(c2ccc(-c3ccccc3)cc2)c2ccc(-c3ccc4c(c3)C3(c5ccccc5-c5ccccc53)c3ccccc3-4)cc21 ; CC1(C)c2cc(-c3ccccc3)ccc2N(c2ccccc2)c2ccc(-c3ccc4c(c3)C3(c5ccccc5-c5ccccc53)c3ccccc3-4)cc21]

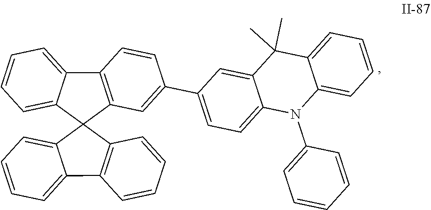 [SMILES: CC1(C)c2ccccc2N(c2ccccc2)c2ccc(-c3ccc4c(c3)C3(c5ccccc5-c5ccccc53)c3ccccc3-4)cc21]

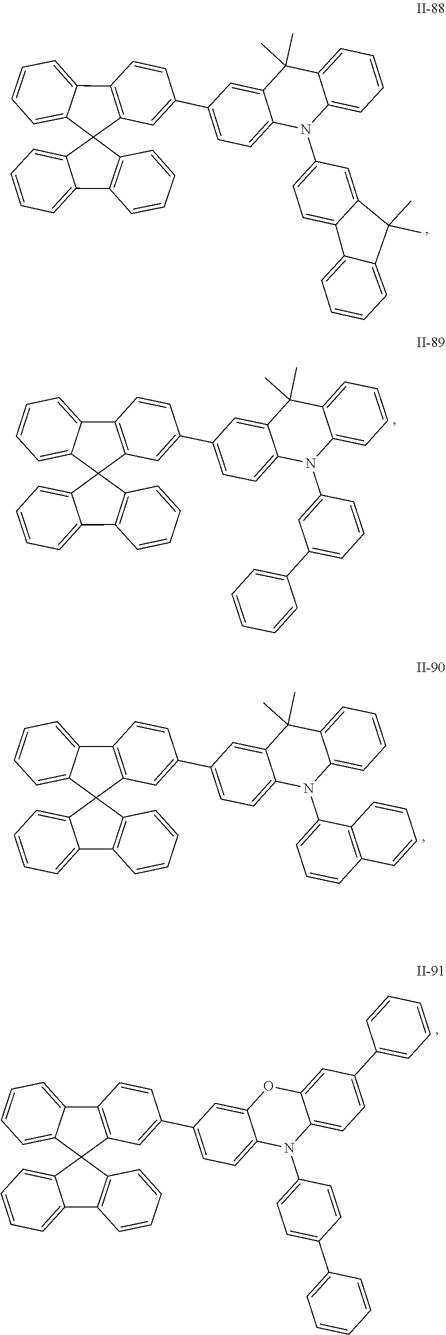 [SMILES: CC1(C)c2ccccc2-c2ccc(N3c4ccccc4C(C)(C)c4cc(-c5ccc6c(c5)C5(c7ccccc7-c7ccccc75)c5ccccc5-6)ccc43)cc21 ; CC1(C)c2ccccc2N(c2cccc(-c3ccccc3)c2)c2ccc(-c3ccc4c(c3)C3(c5ccccc5-c5ccccc53)c3ccccc3-4)cc21 ; CC1(C)c2ccccc2N(c2cccc3ccccc23)c2ccc(-c3ccc4c(c3)C3(c5ccccc5-c5ccccc53)c3ccccc3-4)cc21 ; c1ccc(-c2ccc(N3c4ccc(-c5ccccc5)cc4Oc4cc(-c5ccc6c(c5)C5(c7ccccc7-c7ccccc75)c5ccccc5-6)ccc43)cc2)cc1]

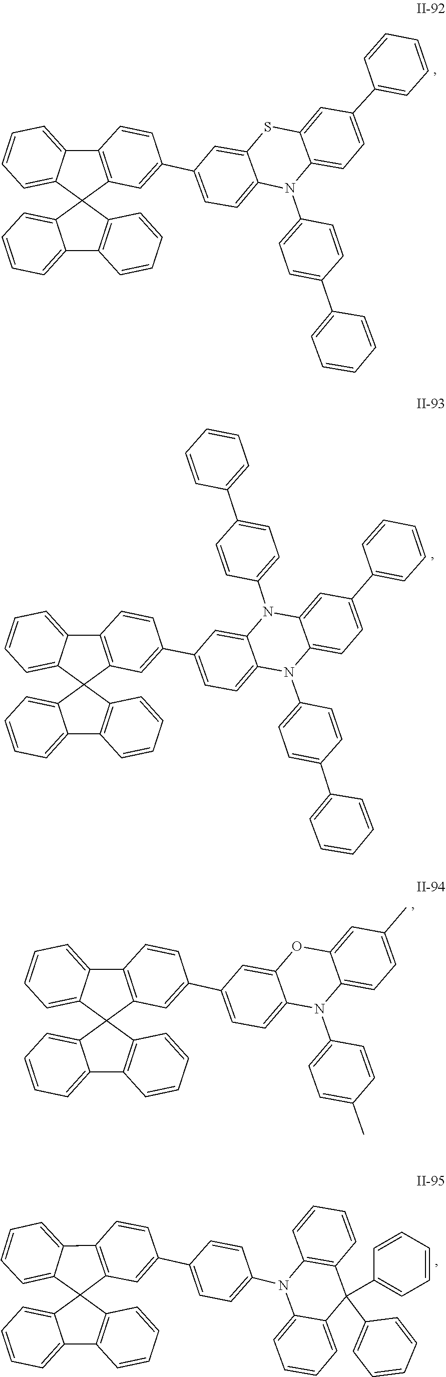 [SMILES: c1ccc(-c2ccc(N3c4ccc(-c5ccccc5)cc4Sc4cc(-c5ccc6c(c5)C5(c7ccccc7-c7ccccc75)c5ccccc5-6)ccc43)cc2)cc1 ; c1ccc(-c2ccc(N3c4ccc(-c5ccccc5)cc4N(c4ccc(-c5ccccc5)cc4)c4cc(-c5ccc6c(c5)C5(c7ccccc7-c7ccccc75)c5ccccc5-6)ccc43)cc2)cc1 ; Cc1ccc(N2c3ccc(C)cc3Oc3cc(-c4ccc5c(c4)C4(c6ccccc6-c6ccccc64)c4ccccc4-5)ccc32)cc1 ; c1ccc(C2(c3ccccc3)c3ccccc3N(c3ccc(-c4ccc5c(c4)C4(c6ccccc6-c6ccccc64)c4ccccc4-5)cc3)c3ccccc32)cc1]

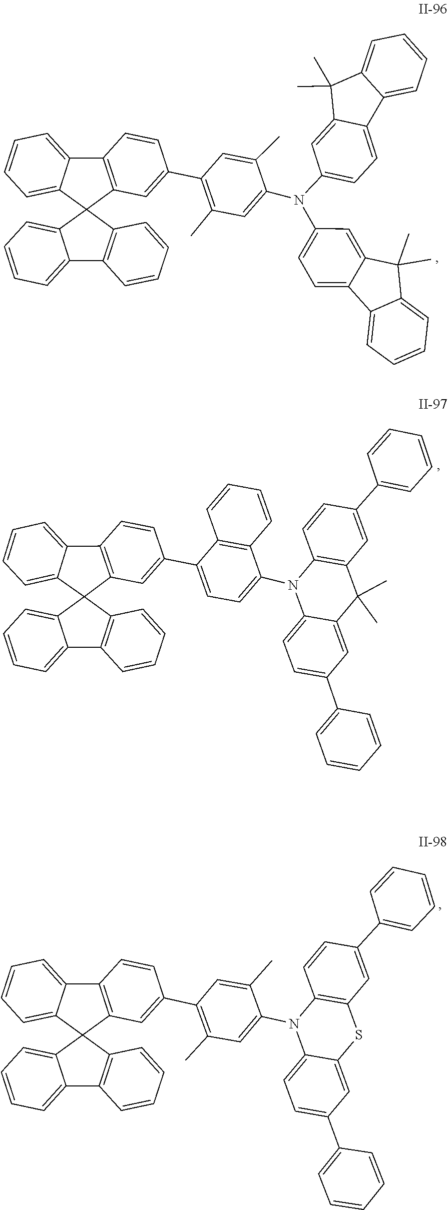 [SMILES: Cc1cc(N(c2ccc3c(c2)C(C)(C)c2ccccc2-3)c2ccc3c(c2)C(C)(C)c2ccccc2-3)c(C)cc1-c1ccc2c(c1)C1(c3ccccc3-c3ccccc31)c1ccccc1-2 ; CC1(C)c2cc(-c3ccccc3)ccc2N(c2ccc(-c3ccc4c(c3)C3(c5ccccc5-c5ccccc53)c3ccccc3-4)c3ccccc23)c2ccc(-c3ccccc3)cc21 ; Cc1cc(N2c3ccc(-c4ccccc4)cc3Sc3cc(-c4ccccc4)ccc32)c(C)cc1-c1ccc2c(c1)C1(c3ccccc3-c3ccccc31)c1ccccc1-2]

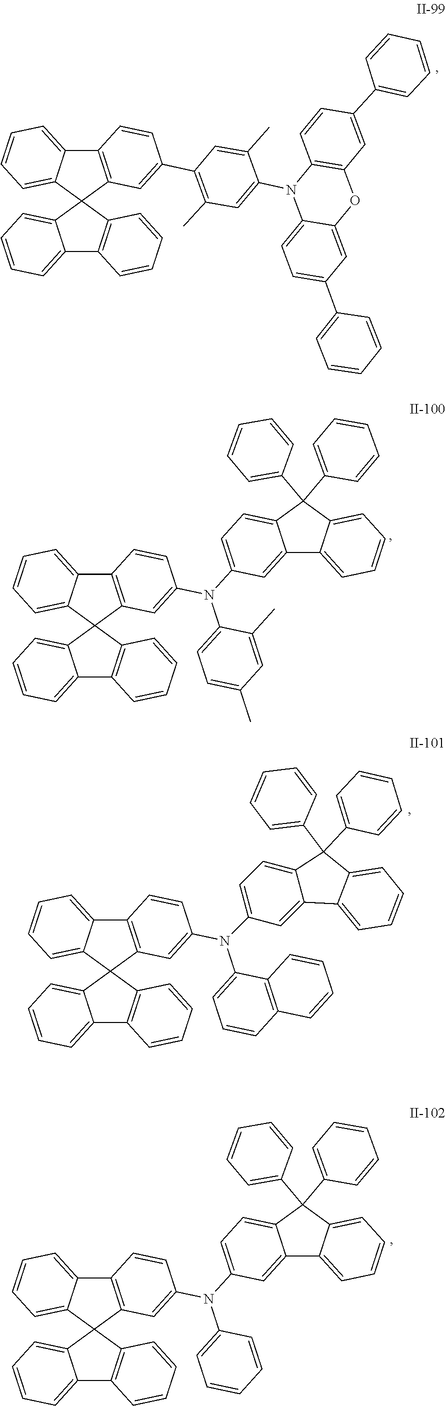 [SMILES: Cc1cc(N2c3ccc(-c4ccccc4)cc3Oc3cc(-c4ccccc4)ccc32)c(C)cc1-c1ccc2c(c1)C1(c3ccccc3-c3ccccc31)c1ccccc1-2 ; Cc1ccc(N(c2ccc3c(c2)-c2ccccc2C3(c2ccccc2)c2ccccc2)c2ccc3c(c2)C2(c4ccccc4-c4ccccc42)c2ccccc2-3)c(C)c1 ; c1ccc(C2(c3ccccc3)c3ccccc3-c3cc(N(c4ccc5c(c4)C4(c6ccccc6-c6ccccc64)c4ccccc4-5)c4cccc5ccccc45)ccc32)cc1 ; c1ccc(N(c2ccc3c(c2)-c2ccccc2C3(c2ccccc2)c2ccccc2)c2ccc3c(c2)C2(c4ccccc4-c4ccccc42)c2ccccc2-3)cc1]

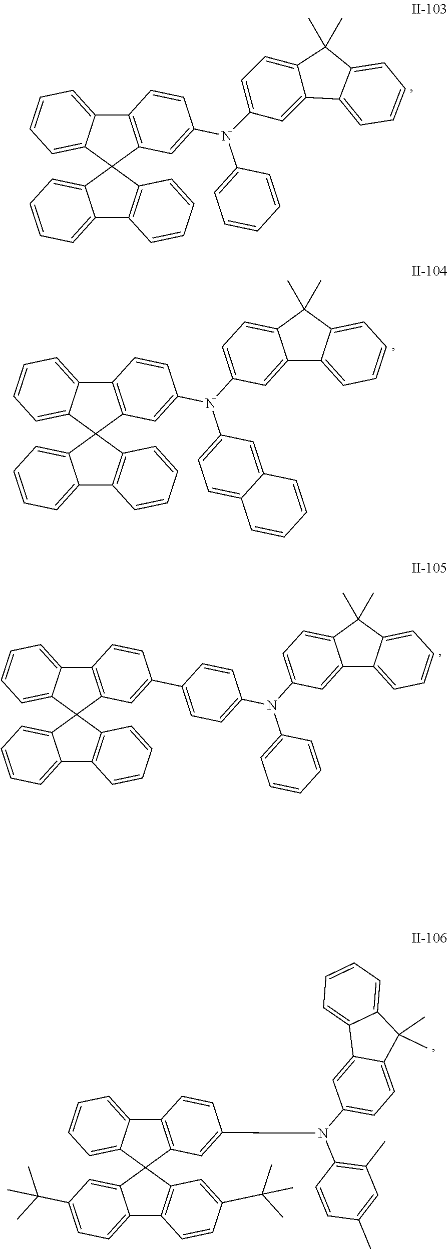 [SMILES: CC1(C)c2ccccc2-c2cc(N(c3ccccc3)c3ccc4c(c3)C3(c5ccccc5-c5ccccc53)c3ccccc3-4)ccc21 ; CC1(C)c2ccccc2-c2cc(N(c3ccc4c(c3)C3(c5ccccc5-c5ccccc53)c3ccccc3-4)c3ccc4ccccc4c3)ccc21 ; CC1(C)c2ccccc2-c2cc(N(c3ccccc3)c3ccc(-c4ccc5c(c4)C4(c6ccccc6-c6ccccc64)c4ccccc4-5)cc3)ccc21 ; Cc1ccc(N(c2ccc3c(c2)-c2ccccc2C3(C)C)c2ccc3c(c2)C2(c4ccccc4-3)c3cc(C(C)(C)C)ccc3-c3ccc(C(C)(C)C)cc32)c(C)c1]

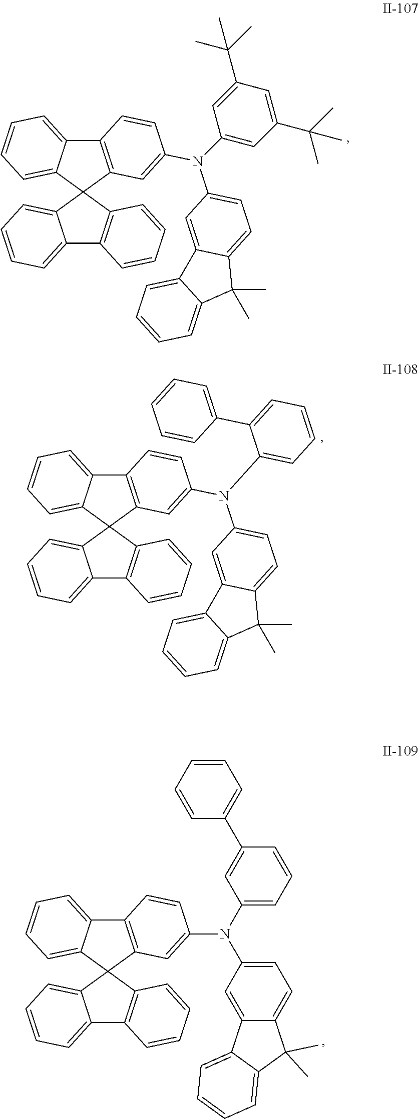

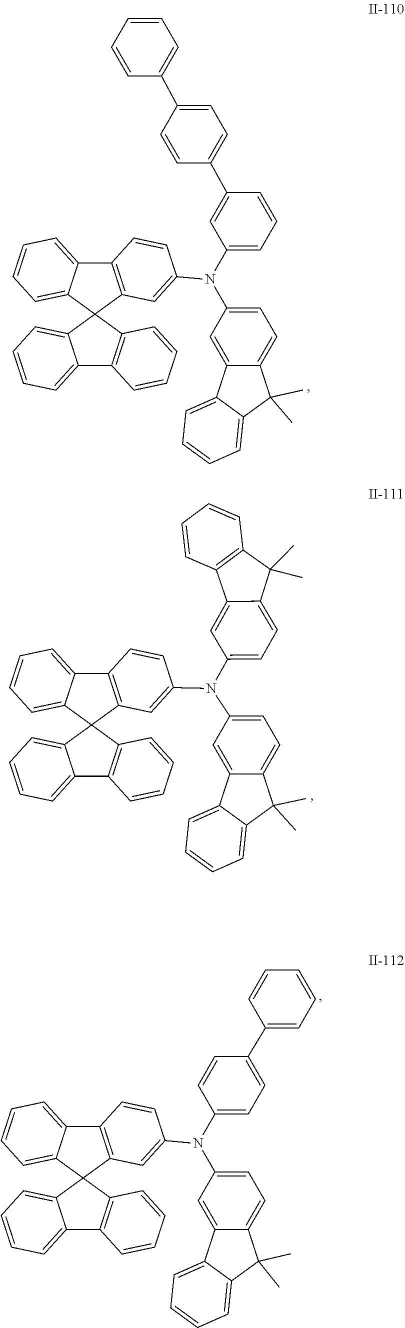

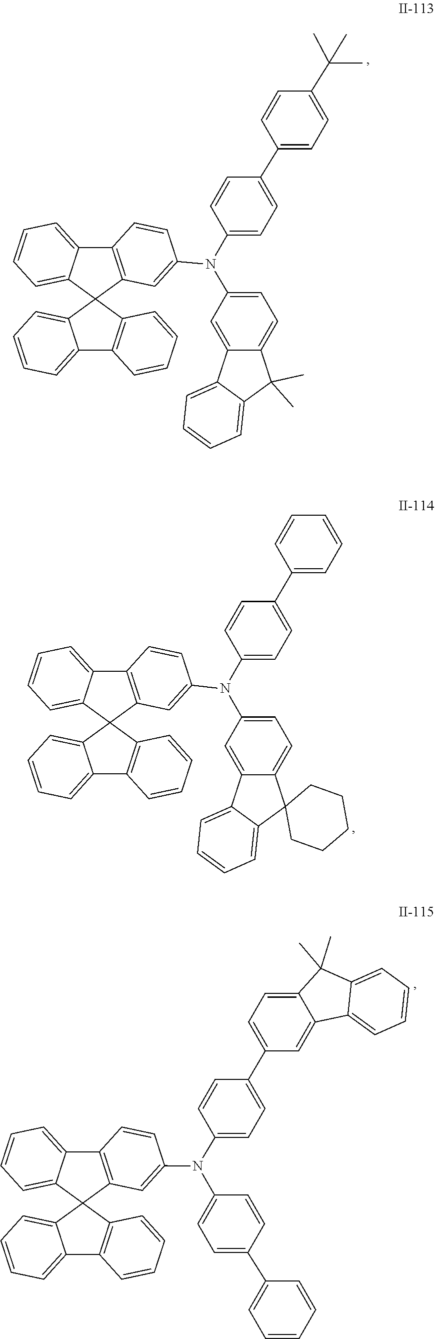 [SMILES: CC(C)(C)c1ccc(-c2ccc(N(c3ccc4c(c3)-c3ccccc3C4(C)C)c3ccc4c(c3)C3(c5ccccc5-c5ccccc53)c3ccccc3-4)cc2)cc1 ; c1ccc(-c2ccc(N(c3ccc4c(c3)-c3ccccc3C43CCCCC3)c3ccc4c(c3)C3(c5ccccc5-c5ccccc53)c3ccccc3-4)cc2)cc1 ; CC1(C)c2ccccc2-c2cc(-c3ccc(N(c4ccc(-c5ccccc5)cc4)c4ccc5c(c4)C4(c6ccccc6-c6ccccc64)c4ccccc4-5)cc3)ccc21]

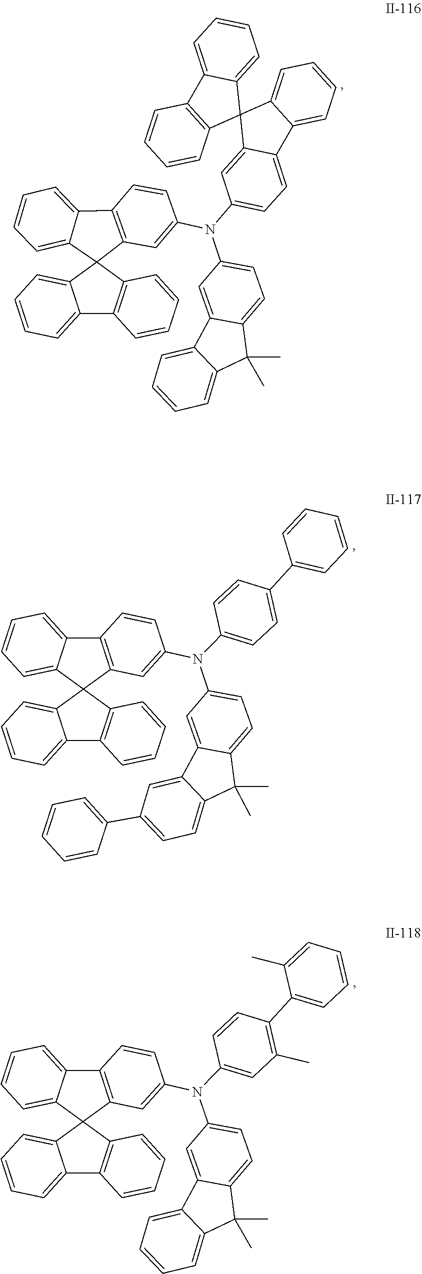 [SMILES: CC1(C)c2ccccc2-c2cc(N(c3ccc4c(c3)C3(c5ccccc5-c5ccccc53)c3ccccc3-4)c3ccc4c(c3)C3(c5ccccc5-c5ccccc53)c3ccccc3-4)ccc21 ; CC1(C)c2ccc(-c3ccccc3)cc2-c2cc(N(c3ccc(-c4ccccc4)cc3)c3ccc4c(c3)C3(c5ccccc5-c5ccccc53)c3ccccc3-4)ccc21 ; Cc1ccccc1-c1ccc(N(c2ccc3c(c2)-c2ccccc2C3(C)C)c2ccc3c(c2)C2(c4ccccc4-c4ccccc42)c2ccccc2-3)cc1C]

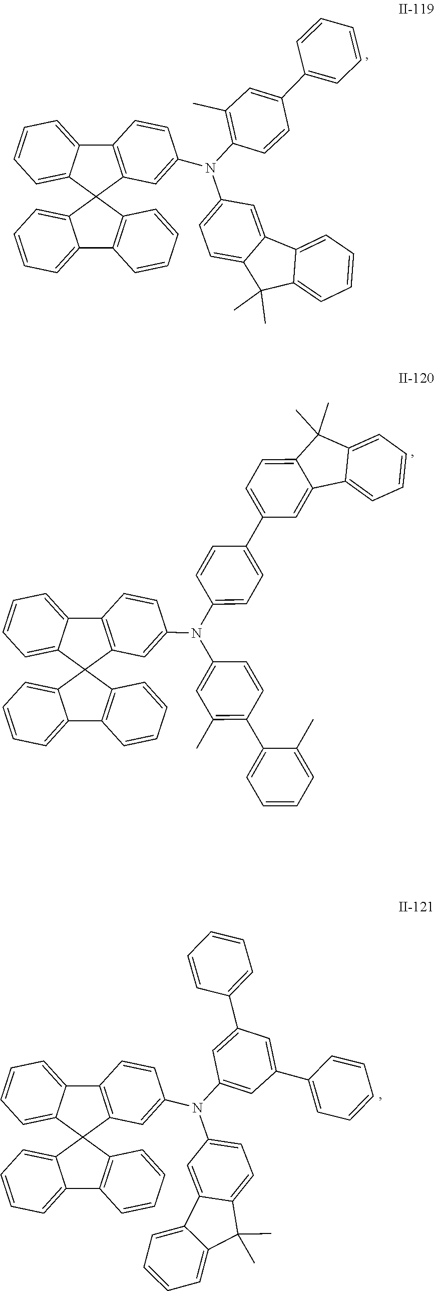 [SMILES: Cc1cc(-c2ccccc2)ccc1N(c1ccc2c(c1)-c1ccccc1C2(C)C)c1ccc2c(c1)C1(c3ccccc3-c3ccccc31)c1ccccc1-2 ; Cc1ccccc1-c1ccc(N(c2ccc(-c3ccc4c(c3)-c3ccccc3C4(C)C)cc2)c2ccc3c(c2)C2(c4ccccc4-c4ccccc42)c2ccccc2-3)cc1C ; CC1(C)c2ccccc2-c2cc(N(c3cc(-c4ccccc4)cc(-c4ccccc4)c3)c3ccc4c(c3)C3(c5ccccc5-c5ccccc53)c3ccccc3-4)ccc21]

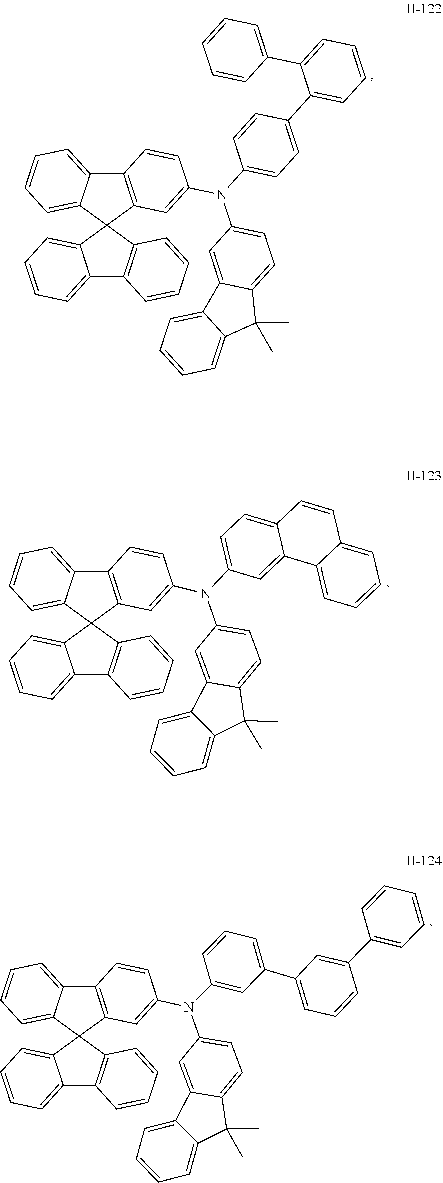 [SMILES: CC1(C)c2ccccc2-c2cc(N(c3ccc(-c4ccccc4-c4ccccc4)cc3)c3ccc4c(c3)C3(c5ccccc5-c5ccccc53)c3ccccc3-4)ccc21 ; CC1(C)c2ccccc2-c2cc(N(c3ccc4c(c3)C3(c5ccccc5-c5ccccc53)c3ccccc3-4)c3ccc4ccc5ccccc5c4c3)ccc21 ; CC1(C)c2ccccc2-c2cc(N(c3cccc(-c4cccc(-c5ccccc5)c4)c3)c3ccc4c(c3)C3(c5ccccc5-c5ccccc53)c3ccccc3-4)ccc21]

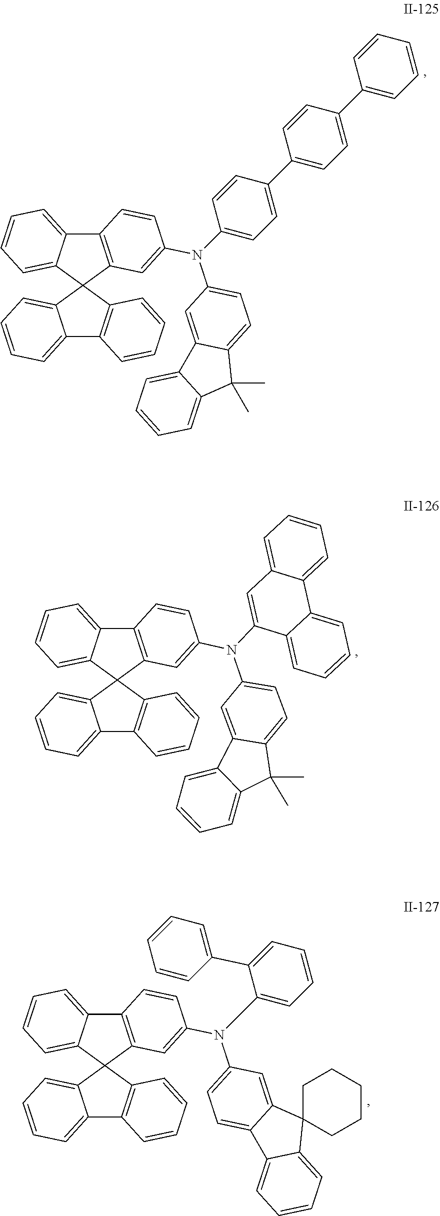 [SMILES: CC1(C)c2ccccc2-c2cc(N(c3ccc(-c4ccc(-c5ccccc5)cc4)cc3)c3ccc4c(c3)C3(c5ccccc5-c5ccccc53)c3ccccc3-4)ccc21 ; CC1(C)c2ccccc2-c2cc(N(c3ccc4c(c3)C3(c5ccccc5-c5ccccc53)c3ccccc3-4)c3cc4ccccc4c4ccccc34)ccc21 ; c1ccc(-c2ccccc2N(c2ccc3c(c2)C2(CCCCC2)c2ccccc2-3)c2ccc3c(c2)C2(c4ccccc4-c4ccccc42)c2ccccc2-3)cc1]

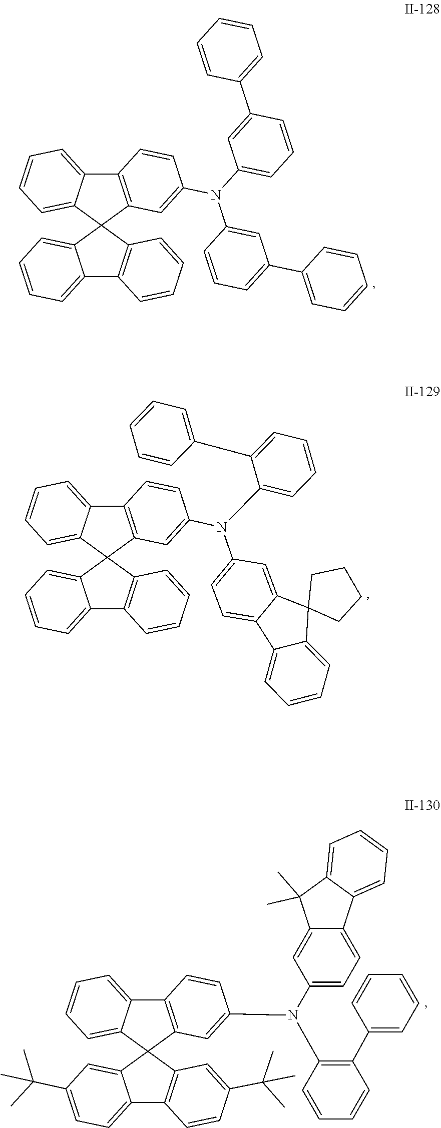 [SMILES: c1ccc(-c2cccc(N(c3cccc(-c4ccccc4)c3)c3ccc4c(c3)C3(c5ccccc5-c5ccccc53)c3ccccc3-4)c2)cc1 ; c1ccc(-c2ccccc2N(c2ccc3c(c2)C2(CCCC2)c2ccccc2-3)c2ccc3c(c2)C2(c4ccccc4-c4ccccc42)c2ccccc2-3)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

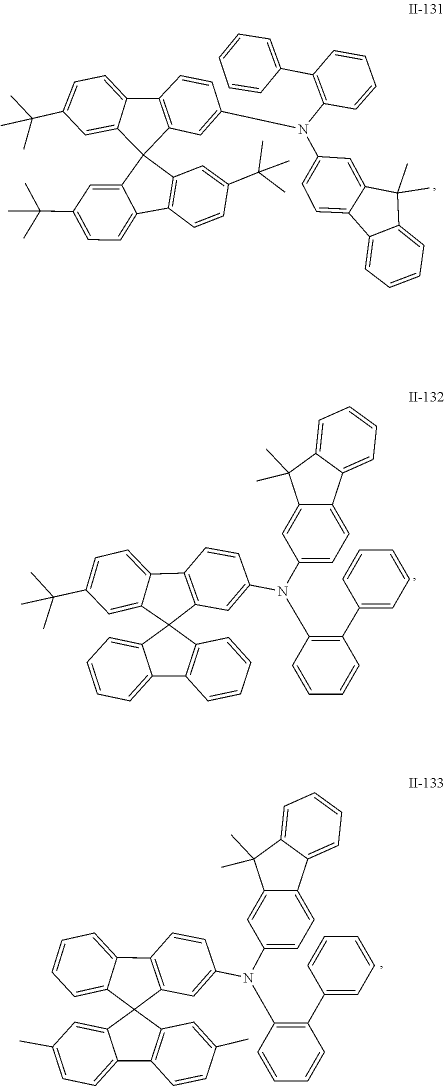

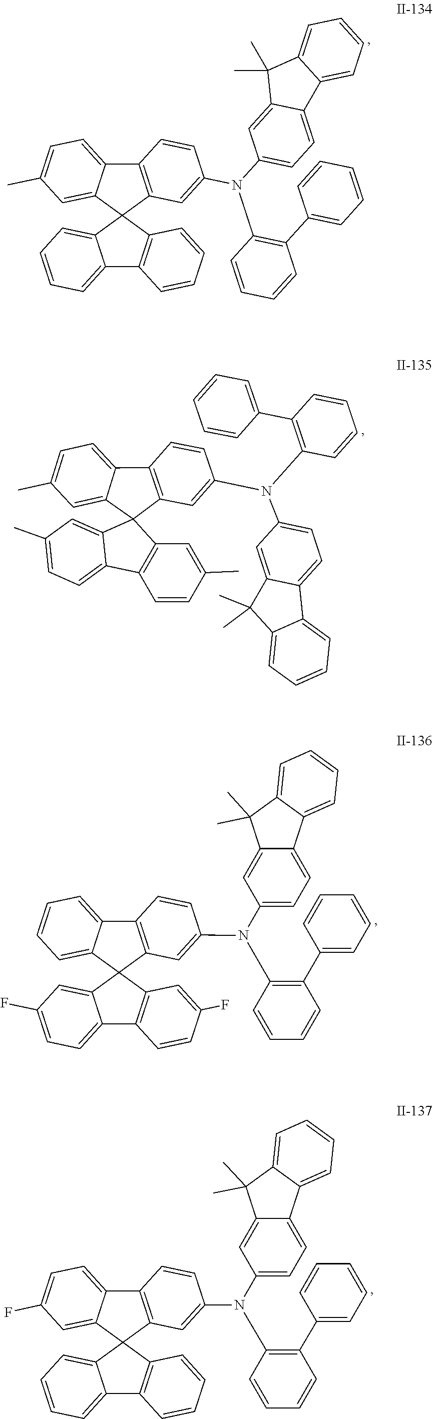 [SMILES: Cc1ccc2c(c1)C1(c3ccccc3-c3ccccc31)c1cc(N(c3ccc4c(c3)C(C)(C)c3ccccc3-4)c3ccccc3-c3ccccc3)ccc1-2 ; Cc1ccc2c(c1)C1(c3cc(C)ccc3-2)c2cc(C)ccc2-c2ccc(N(c3ccc4c(c3)C(C)(C)c3ccccc3-4)c3ccccc3-c3ccccc3)cc21 ; CC1(C)c2ccccc2-c2ccc(N(c3ccc4c(c3)C3(c5ccccc5-4)c4cc(F)ccc4-c4ccc(F)cc43)c3ccccc3-c3ccccc3)cc21 ; CC1(C)c2ccccc2-c2ccc(N(c3ccc4c(c3)C3(c5ccccc5-c5ccccc53)c3cc(F)ccc3-4)c3ccccc3-c3ccccc3)cc21]

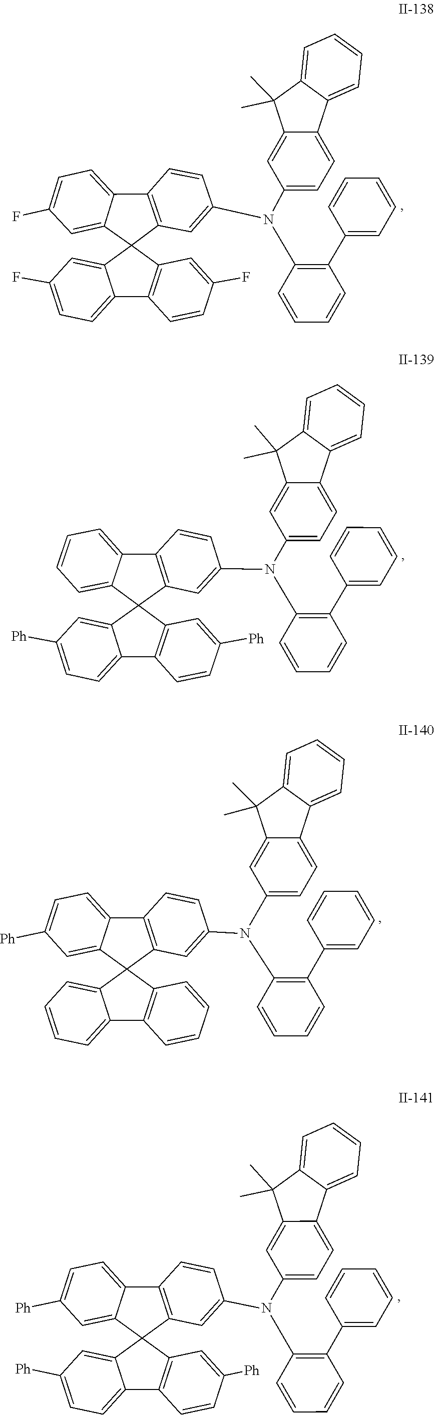 [SMILES: CC1(C)c2ccccc2-c2ccc(N(c3ccc4c(c3)C3(c5cc(F)ccc5-c5ccc(F)cc53)c3cc(F)ccc3-4)c3ccccc3-c3ccccc3)cc21 ; CC1(C)c2ccccc2-c2ccc(N(c3ccc4c(c3)C3(c5ccccc5-4)c4cc(-c5ccccc5)ccc4-c4ccc(-c5ccccc5)cc43)c3ccccc3-c3ccccc3)cc21 ; CC1(C)c2ccccc2-c2ccc(N(c3ccc4c(c3)C3(c5ccccc5-c5ccccc53)c3cc(-c5ccccc5)ccc3-4)c3ccccc3-c3ccccc3)cc21 ; CC1(C)c2ccccc2-c2ccc(N(c3ccc4c(c3)C3(c5cc(-c6ccccc6)ccc5-c5ccc(-c6ccccc6)cc53)c3cc(-c5ccccc5)ccc3-4)c3ccccc3-c3ccccc3)cc21]

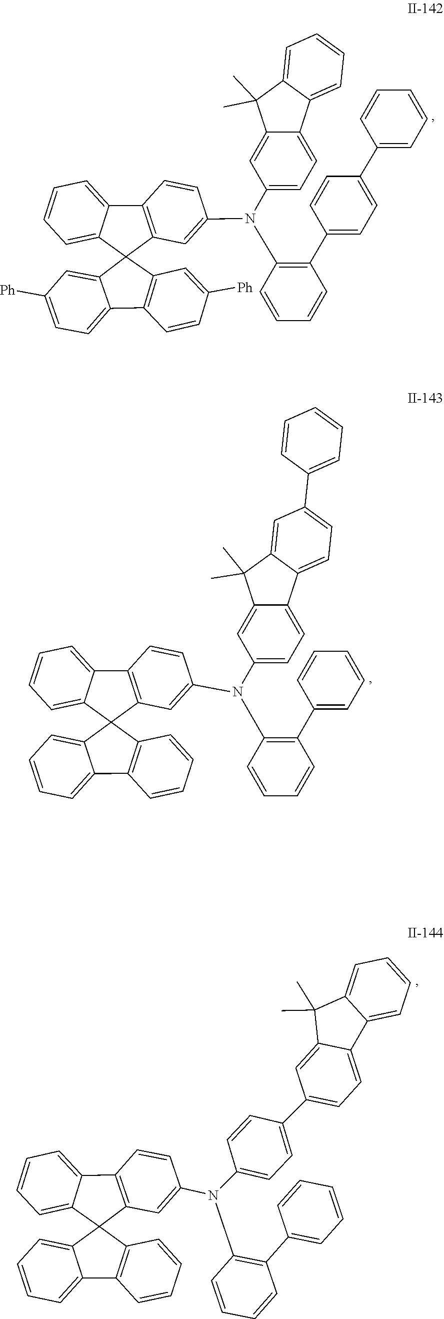 [SMILES: CC1(C)c2ccccc2-c2ccc(N(c3ccc4c(c3)C3(c5ccccc5-4)c4cc(-c5ccccc5)ccc4-c4ccc(-c5ccccc5)cc43)c3ccccc3-c3ccc(-c4ccccc4)cc3)cc21 ; CC1(C)c2cc(-c3ccccc3)ccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(-c3ccc(N(c4ccc5c(c4)C4(c6ccccc6-c6ccccc64)c4ccccc4-5)c4ccccc4-c4ccccc4)cc3)cc21]

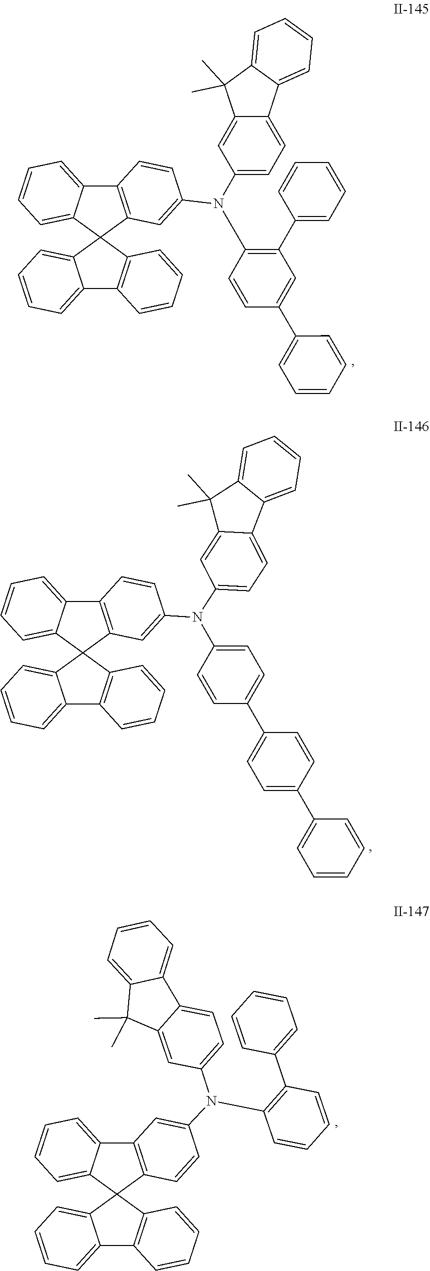 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21 ; CC1(C)c2ccccc2-c2ccc(N(c3ccc(-c4ccc(-c5ccccc5)cc4)cc3)c3ccc4c(c3)C3(c5ccccc5-c5ccccc53)c3ccccc3-4)cc21 ; CC1(C)c2ccccc2-c2ccc(N(c3ccc4c(c3)-c3ccccc3C43c4ccccc4-c4ccccc43)c3ccccc3-c3ccccc3)cc21]

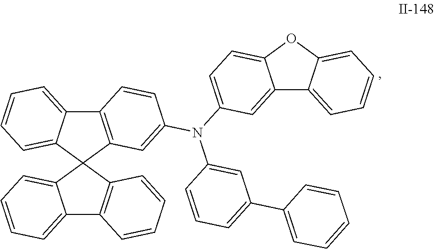 [SMILES: c1ccc(-c2cccc(N(c3ccc4c(c3)C3(c5ccccc5-c5ccccc53)c3ccccc3-4)c3ccc4oc5ccccc5c4c3)c2)cc1]

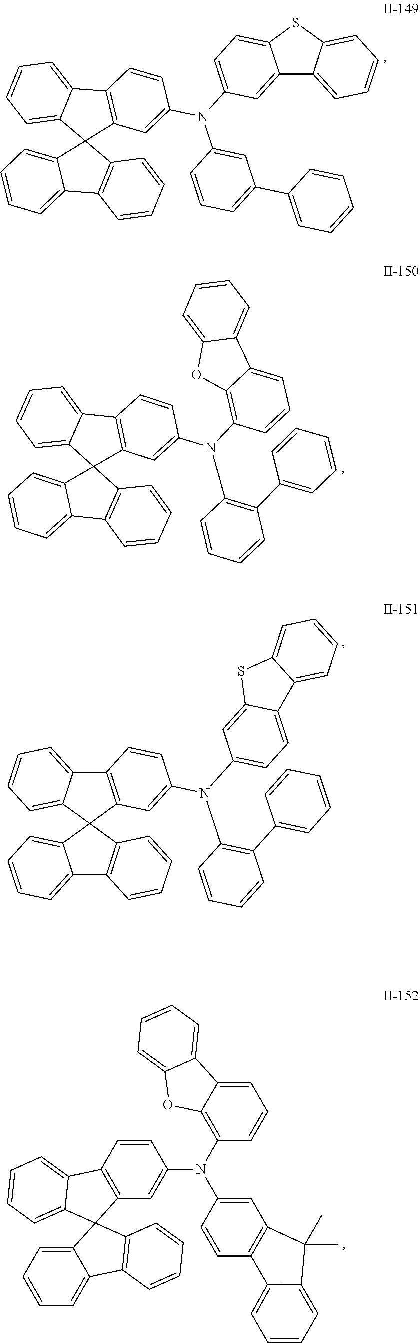 [SMILES: c1ccc(-c2cccc(N(c3ccc4c(c3)C3(c5ccccc5-c5ccccc53)c3ccccc3-4)c3ccc4sc5ccccc5c4c3)c2)cc1 ; c1ccc(-c2ccccc2N(c2ccc3c(c2)C2(c4ccccc4-c4ccccc42)c2ccccc2-3)c2cccc3c2oc2ccccc23)cc1 ; c1ccc(-c2ccccc2N(c2ccc3c(c2)C2(c4ccccc4-c4ccccc42)c2ccccc2-3)c2ccc3c(c2)sc2ccccc23)cc1 ; CC1(C)c2ccccc2-c2ccc(N(c3ccc4c(c3)C3(c5ccccc5-c5ccccc53)c3ccccc3-4)c3cccc4c3oc3ccccc34)cc21]

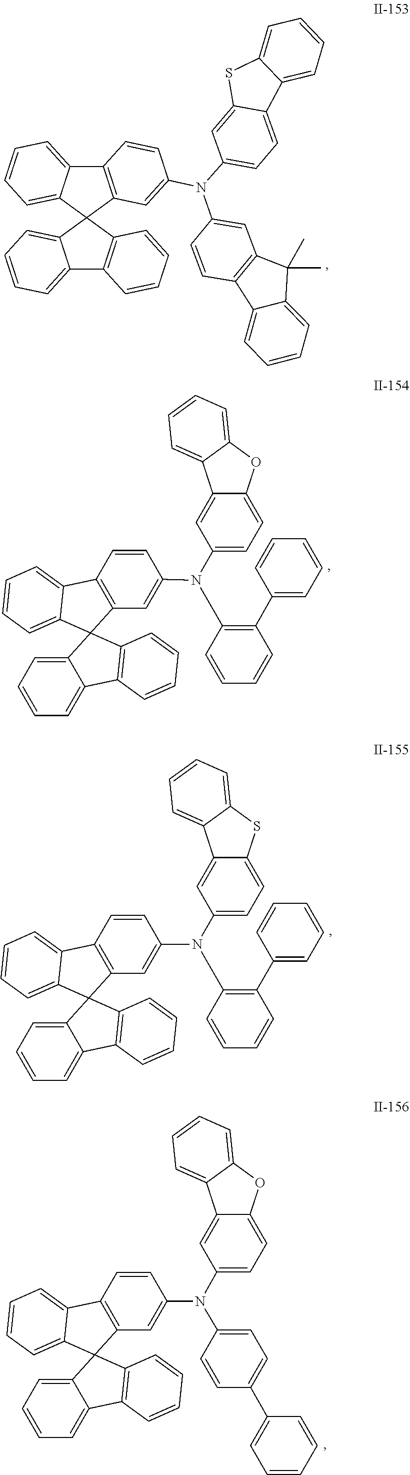 [SMILES: CC1(C)c2ccccc2-c2ccc(N(c3ccc4c(c3)C3(c5ccccc5-c5ccccc53)c3ccccc3-4)c3ccc4c(c3)sc3ccccc34)cc21 ; c1ccc(-c2ccccc2N(c2ccc3c(c2)C2(c4ccccc4-c4ccccc42)c2ccccc2-3)c2ccc3oc4ccccc4c3c2)cc1 ; c1ccc(-c2ccccc2N(c2ccc3c(c2)C2(c4ccccc4-c4ccccc42)c2ccccc2-3)c2ccc3sc4ccccc4c3c2)cc1 ; c1ccc(-c2ccc(N(c3ccc4c(c3)C3(c5ccccc5-c5ccccc53)c3ccccc3-4)c3ccc4oc5ccccc5c4c3)cc2)cc1]

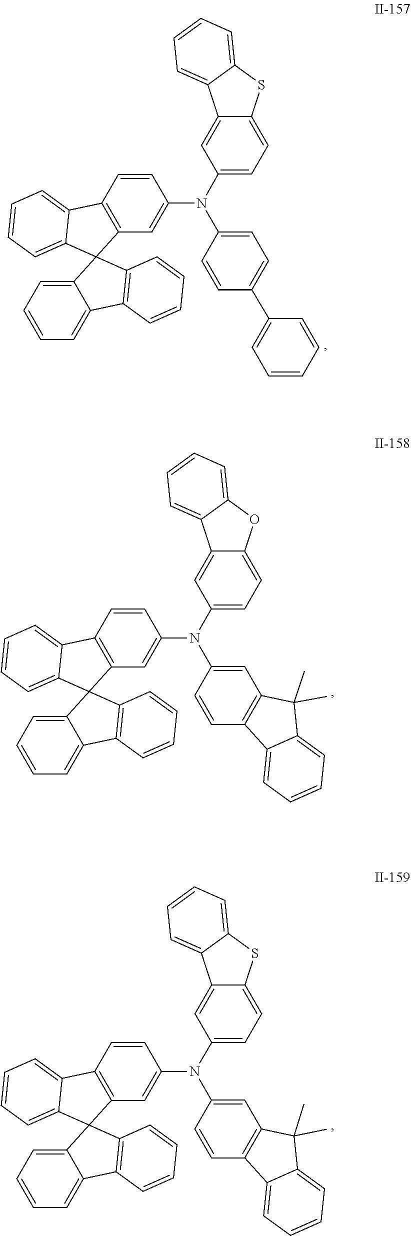 [SMILES: c1ccc(-c2ccc(N(c3ccc4c(c3)C3(c5ccccc5-c5ccccc53)c3ccccc3-4)c3ccc4sc5ccccc5c4c3)cc2)cc1 ; CC1(C)c2ccccc2-c2ccc(N(c3ccc4c(c3)C3(c5ccccc5-c5ccccc53)c3ccccc3-4)c3ccc4oc5ccccc5c4c3)cc21 ; CC1(C)c2ccccc2-c2ccc(N(c3ccc4c(c3)C3(c5ccccc5-c5ccccc53)c3ccccc3-4)c3ccc4sc5ccccc5c4c3)cc21]

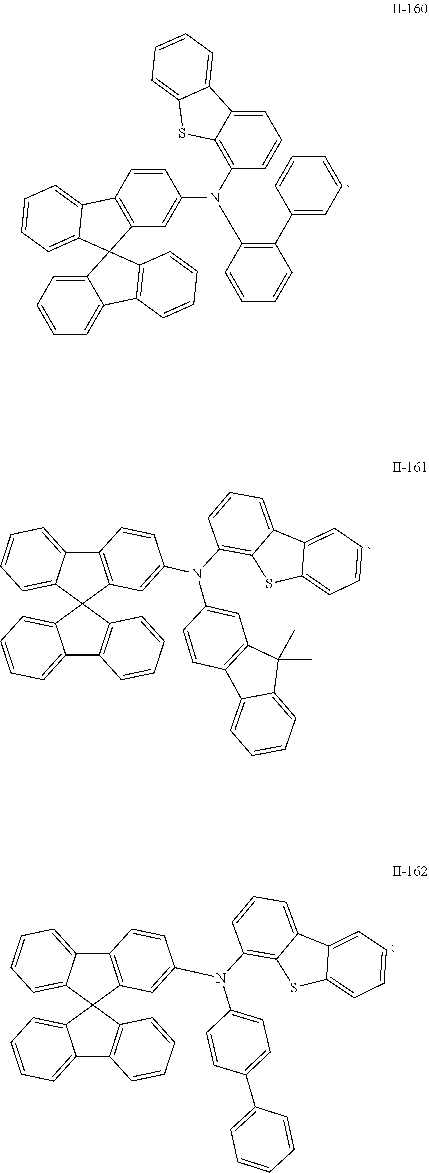 [SMILES: c1ccc(-c2ccccc2N(c2ccc3c(c2)C2(c4ccccc4-c4ccccc42)c2ccccc2-3)c2cccc3c2sc2ccccc23)cc1 ; CC1(C)c2ccccc2-c2ccc(N(c3ccc4c(c3)C3(c5ccccc5-c5ccccc53)c3ccccc3-4)c3cccc4c3sc3ccccc34)cc21 ; c1ccc(-c2ccc(N(c3ccc4c(c3)C3(c5ccccc5-c5ccccc53)c3ccccc3-4)c3cccc4c3sc3ccccc34)cc2)cc1]

wherein Compound IV-I to Compound IV-273 each have a structure represented by Formula 4-4:

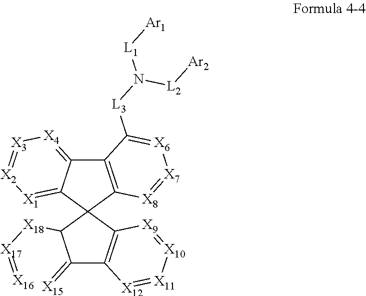

wherein in Formula 4-4, X₁ to X₄, X₆ to X₁₂ and X₁₅ to X₁₈ are CH, L₁ and L₂ are single bonds, and L₃, Ar₁ and Ar₂ correspond to atoms or groups listed in the following table, respectively:

| Compound | | | | Compound | | | |
|---|---|---|---|---|---|---|---|
| No. | L₃ | Ar₁ | Ar₂ | No. | L₃ | Ar₁ | Ar₂ |
| IV-1 | L-0 | G1 | G1 | IV-2 | L-0 | G2 | G2 |
| IV-3 | L-0 | G3 | G3 | IV-4 | L-0 | G4 | G4 |
| IV-5 | L-0 | G10 | G10 | IV-6 | L-0 | G11 | G11 |
| IV-7 | L-0 | G25 | G25 | IV-8 | L-0 | G26 | G26 |
| IV-9 | L-0 | G27 | G27 | IV-10 | L-0 | G28 | G28 |
| IV-11 | L-0 | G29 | G29 | IV-12 | L-0 | G31 | G31 |
| IV-13 | L-0 | G32 | G32 | IV-14 | L-0 | G1 | G2 |
| IV-15 | L-0 | G1 | G3 | IV-16 | L-0 | G1 | G4 |
| IV-17 | L-0 | G1 | G5 | IV-18 | L-0 | G1 | G6 |
| IV-19 | L-0 | G1 | G7 | IV-20 | L-0 | G1 | G8 |
| IV-21 | L-0 | G1 | G9 | IV-22 | L-0 | G1 | G10 |
| IV-23 | L-0 | G1 | G11 | IV-24 | L-0 | G1 | G12 |
| IV-25 | L-0 | G1 | G13 | IV-26 | L-0 | G1 | G14 |
| IV-27 | L-0 | G1 | G15 | IV-28 | L-0 | G1 | G16 |
| IV-29 | L-0 | G1 | G17 | IV-30 | L-0 | G1 | G18 |
| IV-31 | L-0 | G1 | G19 | IV-32 | L-0 | G1 | G20 |
| IV-33 | L-0 | G1 | G21 | IV-34 | L-0 | G1 | G22 |
| IV-35 | L-0 | G1 | G23 | IV-36 | L-0 | G1 | G24 |
| IV-37 | L-0 | G1 | G25 | IV-38 | L-0 | G1 | G26 |
| IV-39 | L-0 | G1 | G27 | IV-40 | L-0 | G1 | G28 |
| IV-41 | L-0 | G1 | G29 | IV-42 | L-0 | G1 | G30 |
| IV-43 | L-0 | G1 | G31 | IV-44 | L-0 | G1 | G32 |
| IV-45 | L-0 | G1 | G33 | IV-46 | L-0 | G2 | G3 |
| IV-47 | L-0 | G2 | G4 | IV-48 | L-0 | G2 | G5 |
| IV-49 | L-0 | G2 | G6 | IV-50 | L-0 | G2 | G7 |
| IV-51 | L-0 | G2 | G8 | IV-52 | L-0 | G2 | G9 |
| IV-53 | L-0 | G2 | G10 | IV-54 | L-0 | G2 | G11 |
| IV-55 | L-0 | G2 | G12 | IV-56 | L-0 | G2 | G13 |
| IV-57 | L-0 | G2 | G14 | IV-58 | L-0 | G2 | G15 |
| IV-59 | L-0 | G2 | G16 | IV-60 | L-0 | G2 | G17 |
| IV-61 | L-0 | G2 | G18 | IV-62 | L-0 | G2 | G19 |
| IV-63 | L-0 | G2 | G20 | IV-64 | L-0 | G2 | G21 |
| IV-65 | L-0 | G2 | G22 | IV-66 | L-0 | G2 | G23 |
| IV-67 | L-0 | G2 | G24 | IV-68 | L-0 | G2 | G25 |
| IV-69 | L-0 | G2 | G26 | IV-70 | L-0 | G2 | G27 |
| IV-71 | L-0 | G2 | G28 | IV-72 | L-0 | G2 | G29 |
| IV-73 | L-0 | G2 | G30 | IV-74 | L-0 | G2 | G31 |
| IV-75 | L-0 | G2 | G32 | IV-76 | L-0 | G2 | G33 |
| IV-77 | L-0 | G3 | G4 | IV-78 | L-0 | G3 | G5 |
| IV-79 | L-0 | G3 | G6 | IV-80 | L-0 | G3 | G7 |
| IV-81 | L-0 | G3 | G8 | IV-82 | L-0 | G3 | G9 |
| IV-83 | L-0 | G3 | G10 | IV-84 | L-0 | G3 | G11 |
| IV-85 | L-0 | G3 | G12 | IV-86 | L-0 | G3 | G13 |
| IV-87 | L-0 | G3 | G14 | IV-88 | L-0 | G3 | G15 |
| IV-89 | L-0 | G3 | G16 | IV-90 | L-0 | G3 | G17 |
| IV-91 | L-0 | G3 | G18 | IV-92 | L-0 | G3 | G19 |
| IV-93 | L-0 | G3 | G20 | IV-94 | L-0 | G3 | G21 |
| IV-95 | L-0 | G3 | G22 | IV-96 | L-0 | G3 | G23 |
| IV-97 | L-0 | G3 | G24 | IV-98 | L-0 | G3 | G25 |
| IV-99 | L-0 | G3 | G26 | IV-100 | L-0 | G3 | G27 |
| IV-101 | L-0 | G3 | G28 | IV-102 | L-0 | G3 | G29 |
| IV-103 | L-0 | G3 | G30 | IV-104 | L-0 | G3 | G31 |
| IV-105 | L-0 | G3 | G32 | IV-106 | L-0 | G3 | G33 |
| IV-107 | L-0 | G4 | G5 | IV-108 | L-0 | G4 | G6 |
| IV-109 | L-0 | G4 | G7 | IV-110 | L-0 | G4 | G8 |
| IV-111 | L-0 | G4 | G9 | IV-112 | L-0 | G4 | G10 |
| IV-113 | L-0 | G4 | G11 | IV-114 | L-0 | G4 | G12 |
| IV-115 | L-0 | G4 | G13 | IV-116 | L-0 | G4 | G14 |
| IV-117 | L-0 | G4 | G15 | IV-118 | L-0 | G4 | G16 |
| IV-119 | L-0 | G4 | G17 | IV-120 | L-0 | G4 | G18 |
| IV-121 | L-0 | G4 | G19 | IV-122 | L-0 | G4 | G20 |
| IV-123 | L-0 | G4 | G21 | IV-124 | L-0 | G4 | G22 |
| IV-125 | L-0 | G4 | G23 | IV-126 | L-0 | G4 | G24 |
| IV-127 | L-0 | G4 | G25 | IV-128 | L-0 | G4 | G26 |
| IV-129 | L-0 | G4 | G27 | IV-130 | L-0 | G4 | G28 |
| IV-131 | L-0 | G4 | G29 | IV-132 | L-0 | G4 | G30 |
| IV-133 | L-0 | G4 | G31 | IV-134 | L-0 | G4 | G32 |
| IV-135 | L-0 | G4 | G33 | IV-136 | L-0 | G5 | G6 |
| IV-137 | L-0 | G5 | G7 | IV-138 | L-0 | G5 | G8 |
| IV-139 | L-0 | G5 | G9 | IV-140 | L-0 | G5 | G10 |
| IV-141 | L-0 | G5 | G11 | IV-142 | L-0 | G5 | G12 |
| IV-143 | L-0 | G5 | G13 | IV-144 | L-0 | G5 | G14 |
| IV-145 | L-0 | G5 | G15 | IV-146 | L-0 | G5 | G16 |
| IV-147 | L-0 | G5 | G17 | IV-148 | L-0 | G5 | G18 |
| IV-149 | L-0 | G5 | G19 | IV-150 | L-0 | G5 | G20 |
| IV-151 | L-0 | G5 | G21 | IV-152 | L-0 | G5 | G22 |
| IV-153 | L-0 | G5 | G23 | IV-154 | L-0 | G5 | G24 |
| IV-155 | L-0 | G5 | G25 | IV-156 | L-0 | G5 | G26 |
| IV-157 | L-0 | G5 | G27 | IV-158 | L-0 | G5 | G28 |
| IV-159 | L-0 | G5 | G29 | IV-160 | L-0 | G5 | G30 |
| IV-161 | L-0 | G5 | G31 | IV-162 | L-0 | G5 | G32 |
| IV-163 | L-0 | G5 | G33 | IV-164 | L-0 | G10 | G26 |
| IV-165 | L-0 | G10 | G27 | IV-166 | L-0 | G10 | G28 |
| IV-167 | L-0 | G10 | G29 | IV-168 | L-0 | G10 | G30 |
| IV-169 | L-0 | G10 | G31 | IV-170 | L-0 | G10 | G32 |
| IV-171 | L-0 | G10 | G33 | IV-172 | L-0 | G11 | G26 |
| IV-173 | L-0 | G11 | G27 | IV-174 | L-0 | G11 | G28 |
| IV-175 | L-0 | G11 | G29 | IV-176 | L-0 | G11 | G30 |
| IV-177 | L-0 | G11 | G31 | IV-178 | L-0 | G11 | G32 |
| IV-179 | L-0 | G11 | G33 | IV-180 | L-1 | G1 | G1 |
| IV-181 | L-1 | G2 | G2 | IV-182 | L-1 | G5 | G5 |
| IV-183 | L-1 | G27 | G27 | IV-184 | L-1 | G28 | G28 |
| IV-185 | L-1 | G31 | G31 | IV-186 | L-1 | G32 | G32 |
| IV-187 | L-1 | G1 | G2 | IV-188 | L-1 | G1 | G3 |
| IV-189 | L-1 | G1 | G4 | IV-190 | L-1 | G1 | G5 |
| IV-191 | L-1 | G1 | G10 | IV-192 | L-1 | G1 | G11 |
| IV-193 | L-1 | G1 | G19 | IV-194 | L-1 | G1 | G20 |
| IV-195 | L-1 | G1 | G27 | IV-196 | L-1 | G1 | G28 |
| IV-197 | L-1 | G1 | G31 | IV-198 | L-1 | G1 | G32 |
| IV-199 | L-1 | G2 | G3 | IV-200 | L-1 | G2 | G4 |
| IV-201 | L-1 | G2 | G5 | IV-202 | L-1 | G2 | G10 |
| IV-203 | L-1 | G2 | G11 | IV-204 | L-1 | G2 | G19 |
| IV-205 | L-1 | G2 | G20 | IV-206 | L-1 | G2 | G27 |
| IV-207 | L-1 | G2 | G28 | IV-208 | L-1 | G2 | G31 |
| IV-209 | L-1 | G2 | G32 | IV-210 | L-1 | G4 | G5 |
| IV-211 | L-1 | G4 | G10 | IV-212 | L-1 | G4 | G11 |
| IV-213 | L-1 | G4 | G19 | IV-214 | L-1 | G4 | G20 |
| IV-215 | L-1 | G4 | G27 | IV-216 | L-1 | G4 | G28 |
| IV-217 | L-1 | G4 | G31 | IV-218 | L-1 | G4 | G32 |
| IV-219 | L-1 | G5 | G10 | IV-220 | L-1 | G5 | G11 |
| IV-221 | L-1 | G5 | G19 | IV-222 | L-1 | G5 | G20 |
| IV-223 | L-1 | G5 | G27 | IV-224 | L-1 | G5 | G28 |
| IV-225 | L-1 | G5 | G31 | IV-226 | L-1 | G5 | G32 |
| IV-227 | L-4 | G1 | G1 | IV-228 | L-4 | G2 | G2 |
| IV-229 | L-4 | G5 | G5 | IV-230 | L-4 | G27 | G27 |
| IV-231 | L-4 | G28 | G28 | IV-232 | L-4 | G31 | G31 |
| IV-233 | L-4 | G32 | G32 | IV-234 | L-4 | G1 | G2 |
| IV-235 | L-4 | G1 | G3 | IV-236 | L-4 | G1 | G4 |
| IV-237 | L-4 | G1 | G5 | IV-238 | L-4 | G1 | G10 |
| IV-239 | L-4 | G1 | G11 | IV-240 | L-4 | G1 | G19 |
| IV-241 | L-4 | G1 | G20 | IV-242 | L-4 | G1 | G27 |
| IV-243 | L-4 | G1 | G28 | IV-244 | L-4 | G1 | G31 |
| IV-245 | L-4 | G1 | G32 | IV-246 | L-4 | G2 | G3 |
| IV-247 | L-4 | G2 | G4 | IV-248 | L-4 | G2 | G5 |
| IV-249 | L-4 | G2 | G10 | IV-250 | L-4 | G2 | G11 |
| IV-251 | L-4 | G2 | G19 | IV-252 | L-4 | G2 | G20 |
| IV-253 | L-4 | G2 | G27 | IV-254 | L-4 | G2 | G28 |
| IV-255 | L-4 | G2 | G31 | IV-256 | L-4 | G2 | G32 |
| IV-257 | L-4 | G4 | G5 | IV-258 | L-4 | G4 | G10 |
| IV-259 | L-4 | G4 | G11 | IV-260 | L-4 | G4 | G19 |
| IV-261 | L-4 | G4 | G20 | IV-262 | L-4 | G4 | G27 |
| IV-263 | L-4 | G4 | G28 | IV-264 | L-4 | G4 | G31 |
| IV-265 | L-4 | G4 | G32 | IV-266 | L-4 | G5 | G10 |
| IV-267 | L-4 | G5 | G11 | IV-268 | L-4 | G5 | G19 |
| IV-269 | L-4 | G5 | G20 | IV-270 | L-4 | G5 | G27 |
| IV-271 | L-4 | G5 | G28 | IV-272 | L-4 | G5 | G31 |
| IV-273 | L-4 | G5 | G32 | | | | |

According to an embodiment of the present disclosure, the organic electroluminescent device emits blue light.

According to an embodiment of the present disclosure, the organic electroluminescent device has a maximum emission wavelength between 400 nm and 480 nm.

According to another embodiment of the present disclosure, further disclosed is a display assembly, the display assembly comprises the organic electroluminescent device described in any one of the preceding embodiments.

### Combination with Other Materials

The materials described in the present disclosure for a particular layer in an organic light emitting device can be used in combination with various other materials present in the device. The combinations of these materials are described in more detail in U.S. Patent Application Publication No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Patent Application Publication No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### Device Example

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 10⁻⁷ torr. Compound II-130 and a second compound 183 were co-deposited (at a weight ratio of 98:2) for use as a hole injection layer (HIL) with a thickness of 100 Å. Compound II-130 was used as a hole transporting layer (HTL) with a thickness of 250 Å. Compound EB was used as an electron blocking layer (EBL) with a thickness of 50 Å. Then, Compound N-1-15 as a first host, Compound P-21 as a second host and a first compound Pt14 as a dopant were co-deposited (at a weight ratio of 26.4:61.6:12) for use as an emissive layer (EML) with a thickness of 350 Å. Compound N-1-15 was used as a hole blocking layer (HBL) with a thickness of 50 Å. On the HBL, Compound ET and 8-hydroxyquinolinolato-lithium (Liq) were co-deposited for use as an electron transporting layer (ETL) with a thickness of 310 Å. Finally, LiF was deposited for use as an electron injection layer with a thickness of 15 Å and Al was deposited for use as a cathode with a thickness of 1200 Å. The device was transferred back to the glovebox and encapsulated with a glass lid and a moisture getter to complete the device.

### Device Example 2

The implementation mode of Device Example 2 was the same as that of Device Example 1 except that in the hole injection layer (HIL), Compound 183 was replaced with Compound 184.

### Device Comparative Example 1

The implementation mode of Device Comparative Example 1 was the same as that of Device Example 1 except that in the hole injection layer (HIL), Compound 183 was replaced with Compound PD-1.

### Device Comparative Example 2

The implementation mode of Device Comparative Example 2 was the same as that of Device Example 1 except that in the emissive layer (EML), Compound Pt14 was replaced with Compound Pt-A.

### Device Comparative Example 3

The implementation mode of Device Comparative Example 3 was the same as that of Device Example 2 except that in the emissive layer (EML), Compound Pt14 was replaced with Compound Pt-A.

Detailed structures and thicknesses of layers of the devices are shown in the following table. A layer using more than one material is obtained by doping different compounds at their weight ratio as recorded.

TABLE 1
Part of device structures in device examples and comparative examples

| Device ID | HIL | HTL | EBL | EML | HBL | ETL |
|---|---|---|---|---|---|---|
| Example 1 | Compound II- | Compound | Compound | Compound P- | Compound | Compound |
| | 130:Compound | II-130 (250 | EB (50 Å) | 21:Compound N-1- | N-1-15 (50 | ET:Liq |
| | 183 (98:2) (100 Å) | Å) | | 15:Compound Pt14 | Å) | (40:60) |
| | | | | (61.6:26.4:12) (350 | | (310 Å) |
| | | | | Å) | | |
| Example 2 | Compound II- | Compound | Compound | Compound P- | Compound | Compound |
| | 130:Compound | II-130 (250 | EB (50 Å) | 21:Compound N-1- | N-1-15 (50 | ET:Liq |
| | 184 (98:2) (100 Å) | Å) | | 15:Compound Pt14 | Å) | (40:60) |
| | | | | (61.6:26.4:12) (350 | | (310 Å) |
| | | | | Å) | | |
| Comparative | Compound II- | Compound | Compound | Compound P- | Compound | Compound |
| Example 1 | 130:Compound | II-130 (250 | EB (50 Å) | 21:Compound N-1- | N-1-15 (50 | ET:Liq |
| | PD-1 (98:2) (100 | Å) | | 15:Compound Pt14 | Å) | (40:60) |
| | Å) | | | (61.6:26.4:12) (350 | | (310 Å) |
| | | | | Å) | | |
| Comparative | Compound II- | Compound | Compound | Compound P- | Compound | Compound |
| Example 2 | 130:Compound | II-130 (250 | EB (50 Å) | 21:Compound N-1- | N-1-15 (50 | ET:Liq |
| | 183 (98:2) (100 Å) | Å) | | 15:Compound Pt-A | Å) | (40:60) |
| | | | | (61.6:26.4:12) (350 | | (310 Å) |
| | | | | Å) | | |
| Comparative | Compound II- | Compound | Compound | Compound P- | Compound | Compound |
| Example 3 | 130:Compound | II-130 (250 | EB (50 Å) | 21:Compound N-1- | N-1-15 (50 | ET:Liq |
| | 184 (98:2) (100 Å) | Å) | | 15:Compound Pt-A | Å) | (40:60) |
| | | | | (61.6:26.4:12) (350 | | (310 Å) |
| | | | | Å) | | |

The materials used in the devices have the following structures:

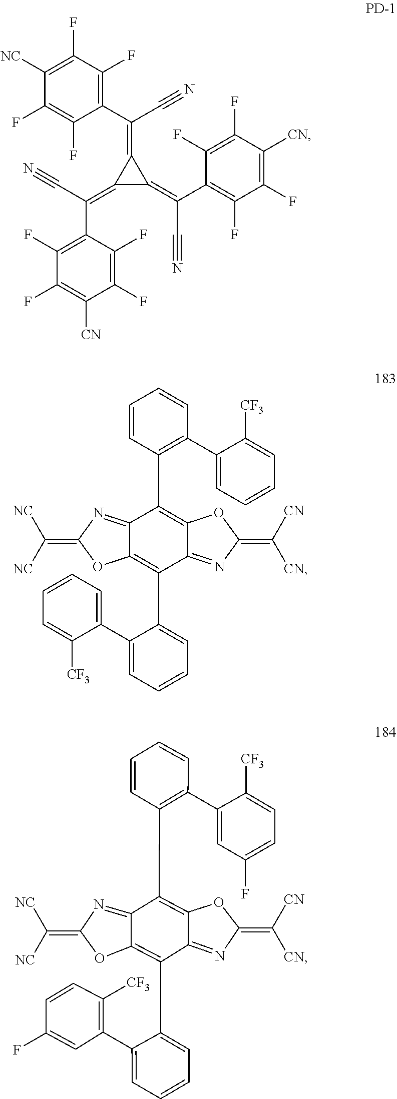 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=c1nc2c(-c3ccccc3-c3ccccc3C(F)(F)F)c3oc(=C(C#N)C#N)nc3c(-c3ccccc3-c3ccccc3C(F)(F)F)c2o1 ; N#CC(C#N)=c1nc2c(-c3ccccc3-c3cc(F)ccc3C(F)(F)F)c3oc(=C(C#N)C#N)nc3c(-c3ccccc3-c3cc(F)ccc3C(F)(F)F)c2o1]

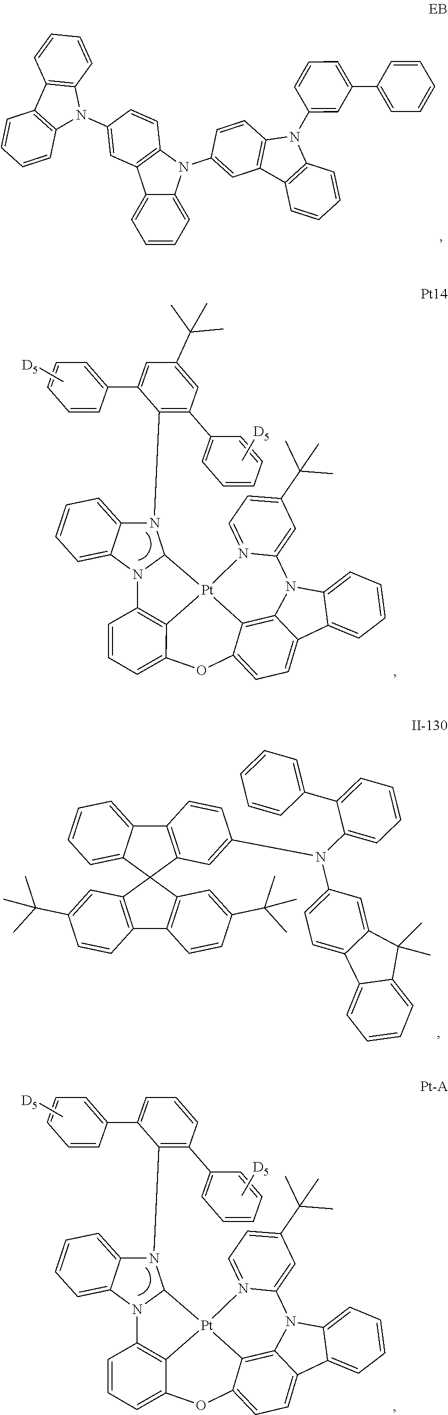

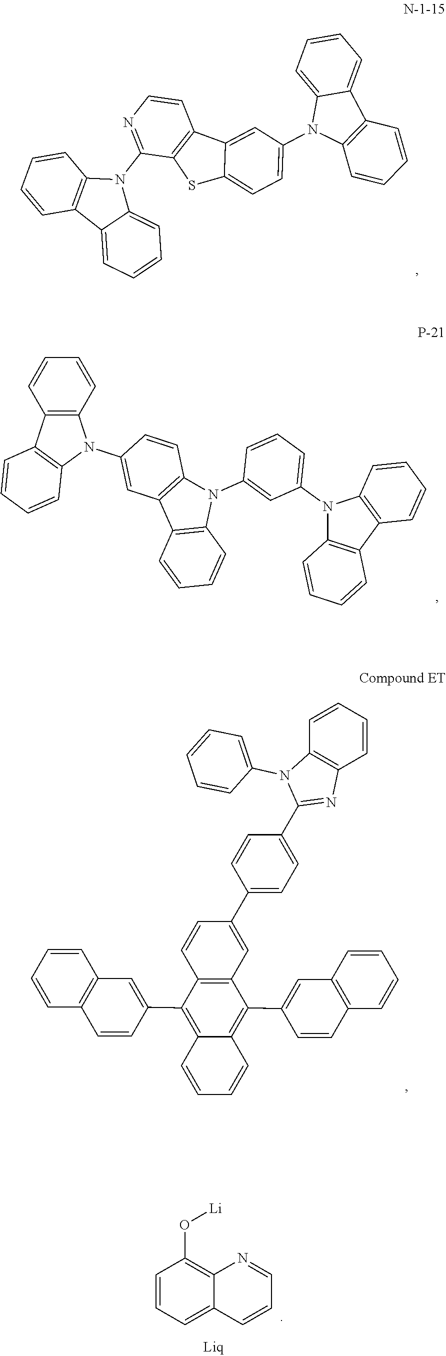

The CIE values, maximum emission wavelengths (λₘₐₓ), full widths at half maximum (FWHM) and external quantum efficiency (EQE) of Examples 1 and 2 and Comparative Examples 1 to 3 were measured at 10 mA/cm². The related data are shown in Table 2.

TABLE 2
Device data

| | | λₘₐₓ | FWHM | EQE |
|---|---|---|---|---|
| Device No. | CIE (x, y) | [nm] | [nm] | (%) |
| Example 1 | 0.131, 0.140 | 462 | 22.0 | 20.00 |
| Example 2 | 0.131, 0.140 | 461 | 22.0 | 19.80 |
| Comparative | 0.131, 0.140 | 461 | 21.9 | 19.03 |
| Example 1 | | | | |
| Comparative | 0.131, 0.150 | 462 | 22.6 | 18.67 |
| Example 2 | | | | |
| Comparative | 0.131, 0.150 | 462 | 22.5 | 18.25 |
| Example 3 | | | | |

As can be seen from the data in Table 2, the maximum emission wavelengths of the examples are basically consistent with those of the comparative examples.

In Example 1, the second compound 183 selected in the present disclosure is used in the HIL, and the first compound Pt14 selected in the present disclosure is used in the EML. In Comparative Example 1, only the first compound Pt14 selected in the present disclosure is used. In Comparative Example 2, only the second compound 183 selected in the present disclosure is used. Compared with Comparative Examples 1 and 2, Example 1 achieves an extremely narrow full width at half maximum (FWHM) that is comparable to or further reduced than Comparative Examples 1 or 2. However, more importantly, the EQE of Example 1 is significantly improved on the basis of very high levels that have been reached in Comparative Examples 1 and 2. The EQE of Example 1 is up to 20%, which is improved by 5.1% and 7.1% compared with those of Comparative Examples 1 and 2, respectively.

In Example 2, the second compound 184 selected in the present disclosure is used in the HIL, and the first compound Pt14 selected in the present disclosure is used in the EML. In Comparative Example 1, only the first compound Pt14 selected in the present disclosure is used.

In Comparative Example 3, only the second compound 184 selected in the present disclosure is used. Compared with Comparative Examples 1 and 3, Example 2 achieves an extremely narrow full width at half maximum (FWHM) that is comparable to or further reduced than Comparative Examples 1 or 3. However, more importantly, the EQE of Example 2 is significantly improved on the basis of very high levels that have been reached in Comparative Examples 1 and 3. The EQE of Example 2 is up to 19.8%, which is improved by 4.0% and 8.5% compared with those of Comparative Examples 1 and 3, respectively. These data proves that the device of the present disclosure has excellent performance. The superiority and uniqueness of the organic electroluminescent device of the present disclosure are proved.

To further verify the advantages of the organic electroluminescent device of the present disclosure, different hole transporting materials are selected for the hole injection layers for experiments.

### Device Example 3

The implementation mode of Device Example 3 was the same as that of Device Example 1 except that in the hole injection layer (HIL), Compound II-130 was replaced with Compound IV-11, and in the hole transporting layer (HTL), Compound II-130 was replaced with Compound IV-11.

### Device Example 4

The implementation mode of Device Example 4 was the same as that of Device Example 3 except that in the hole injection layer (HIL), Compound 183 was replaced with Compound 184.

### Device Comparative Example 4

The implementation mode of Device Comparative Example 4 was the same as that of Device Example 3 except that in the hole injection layer (HIL), Compound 183 was replaced with Compound PD-1.

### Device Comparative Example 5

The implementation mode of Device Comparative Example 5 was the same as that of Device Example 3 except that in the emissive layer (EML), Compound Pt14 was replaced with Compound Pt-A.

### Device Comparative Example 6

The implementation mode of Device Comparative Example 6 was the same as that of Device Example 4 except that in the emissive layer (EML), Compound Pt14 was replaced with Compound Pt-A.

Detailed structures and thicknesses of layers of the devices are shown in the following table. A layer using more than one material is obtained by doping different compounds at their weight ratio as recorded.

TABLE 3
Part of device structures in device examples and comparative examples

| Device ID | HIL | HTL | EBL | EML | HBL | ETL |
|---|---|---|---|---|---|---|
| Example 3 | Compound IV- | Compound | Compound | Compound P- | Compound | Compound |
| | 11:Compound 183 | IV-11 (250 | EB (50 Å) | 21:Compound N-1- | N-1-15 (50 | ET:Liq |
| | (98:2) (100 Å) | Å) | | 15:Compound Pt14 | Å) | (40:60) |
| | | | | (61.6:26.4:12) (350 | | (310 Å) |
| | | | | Å) | | |
| Example 4 | Compound IV- | Compound | Compound | Compound P- | Compound | Compound |
| | 11:Compound 184 | IV-11 (250 | EB (50 Å) | 21:Compound N-1- | N-1-15 (50 | ET:Liq |
| | (98:2) (100 Å) | Å) | | 15:Compound Pt14 | Å) | (40:60) |
| | | | | (61.6:26.4:12) (350 | | (310 Å) |
| | | | | Å) | | |
| Comparative | Compound IV- | Compound | Compound | Compound P- | Compound | Compound |
| Example 4 | 11:Compound PD- | IV-11 (250 | EB (50 Å) | 21:Compound N-1- | N-1-15 (50 | ET:Liq |
| | 1 (98:2) (100 Å) | Å) | | 15:Compound Pt14 | Å) | (40:60) |
| | | | | (61.6:26.4:12) (350 | | (310 Å) |
| | | | | Å) | | |
| Comparative | Compound IV- | Compound | Compound | Compound P- | Compound | Compound |
| Example 5 | 11:Compound 183 | IV-11 (250 | EB (50 Å) | 21:Compound N-1- | N-1-15 (50 | ET:Liq |
| | (98:2) (100 Å) | Å) | | 15:Compound Pt-A | Å) | (40:60) |
| | | | | (61.6:26.4:12) (350 | | (310 Å) |
| | | | | Å) | | |
| Comparative | Compound IV- | Compound | Compound | Compound P- | Compound | Compound |
| Example 6 | 11:Compound 184 | IV-11 (250 | EB (50 Å) | 21:Compound N-1- | N-1-15 (50 | ET:Liq |
| | (98:2) (100 Å) | Å) | | 15:Compound Pt-A | Å) | (40:60) |
| | | | | (61.6:26.4:12) (350 | | (310 Å) |
| | | | | Å) | | |

The new material used in the devices has the following structure:

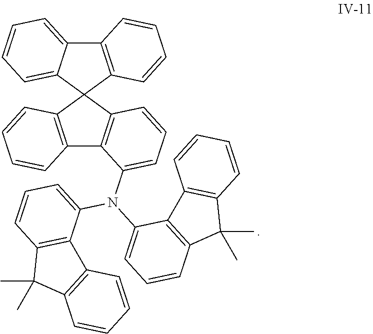

The CIE values, maximum emission wavelengths (λₘₐₓ), full widths at half maximum (FWHM) and external quantum efficiency (EQE) of Examples 3 and 4 and Comparative Examples 4 to 6 were measured at 10 mA/cm². The related data are shown in Table 4.

TABLE 4
Device data

| | | λₘₐₓ | FWHM | EQE |
|---|---|---|---|---|
| Device No. | CIE (x, y) | [nm] | [nm] | (%) |
| Example 3 | 0.131, 0.148 | 462 | 22.5 | 19.46 |
| Example 4 | 0.131, 0.148 | 461 | 22.5 | 18.99 |
| Comparative | 0.131, 0.148 | 461 | 22.5 | 17.97 |
| Example 4 | | | | |
| Comparative | 0.131, 0.157 | 462 | 23.1 | 18.32 |
| Example 5 | | | | |
| Comparative | 0.131, 0.158 | 462 | 23.2 | 17.63 |
| Example 6 | | | | |

As can be seen from the data in Table 4, the maximum emission wavelengths of the examples are basically consistent with those of the comparative examples.

In Example 3, the second compound 183 selected in the present disclosure is used in the HIL, and the first compound Pt14 selected in the present disclosure is used in the EML. In Comparative Example 4, only the first compound Pt14 selected in the present disclosure is used. In Comparative Example 5, only the second compound 183 selected in the present disclosure is used. Compared with Comparative Examples 4 and 5, Example 3 achieves an extremely narrow full width at half maximum (FWHM) that is comparable to or further reduced than Comparative Examples 4 or 5. However, more importantly, the EQE of Example 3 is significantly improved on the basis of very high levels that have been reached in Comparative Examples 4 and 5. The EQE of Example 3 is up to 19.46%, which is improved by 8.3% and 6.2% compared with those of Comparative Examples 4 and 5, respectively.

In Example 4, the second compound 184 selected in the present disclosure is used in the HIL, and the first compound Pt14 selected in the present disclosure is used in the EML. In Comparative Example 4, only the first compound Pt14 selected in the present disclosure is used. In Comparative Example 6, only the second compound 184 selected in the present disclosure is used. Compared with Comparative Examples 4 and 6, Example 4 achieves an extremely narrow full width at half maximum (FWHM) that is comparable to or further reduced (by 0.7 nm) than Comparative Examples 4 or 6. However, more importantly, the EQE of Example 4 is significantly improved on the basis of very high levels that have been reached in Comparative Examples 4 and 6. The EQE of Example 4 is up to 18.99%, which is improved by 5.6% and 7.7% compared with those of Comparative Examples 4 and 6, respectively. These data proves that the device of the present disclosure has excellent performance. The superiority and uniqueness of the organic electroluminescent device of the present disclosure are proved.

To conclude, using a particular combination consisting of the first compound where a particular multi-substituted aromatic group having a structure of Formula 2 is introduced at an N position of imidazole in Formula 1 selected in the present disclosure as a light-emitting material and the second compound having a structure of Formula 3 selected in the present disclosure for the organic electroluminescent device is more conducive to hole injection and charge balance, exhibits excellent device performance and can obtain an extremely narrow full width at half maximum and higher efficiency. It is proved that the device comprising the combination of the first compound selected in the present disclosure and the second compound selected in the present disclosure has an excellent application prospect.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An organic electroluminescent device, comprising:
an anode,
a cathode, and
a first organic layer and a second organic layer disposed between the anode and the cathode;
wherein the first organic layer comprises a first compound, wherein the first compound has a structure represented by Formula 1: 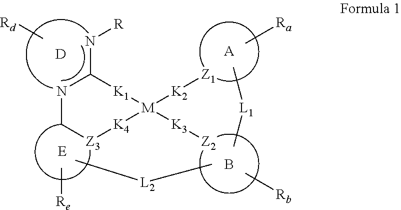
wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 1 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof;
y is 1, 2, 3, 4 or 5;
K₁ to K₄ are, at each occurrence identically or differently, selected from a single bond, O or S;
Z₁ to Z₃ are, at each occurrence identically or differently, selected from C or N;
R in Formula 1 has a structure represented by Formula 2: 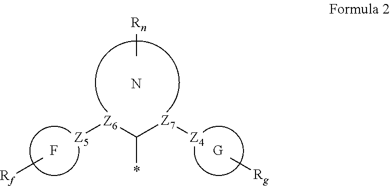
wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof;
Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined; and
adjacent substituents R″, Rₐ, R_{b}, R_{d}, Rₑ, R_{f}, R_{g} and Rₙ can be optionally joined to form a ring;
wherein the second organic layer comprises a second compound, wherein the second compound has a structure represented by Formula 3: 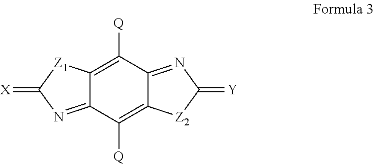
wherein in Formula 3,
X and Y are, at each occurrence identically or differently, selected from NQ′, CQ″Q′″, O, S or Se;
Z₁ and Z₂ are, at each occurrence identically or differently, selected from O, S or Se;
Q, Q′, Q″ and Q′″ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof;
at least one of Q, Q′, Q″ and Q′″ is a group having at least one electron withdrawing group; and
adjacent substituents Q″ and Q′″ can be optionally joined to form a ring.

2. The organic electroluminescent device according to claim 1, wherein M is selected from Cu, Ag, Au, Ru, Rh, Pd, Os, Ir or Pt; preferably, M is selected from Pt or Pd; more preferably, M is selected from Pt.

3. The organic electroluminescent device according to claim 1, wherein the ring A, the ring B, the ring E, the ring F, the ring G and the ring N are, at each occurrence identically or differently, selected from a five-membered unsaturated carbocyclic ring, an aromatic ring having 6 to 30 carbon atoms, a heteroaromatic ring having 3 to 30 carbon atoms or a combination thereof; the ring D is, at each occurrence identically or differently, selected from an unsaturated heterocyclic ring having 1 to 18 carbon atoms;
preferably, the ring A, the ring B, the ring E, the ring F, the ring G and the ring N are, at each occurrence identically or differently, selected from a five-membered unsaturated carbocyclic ring, an aromatic ring having 6 to 18 carbon atoms, a heteroaromatic ring having 3 to 18 carbon atoms or a combination thereof; the ring D is, at each occurrence identically or differently, selected from a heteroaromatic ring having 3 to 18 carbon atoms; and
most preferably, the ring A, the ring B, the ring E, the ring F, the ring G and the ring N are, at each occurrence identically or differently, selected from a benzene ring, a pyridine ring, an indene ring, a fluorene ring, an indole ring, a carbazole ring, an indolocarbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring, an imidazole ring, a benzimidazole ring or a combination thereof; the ring D is, at each occurrence identically or differently, selected from an imidazolecarbene ring or a benzimidazolecarbene ring.

4. The organic electroluminescent device according to claim 1, wherein L₁ is selected from a single bond, O, S, (SiR″R″)_{y}, NR″ or a combination thereof, wherein y is 1 or 2;
preferably, L₁ is selected from a single bond, O or S; and
more preferably, L₁ is selected from a single bond.

5. The organic electroluminescent device according to claim 1, wherein K₁ to K₄ are selected from a single bond, and the first compound has a structure represented by one of Formula 1-1 to Formula 1-20: 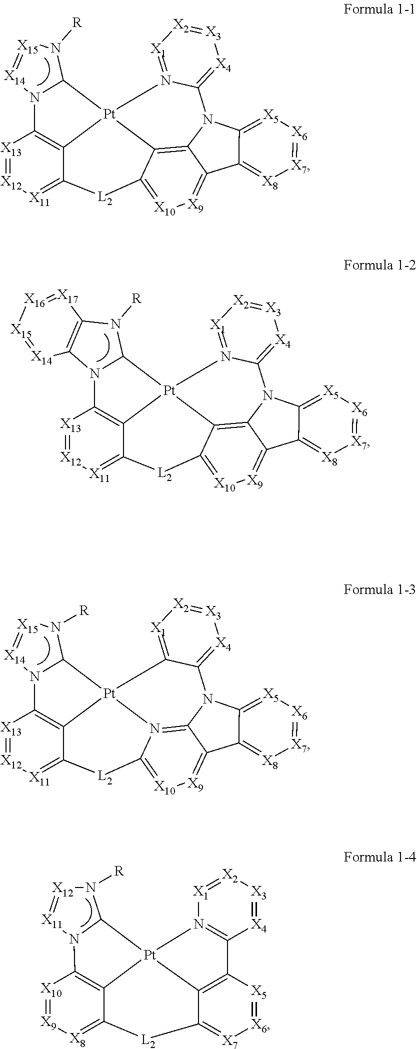 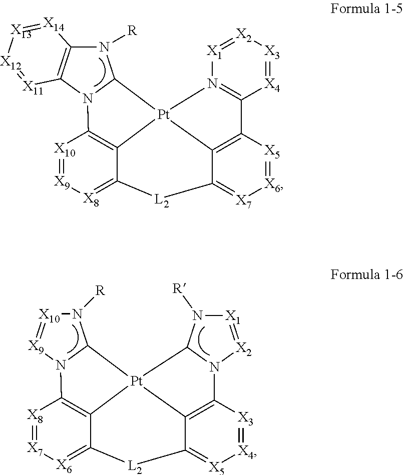 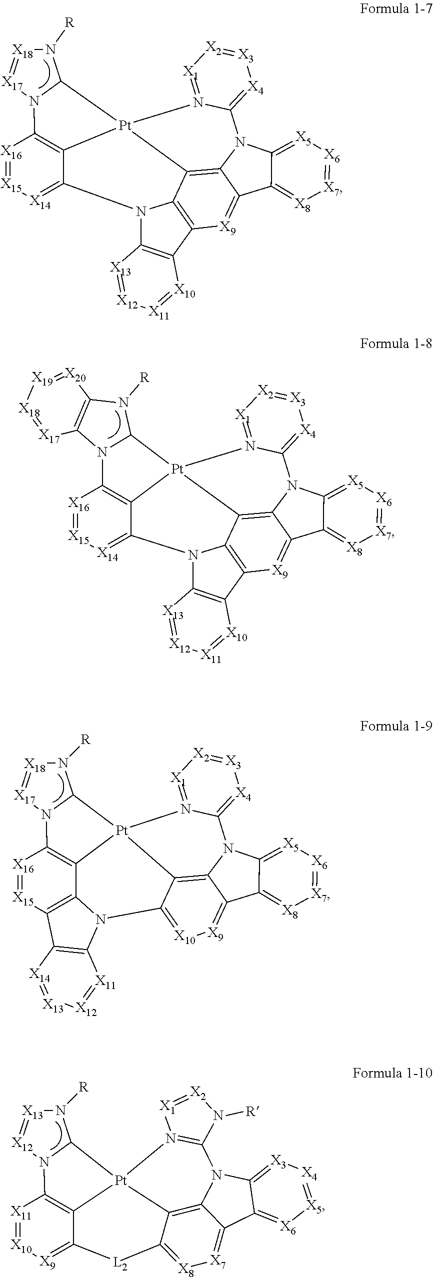 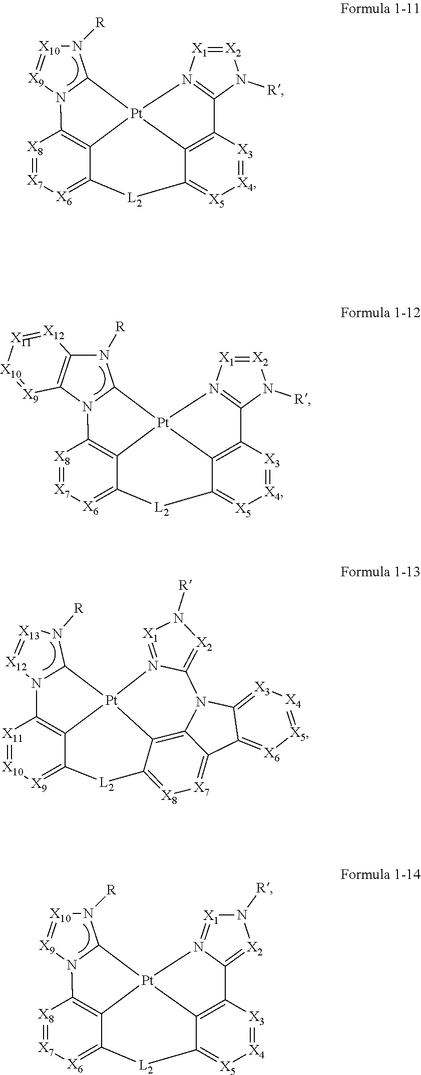 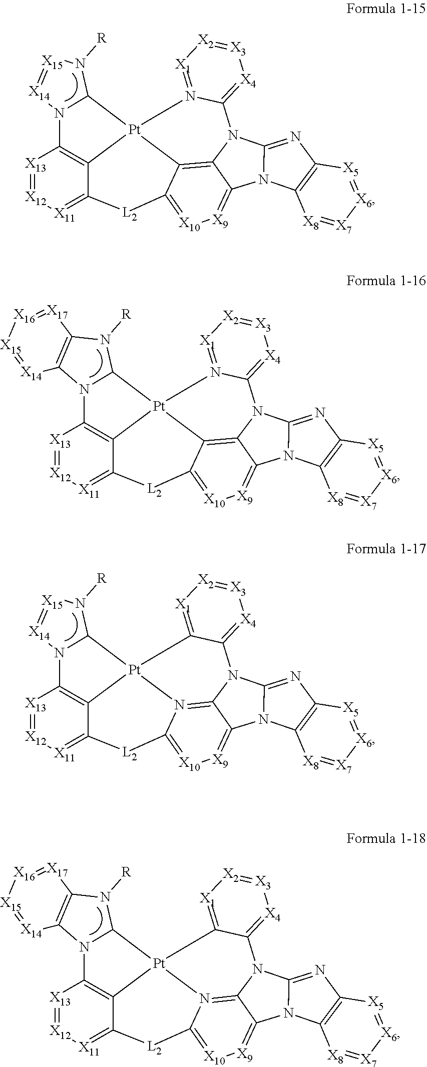 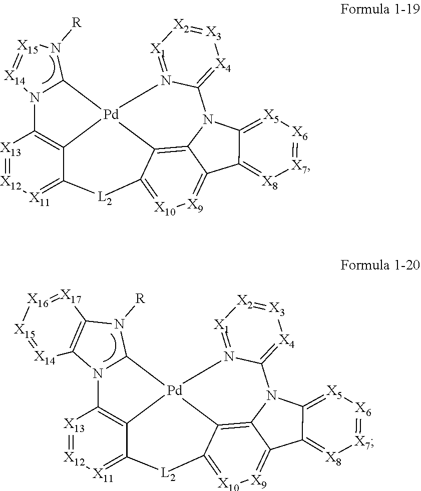
wherein in Formula 1-1 to Formula 1-20,
L₂ is, at each occurrence identically or differently, selected from a single bond, O, S, Se, (SiR″R″)_{y}, PR″, NR″, substituted or unsubstituted arylene having 6 to 30 carbon atoms or a combination thereof;
y is, at each occurrence identically or differently, selected from 1, 2, 3, 4 or 5;
X₁ to X₂₀ are, at each occurrence identically or differently, selected from CRₓ or N;
R has a structure represented by Formula 2-1: 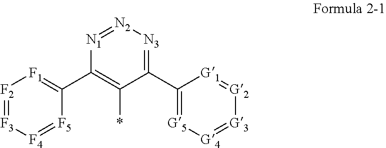
wherein in Formula 2-1, F₁ to F₅ are each independently selected from CR_{f} or N; G′₁ to G′₅ are each independently selected from CR_{g} or N; N₁ to N₃ are each independently selected from CRₙ or N;
R′, R″, Rₓ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of N₁ to N₃ is CRₙ, wherein the Rₙ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R′, R″, Rₓ, R_{f}, R_{g} and Rₙ can be optionally joined to form a ring; and
preferably, the first compound has a structure represented by Formula 1-1 or Formula 1-2.

6. The organic electroluminescent device according to claim 5, wherein N₂ is selected from CRₙ, wherein the Rₙ is, at each occurrence identically or differently, selected from the group consisting of: deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof; and
preferably, Rₙ is, at each occurrence identically or differently, selected from the group consisting of: methyl, partially or fully deuterated methyl, ethyl, partially or fully deuterated ethyl, n-propyl, partially or fully deuterated n-propyl, isopropyl, partially or fully deuterated isopropyl, cyclopropyl, partially or fully deuterated cyclopropyl, n-butyl, partially or fully deuterated n-butyl, isobutyl, partially or fully deuterated isobutyl, t-butyl, partially or fully deuterated t-butyl, cyclopentyl, partially or fully deuterated cyclopentyl, cyclohexyl, partially or fully deuterated cyclohexyl, partially or fully deuterated 2,3,3-trimethylbutan-2-yl, 2,3,3-trimethylbutan-2-yl and combinations thereof.

7. The organic electroluminescent device according to claim 1, wherein L₂ is selected from a single bond, O, S, (SiR″R″)_{y}, NR″ or a combination thereof;
preferably, L₂ is selected from a single bond, O or S; and
more preferably, L₂ is selected from O.

8. The organic electroluminescent device according to claim 5, wherein Rₓ, R′, R″, R_{f}, and R_{g} are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; and
preferably, Rₓ, R′, R″, R_{f} and R_{g} are, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

9. The organic electroluminescent device according to claim 1, wherein R is, at each occurrence identically or differently, selected from the group consisting of An-1 to An-48: 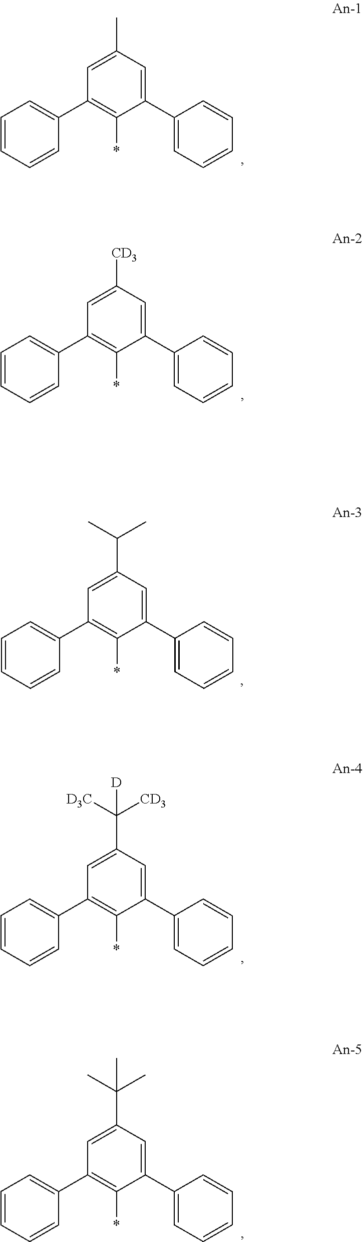 [SMILES: *c1c(-c2ccccc2)cc(C)cc1-c1ccccc1 ; *c1c(-c2ccccc2)cc(C([2H])([2H])[2H])cc1-c1ccccc1 ; *c1c(-c2ccccc2)cc(C(C)C)cc1-c1ccccc1 ; *c1c(-c2ccccc2)cc(C([2H])(C([2H])([2H])[2H])C([2H])([2H])[2H])cc1-c1ccccc1 ; *c1c(-c2ccccc2)cc(C(C)(C)C)cc1-c1ccccc1] 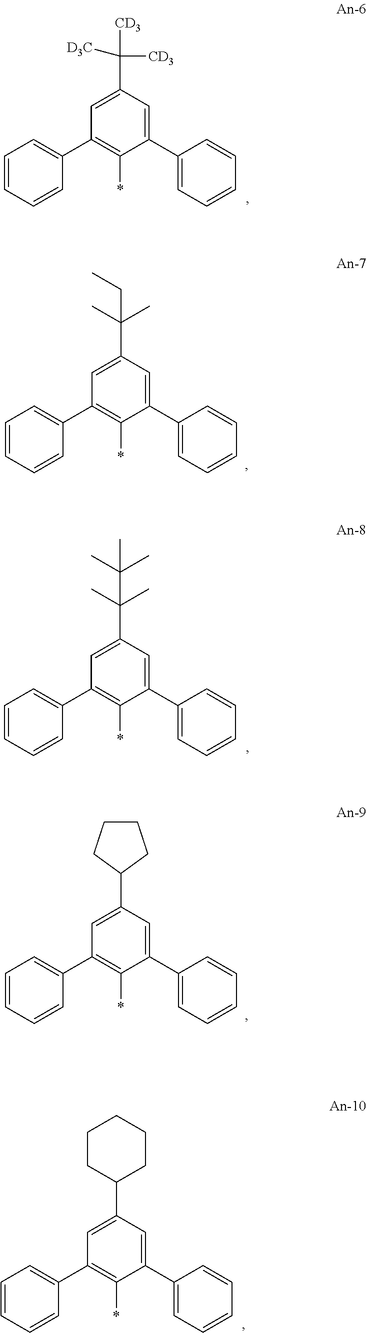 [SMILES: *c1c(-c2ccccc2)cc(C(C([2H])([2H])[2H])(C([2H])([2H])[2H])C([2H])([2H])[2H])cc1-c1ccccc1 ; *c1c(-c2ccccc2)cc(C(C)(C)CC)cc1-c1ccccc1 ; *c1c(-c2ccccc2)cc(C(C)(C)C(C)(C)C)cc1-c1ccccc1 ; *c1c(-c2ccccc2)cc(C2CCCC2)cc1-c1ccccc1 ; *c1c(-c2ccccc2)cc(C2CCCCC2)cc1-c1ccccc1] 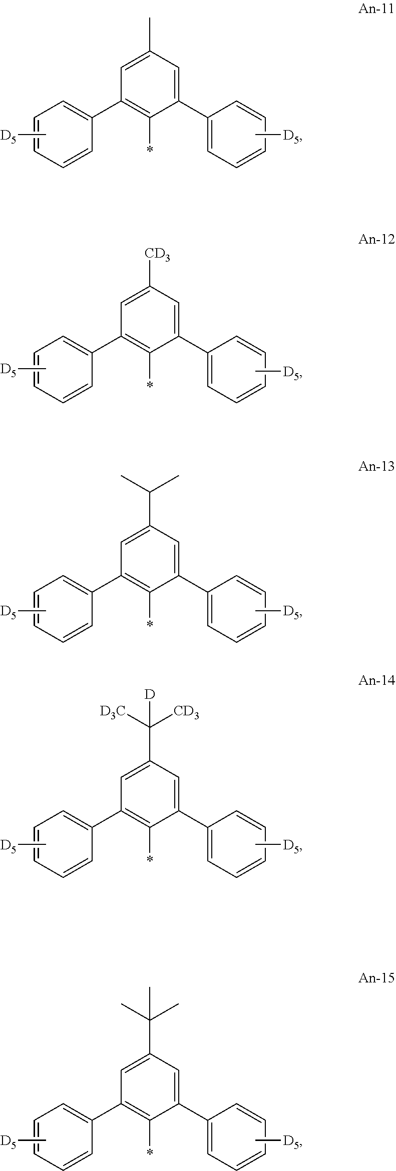 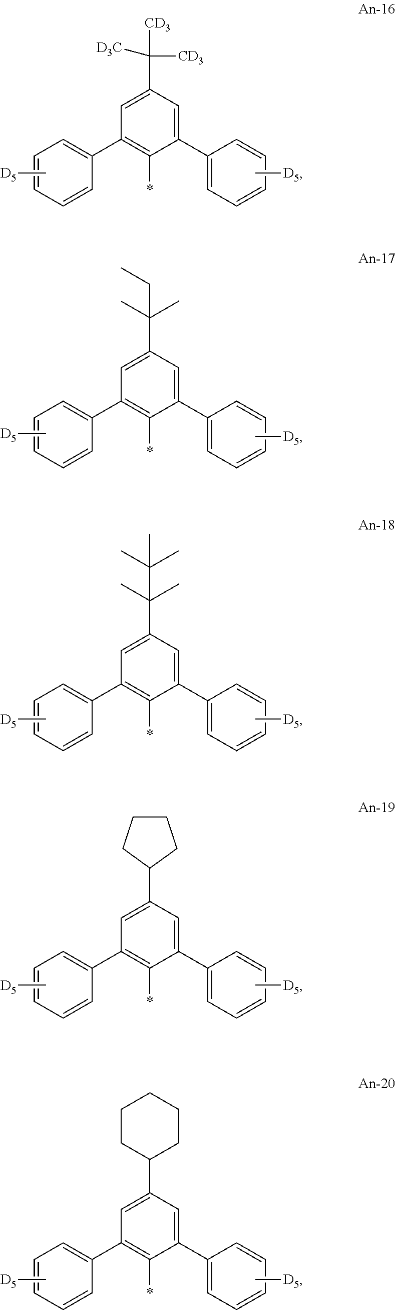 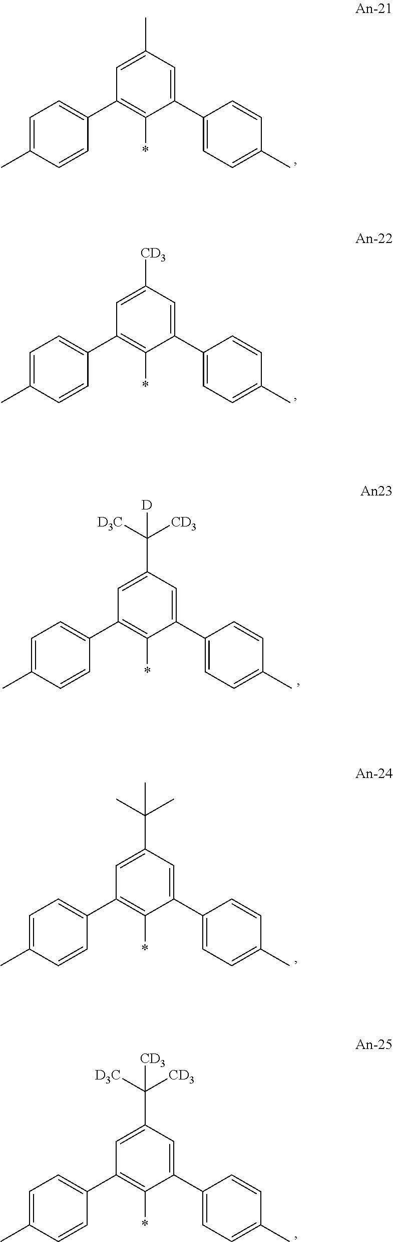 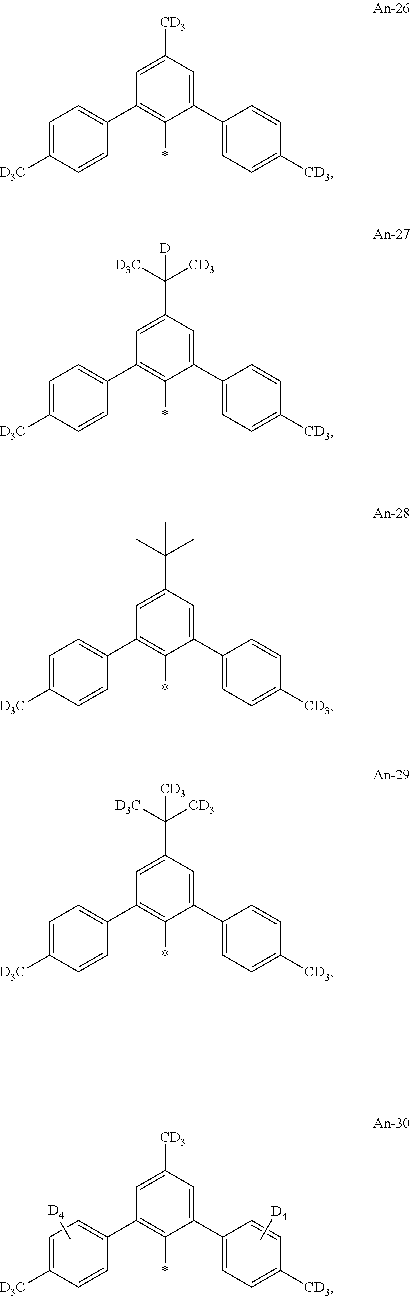 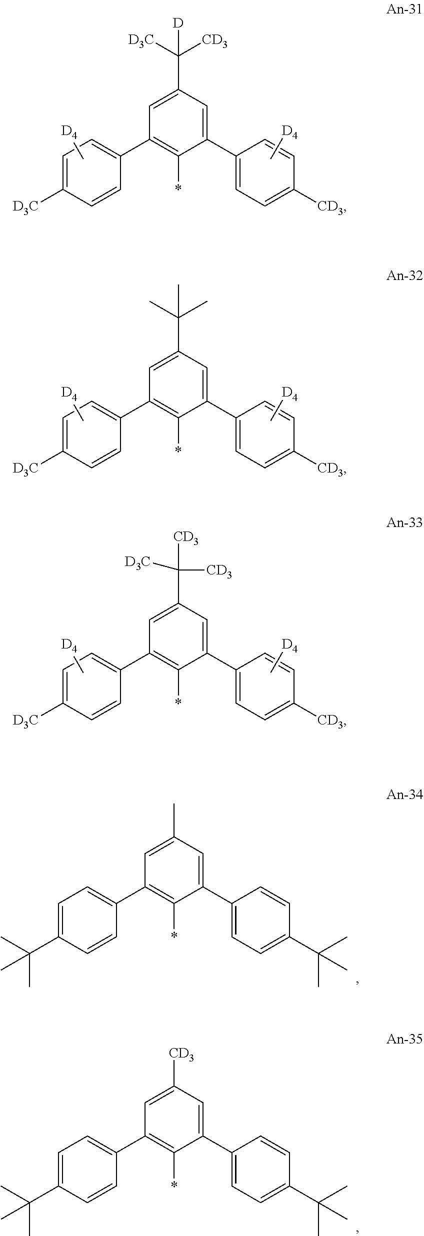 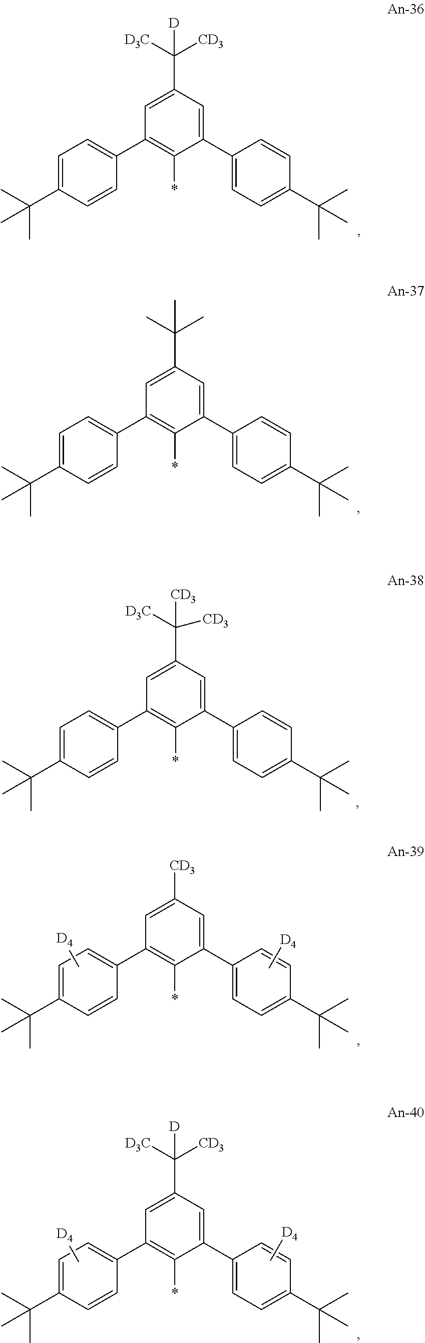 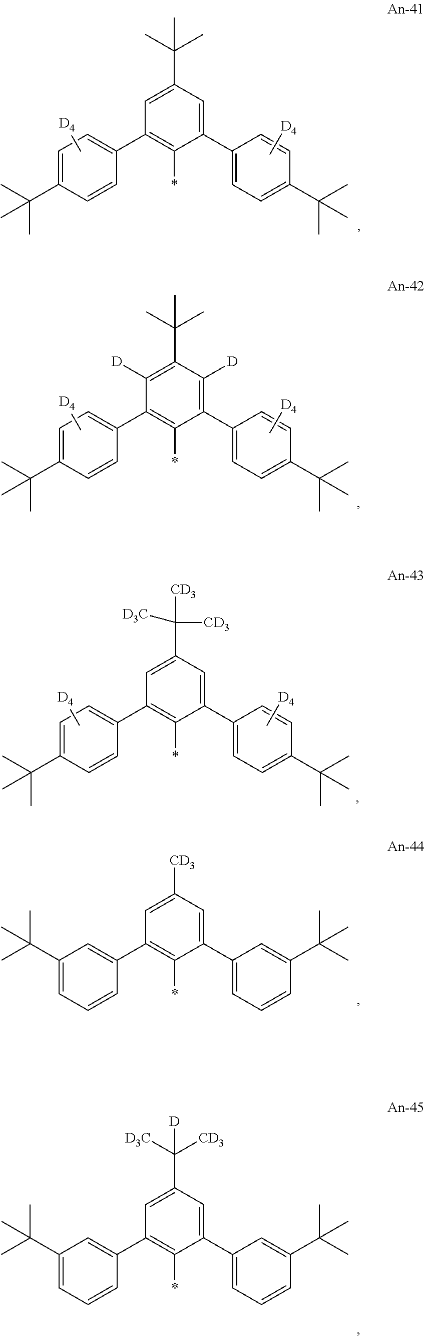 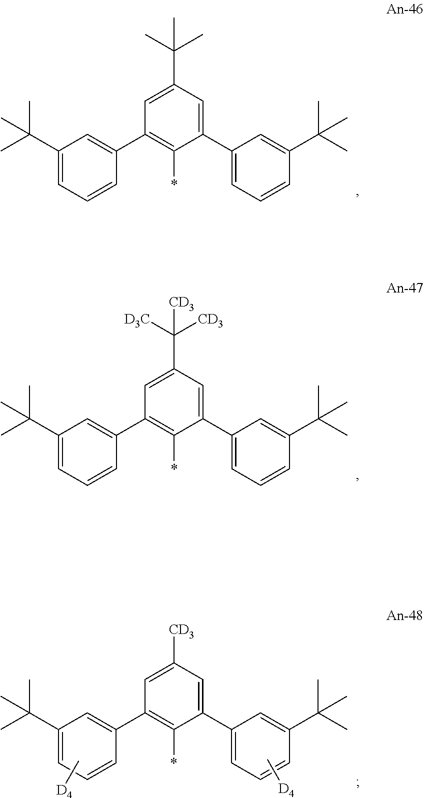
wherein optionally, hydrogens in An-1 to An-48 can be partially or fully substituted with deuterium.

10. The organic electroluminescent device according to claim 1, wherein the first compound has a structure represented by Pt(Lₐ)(L_{b}), wherein Lₐ and L_{b} are a first ligand and a second ligand coordinated to the metal Pt, respectively, and Lₐ is selected from the group consisting of Lₐ1-1 to Lₐ1-29, Lₐ2-1 to Lₐ2-20 and Lₐ3-1 to Lₐ3-7: 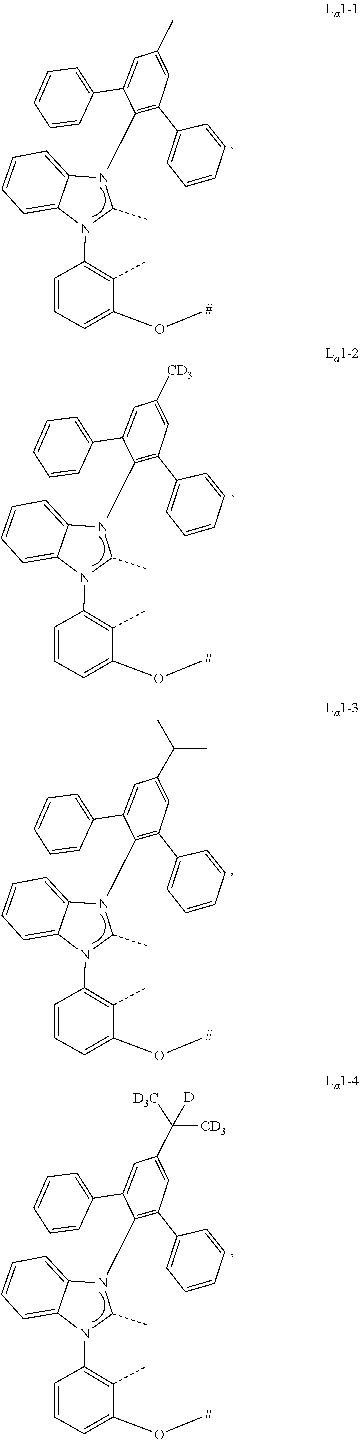 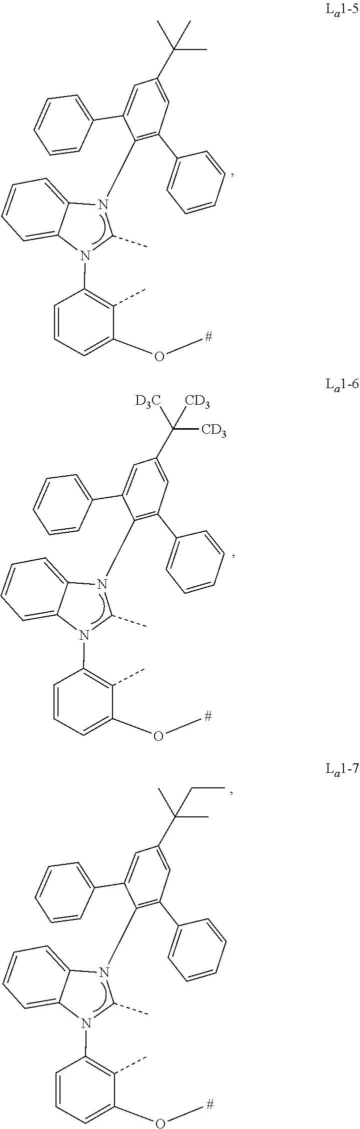 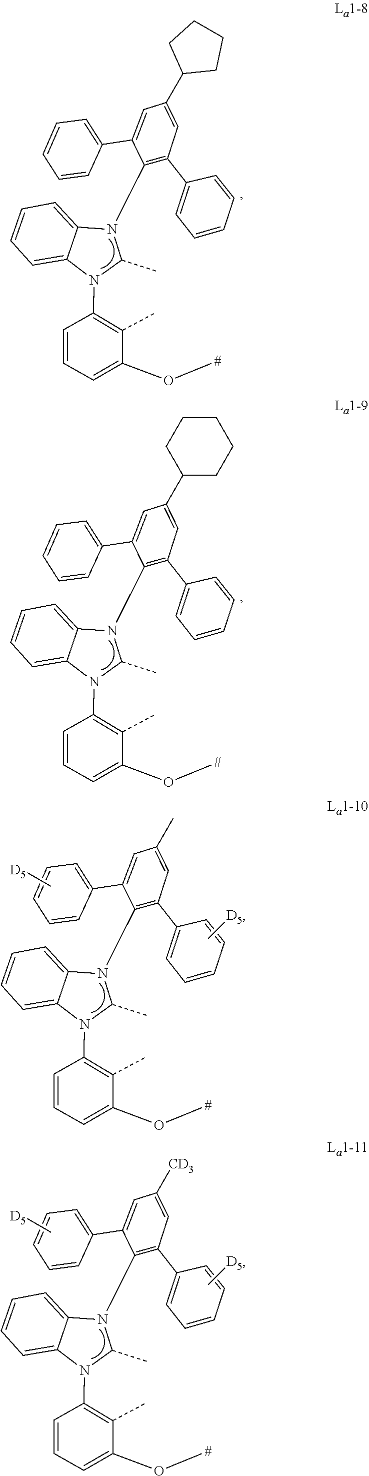 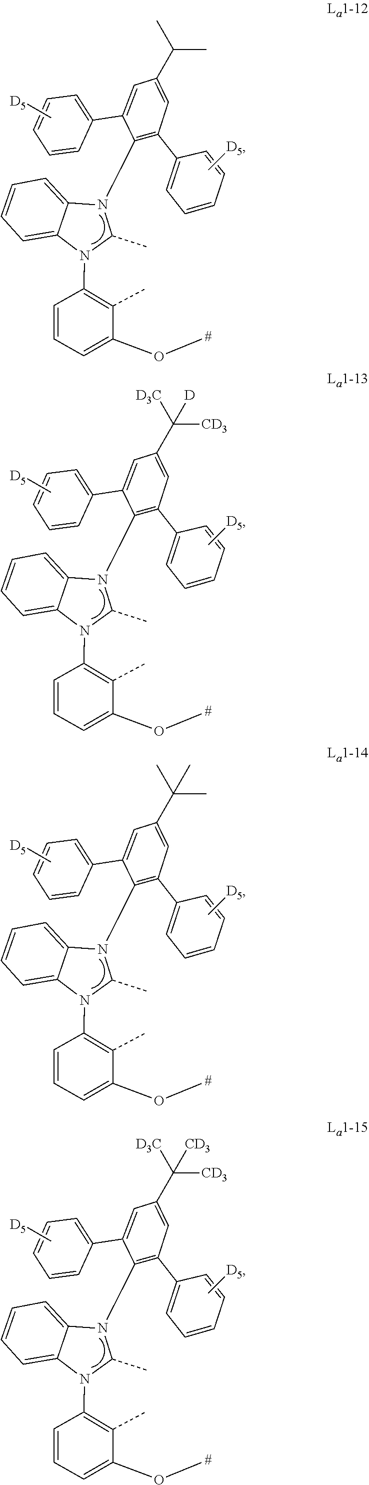 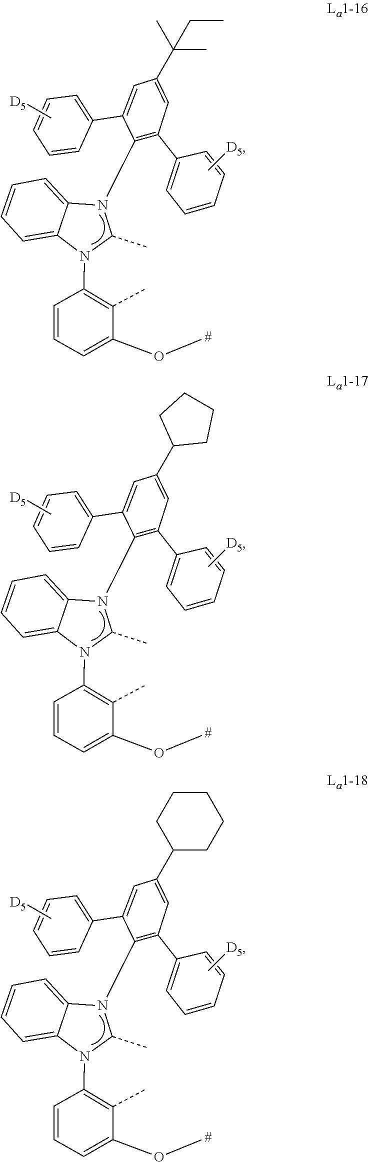 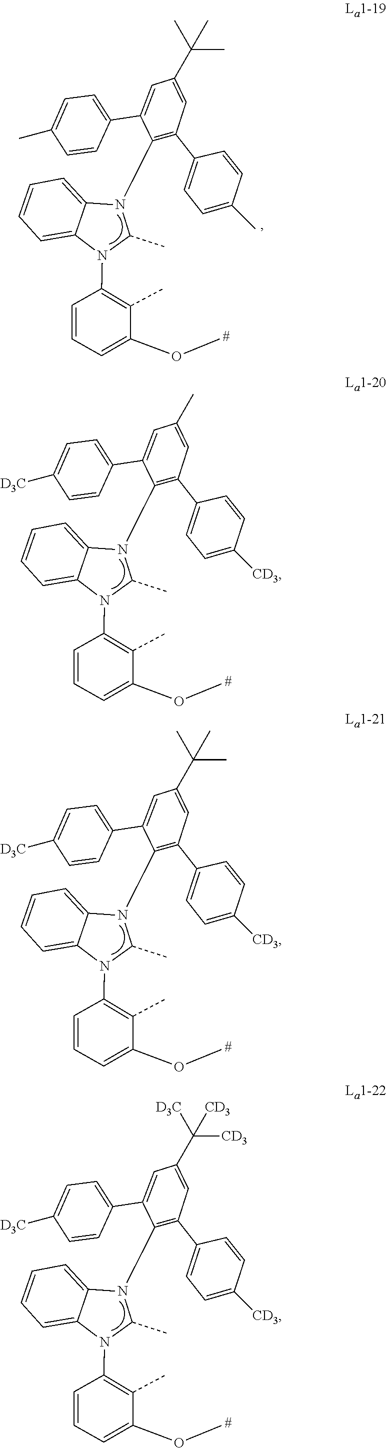 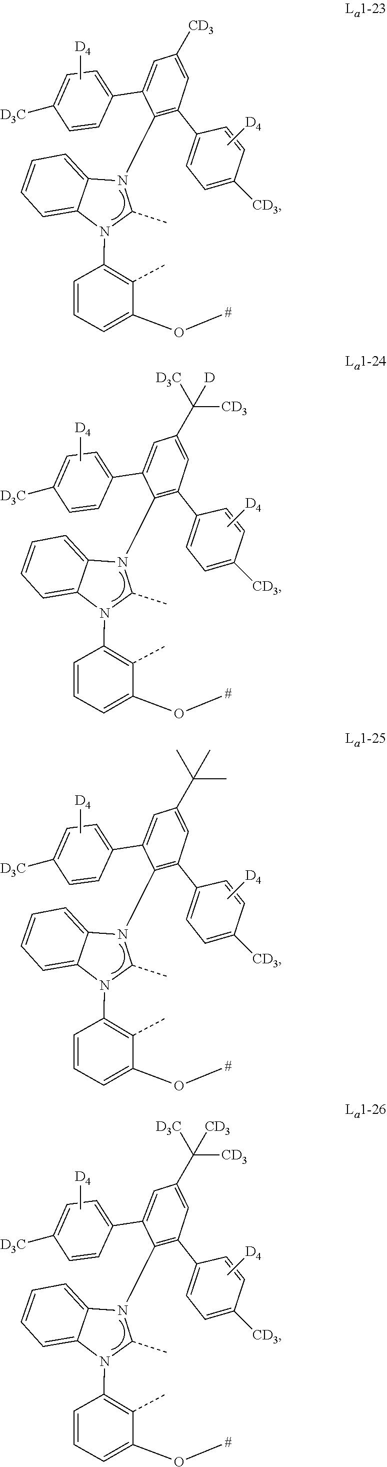 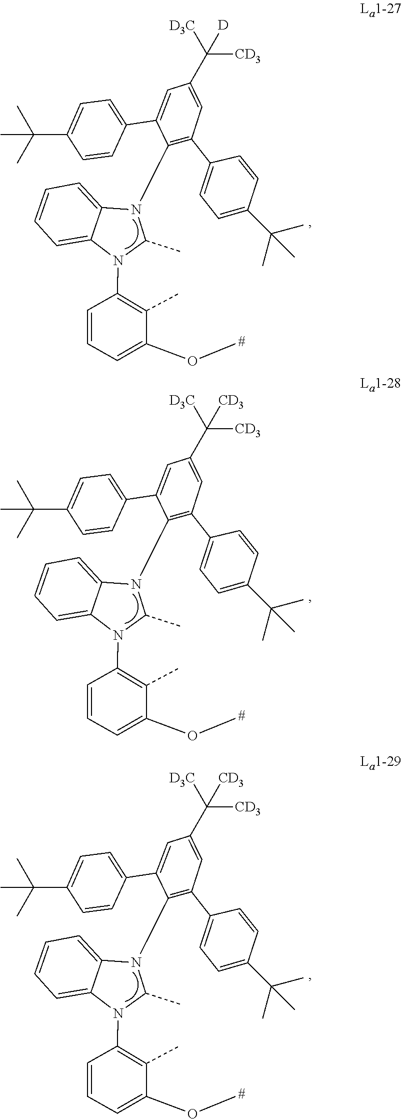 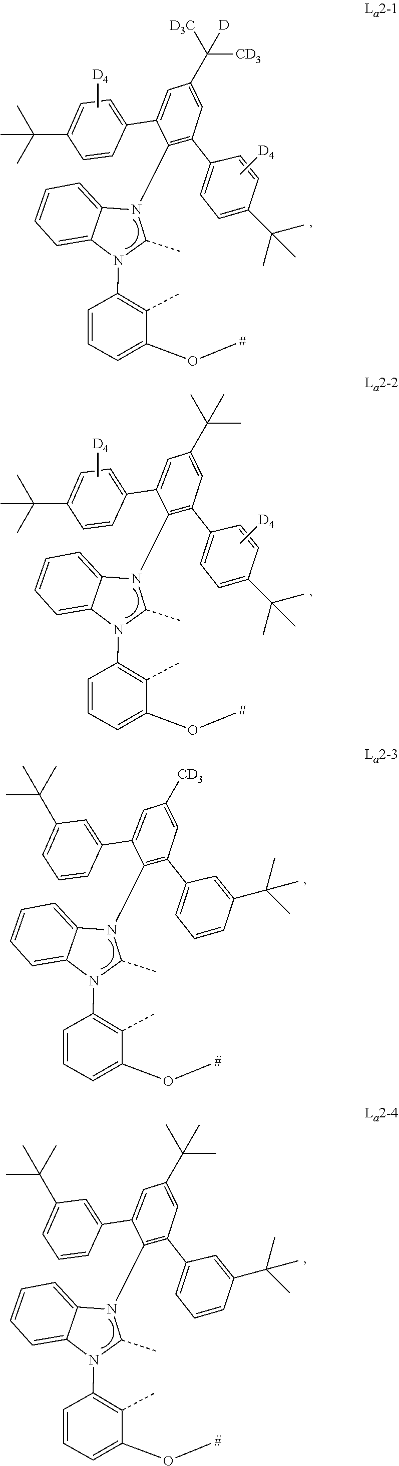 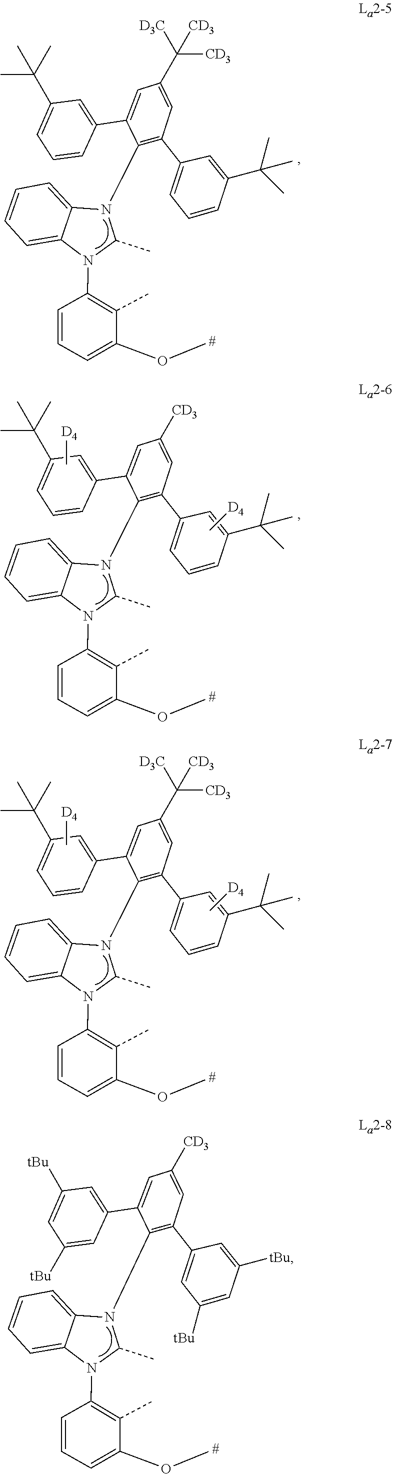 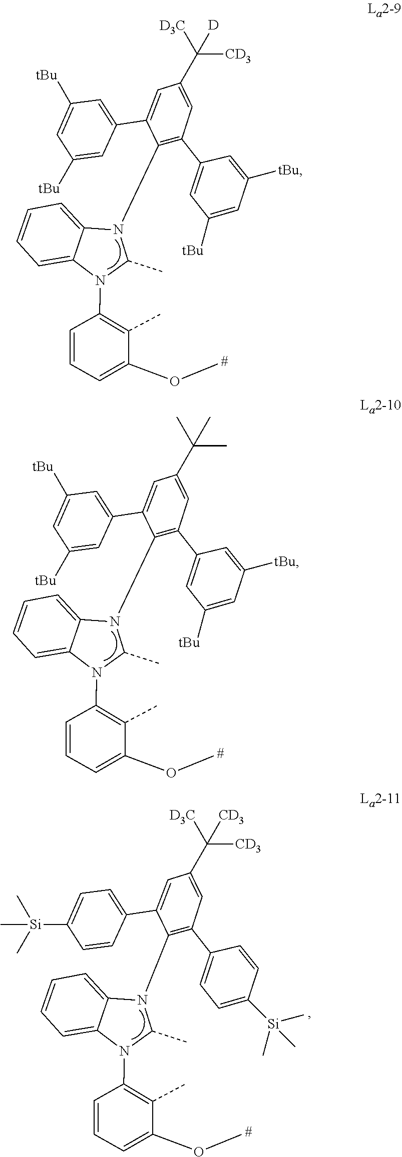 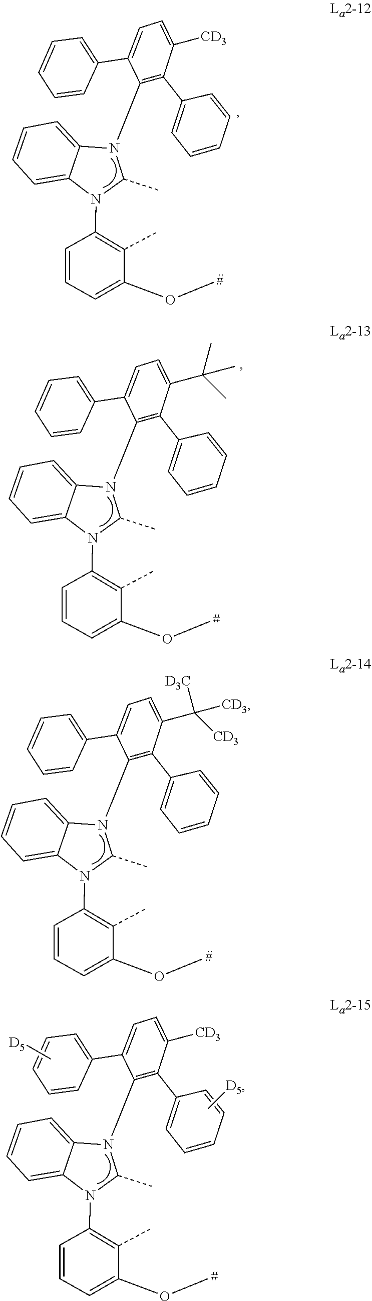 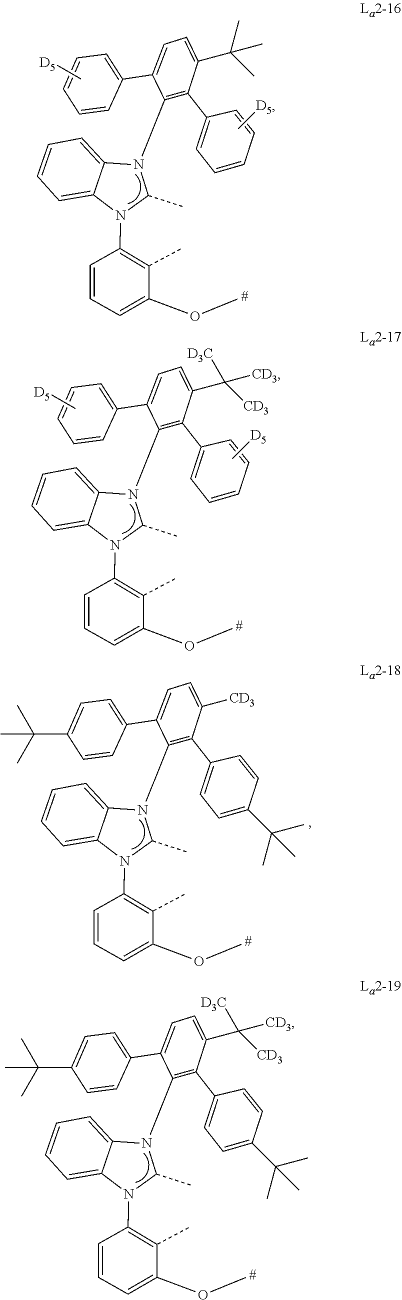 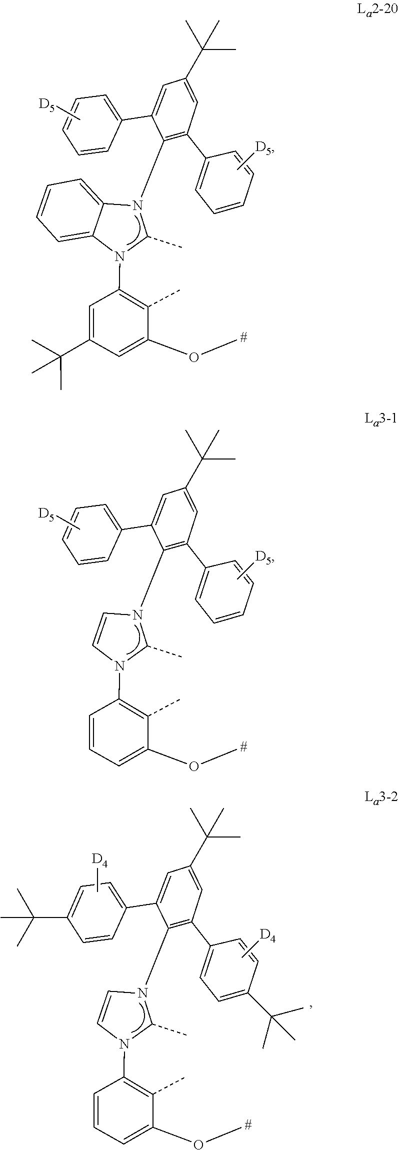 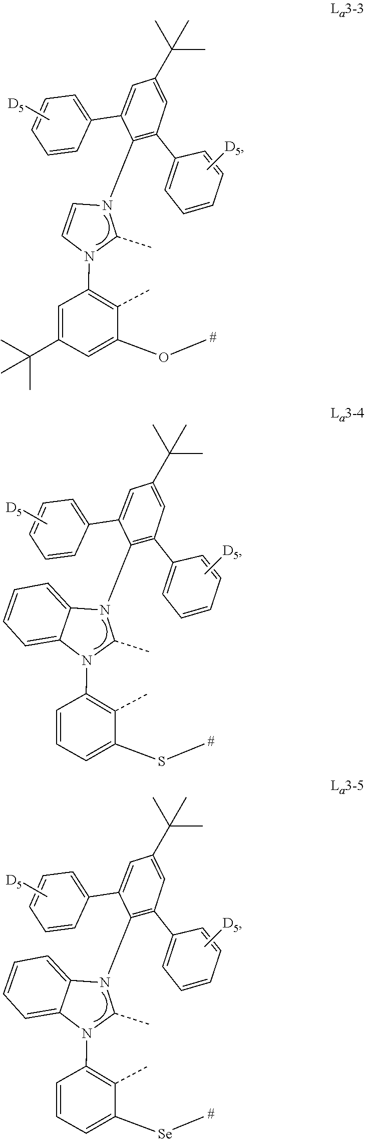 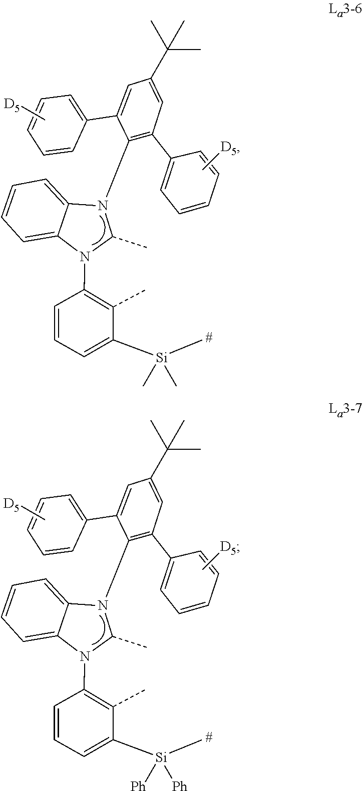
wherein in the structure of Lₐ, “tBu” represents t-butyl;
in the structure of Lₐ, “#” represents a position where the structure is joined to L_{b};
the ligand L_{b} is selected from the group consisting of L_{b}1-1 to L_{b}1-8, L_{b}2-1 to L_{b}2-22 and L_{b}3-1 to L_{b}3-8: 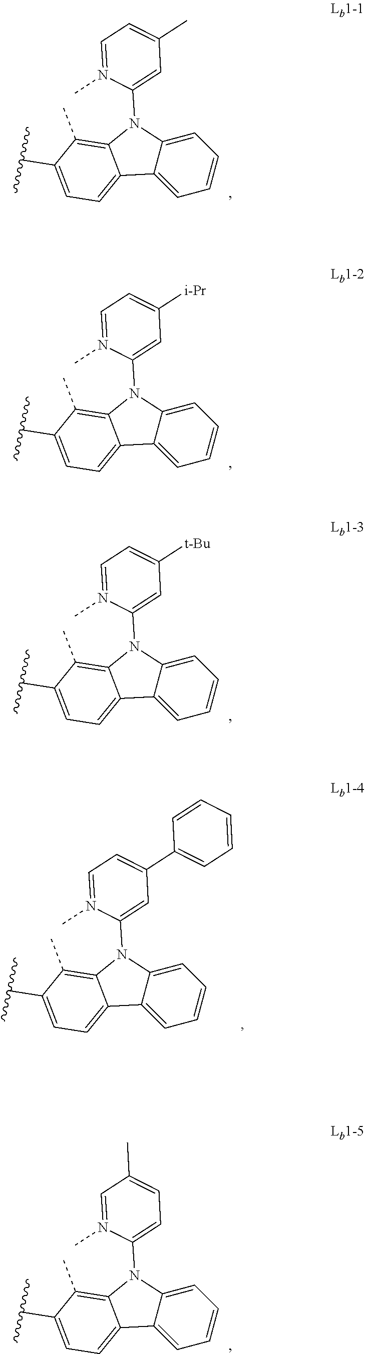 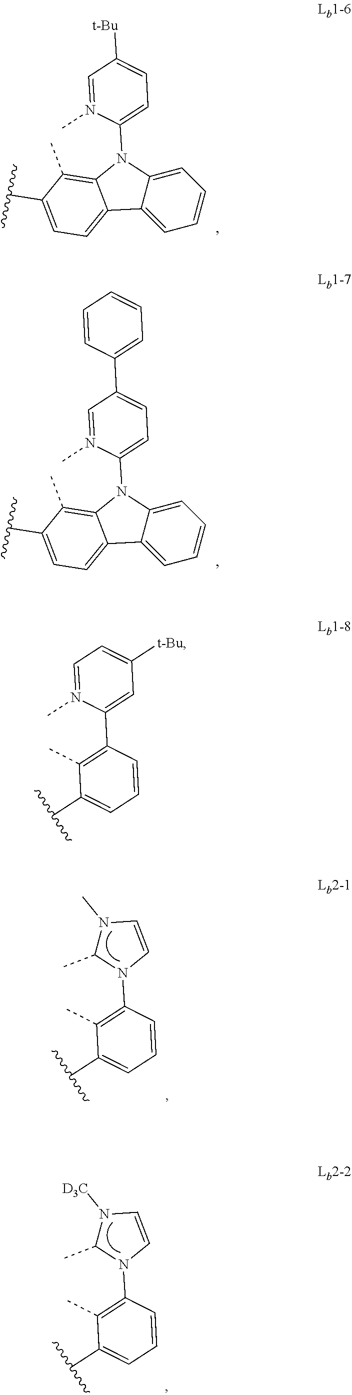 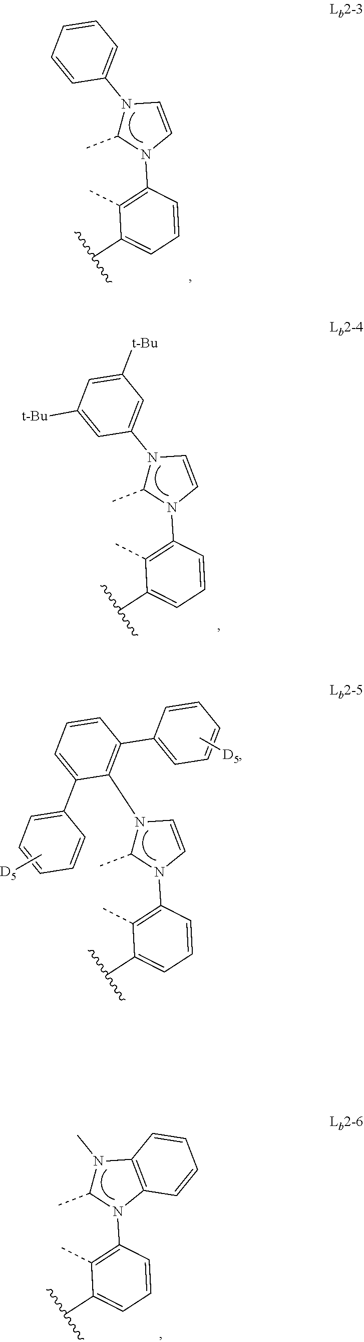 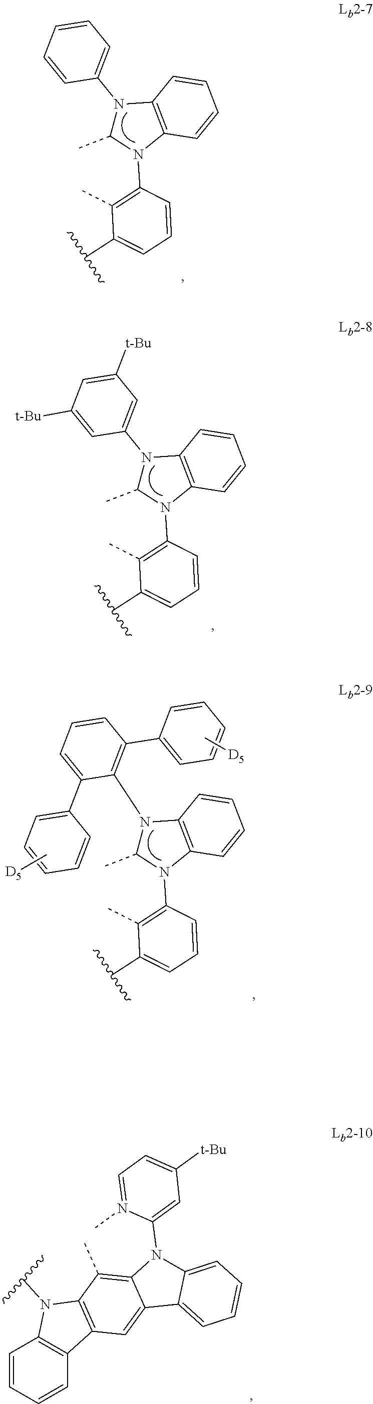 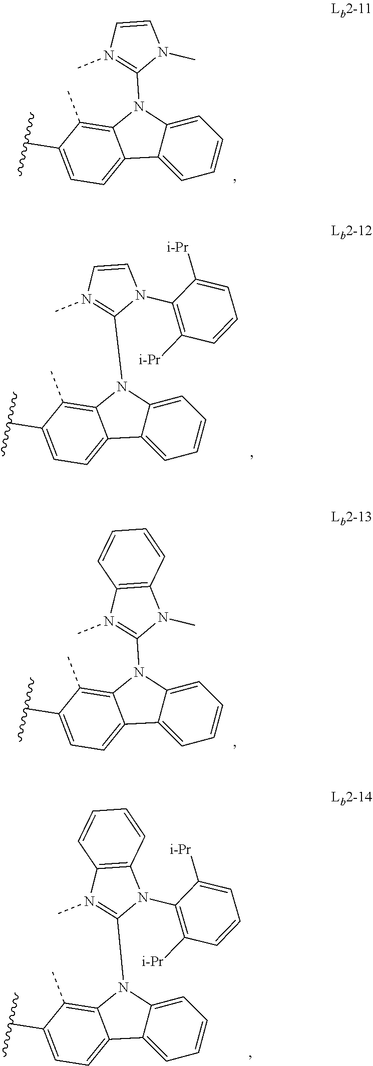 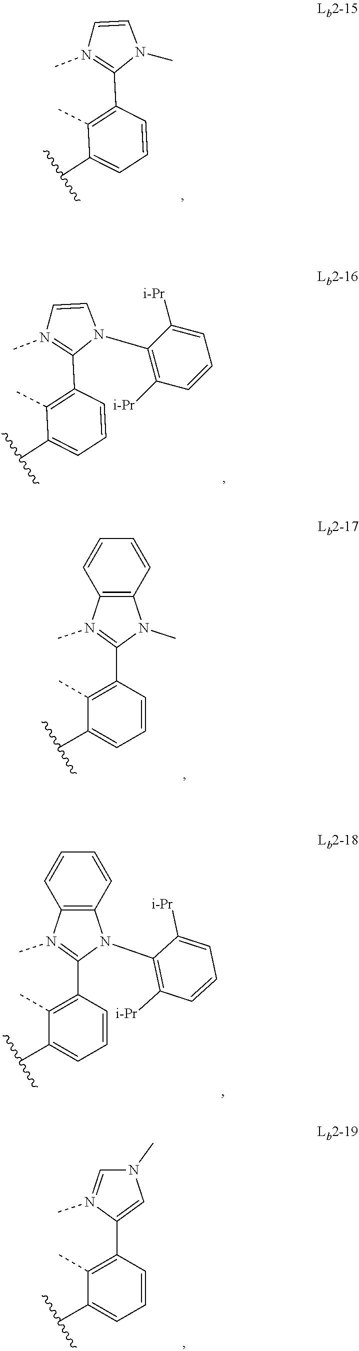 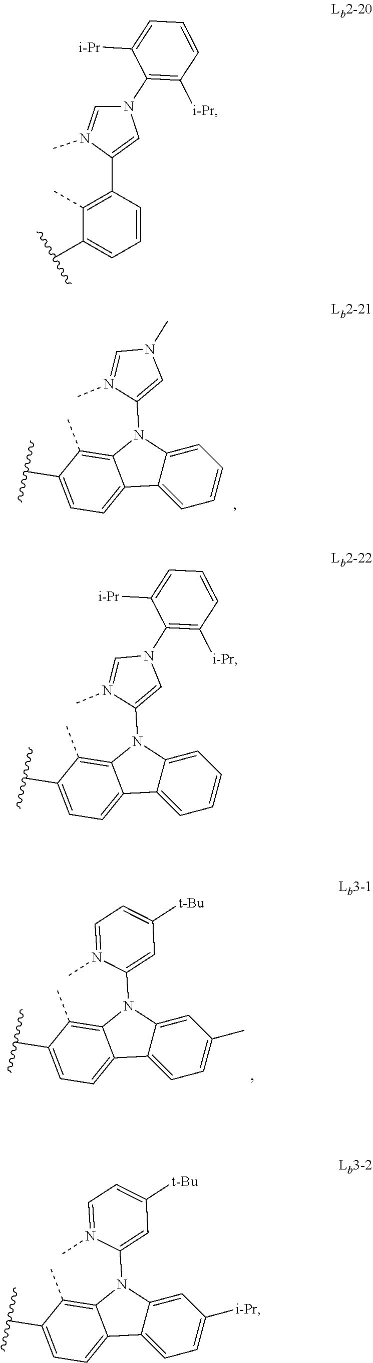 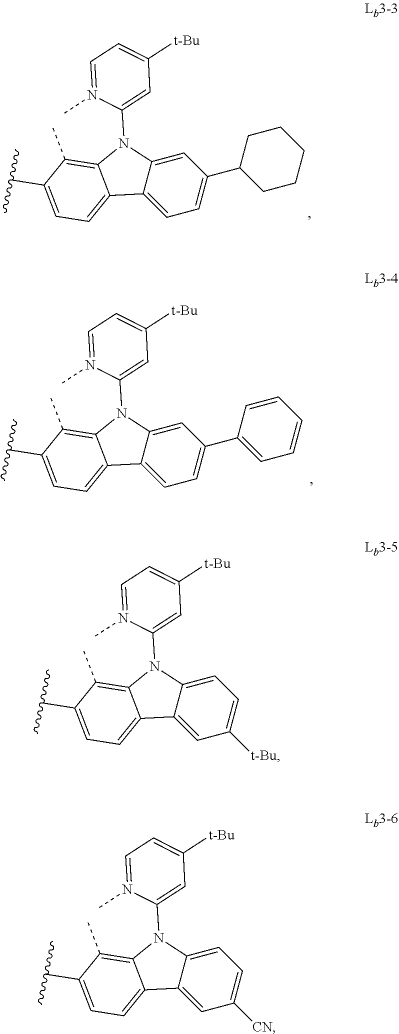 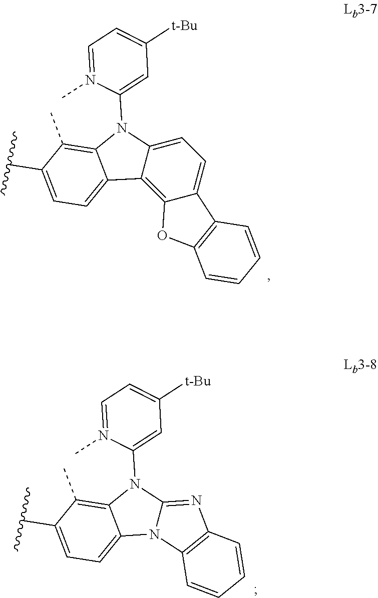
wherein in the structure of L_{b}, “t-Bu” represents t-butyl, and “i-Pr” represents isopropyl;
in the structure of L_{b}, “ [symbol] ” represents a position where the structure is joined to “#” in Lₐ;
preferably, the first compound is selected from the group consisting of Compound Pt1 to Compound Pt166, wherein Compound Pt1 to Compound Pt166 each have the structure represented by Pt(Lₐ)(L_{b}), wherein Lₐ and L_{b} are selected from the structures shown in the following table, respectively:

| Compound | | | Compound | | |
|---|---|---|---|---|---|
| No. | Lₐ | L_{b} | No. | Lₐ | L_{b} |
| Pt1 | Lₐ1-1 | L_{b}1-3 | Pt2 | Lₐ1-2 | L_{b}1-3 |
| Pt3 | Lₐ1-3 | L_{b}1-3 | Pt4 | Lₐ1-4 | L_{b}1-3 |
| Pt5 | Lₐ1-5 | L_{b}1-3 | Pt6 | Lₐ1-6 | L_{b}1-3 |
| Pt7 | Lₐ1-7 | L_{b}1-3 | Pt8 | Lₐ1-8 | L_{b}1-3 |
| Pt9 | Lₐ1-9 | L_{b}1-3 | Pt10 | Lₐ1-10 | L_{b}1-3 |
| Pt11 | Lₐ1-11 | L_{b}1-3 | Pt12 | Lₐ1-12 | L_{b}1-3 |
| Pt13 | Lₐ1-13 | L_{b}1-3 | Pt14 | Lₐ1-14 | L_{b}1-3 |
| Pt15 | Lₐ1-15 | L_{b}1-3 | Pt16 | Lₐ1-16 | L_{b}1-3 |
| Pt17 | Lₐ1-17 | L_{b}1-3 | Pt18 | Lₐ1-18 | L_{b}1-3 |
| Pt19 | Lₐ1-19 | L_{b}1-3 | Pt20 | Lₐ1-20 | L_{b}1-3 |
| Pt21 | Lₐ1-21 | L_{b}1-3 | Pt22 | Lₐ1-22 | L_{b}1-3 |
| Pt23 | Lₐ1-23 | L_{b}1-3 | Pt24 | Lₐ1-24 | L_{b}1-3 |
| Pt25 | Lₐ1-25 | L_{b}1-3 | Pt26 | Lₐ1-26 | L_{b}1-3 |
| Pt27 | Lₐ1-27 | L_{b}1-3 | Pt28 | Lₐ1-28 | L_{b}1-3 |
| Pt29 | Lₐ1-29 | L_{b}1-3 | Pt30 | Lₐ2-1 | L_{b}1-3 |
| Pt31 | Lₐ2-2 | L_{b}1-3 | Pt32 | Lₐ2-3 | L_{b}1-3 |
| Pt33 | Lₐ2-4 | L_{b}1-3 | Pt34 | Lₐ2-5 | L_{b}1-3 |
| Pt35 | Lₐ2-6 | L_{b}1-3 | Pt36 | Lₐ2-7 | L_{b}1-3 |
| Pt37 | Lₐ2-8 | L_{b}1-3 | Pt38 | Lₐ2-9 | L_{b}1-3 |
| Pt39 | Lₐ2-10 | L_{b}1-3 | Pt40 | Lₐ2-11 | L_{b}1-3 |
| Pt41 | Lₐ2-12 | L_{b}1-3 | Pt42 | Lₐ2-13 | L_{b}1-3 |
| Pt43 | Lₐ2-14 | L_{b}1-3 | Pt44 | Lₐ2-15 | L_{b}1-3 |
| Pt45 | Lₐ2-16 | L_{b}1-3 | Pt46 | Lₐ2-17 | L_{b}1-3 |
| Pt47 | Lₐ2-18 | L_{b}1-3 | Pt48 | Lₐ2-19 | L_{b}1-3 |
| Pt49 | Lₐ2-20 | L_{b}1-3 | Pt50 | Lₐ3-1 | L_{b}1-3 |
| Pt51 | Lₐ3-2 | L_{b}1-3 | Pt52 | Lₐ3-3 | L_{b}1-3 |
| Pt53 | Lₐ3-4 | L_{b}1-3 | Pt54 | Lₐ3-5 | L_{b}1-3 |
| Pt55 | Lₐ3-6 | L_{b}1-3 | Pt56 | Lₐ3-7 | L_{b}1-3 |
| Pt57 | Lₐ1-14 | L_{b}1-1 | Pt58 | Lₐ1-14 | L_{b}1-2 |
| Pt59 | Lₐ1-14 | L_{b}1-4 | Pt60 | Lₐ1-14 | L_{b}1-5 |
| Pt61 | Lₐ1-14 | L_{b}1-6 | Pt62 | Lₐ1-14 | L_{b}1-7 |
| Pt63 | Lₐ1-14 | L_{b}1-8 | Pt64 | Lₐ1-14 | L_{b}2-1 |
| Pt65 | Lₐ1-14 | L_{b}2-2 | Pt66 | Lₐ1-14 | L_{b}2-3 |
| Pt67 | Lₐ1-14 | L_{b}2-4 | Pt68 | Lₐ1-14 | L_{b}2-5 |
| Pt69 | Lₐ1-14 | L_{b}2-6 | Pt70 | Lₐ1-14 | L_{b}2-7 |
| Pt71 | Lₐ1-14 | L_{b}2-8 | Pt72 | Lₐ1-14 | L_{b}2-9 |
| Pt73 | Lₐ1-14 | L_{b}2-10 | Pt74 | Lₐ1-14 | L_{b}2-11 |
| Pt75 | Lₐ1-14 | L_{b}2-12 | Pt76 | Lₐ1-14 | L_{b}2-13 |
| Pt77 | Lₐ1-14 | L_{b}2-14 | Pt78 | Lₐ1-14 | L_{b}2-15 |
| Pt79 | Lₐ1-14 | L_{b}2-16 | Pt80 | Lₐ1-14 | L_{b}2-17 |
| Pt81 | Lₐ1-14 | L_{b}2-18 | Pt82 | Lₐ1-14 | L_{b}2-19 |
| Pt83 | Lₐ1-14 | L_{b}2-20 | Pt84 | Lₐ1-14 | L_{b}2-21 |
| Pt85 | Lₐ1-14 | L_{b}2-22 | Pt86 | Lₐ1-14 | L_{b}3-1 |
| Pt87 | Lₐ1-14 | L_{b}3-2 | Pt88 | Lₐ1-14 | L_{b}3-3 |
| Pt89 | Lₐ1-14 | L_{b}3-4 | Pt90 | Lₐ1-14 | L_{b}3-5 |
| Pt91 | Lₐ1-14 | L_{b}3-6 | Pt92 | Lₐ1-14 | L_{b}3-7 |
| Pt93 | Lₐ1-14 | L_{b}3-8 | Pt94 | Lₐ2-10 | L_{b}1-1 |
| Pt95 | Lₐ2-10 | L_{b}1-2 | Pt96 | Lₐ2-10 | L_{b}1-4 |
| Pt97 | Lₐ2-10 | L_{b}1-5 | Pt98 | Lₐ2-10 | L_{b}1-6 |
| Pt99 | Lₐ2-10 | L_{b}1-7 | Pt100 | Lₐ2-10 | L_{b}1-8 |
| Pt101 | Lₐ2-10 | L_{b}2-1 | Pt102 | Lₐ2-10 | L_{b}2-2 |
| Pt103 | Lₐ2-10 | L_{b}2-3 | Pt104 | Lₐ2-10 | L_{b}2-4 |
| Pt105 | Lₐ2-10 | L_{b}2-5 | Pt106 | Lₐ2-10 | L_{b}2-6 |
| Pt107 | Lₐ2-10 | L_{b}2-7 | Pt108 | Lₐ2-10 | L_{b}2-8 |
| Pt109 | Lₐ2-10 | L_{b}2-9 | Pt110 | Lₐ2-10 | L_{b}2-10 |
| Pt111 | Lₐ2-10 | L_{b}2-11 | Pt112 | Lₐ2-10 | L_{b}2-12 |
| Pt113 | Lₐ2-10 | L_{b}2-13 | Pt114 | Lₐ2-10 | L_{b}2-14 |
| Pt115 | Lₐ2-10 | L_{b}2-15 | Pt116 | Lₐ2-10 | L_{b}2-16 |
| Pt117 | Lₐ2-10 | L_{b}2-17 | Pt118 | Lₐ2-10 | L_{b}2-18 |
| Pt119 | Lₐ2-10 | L_{b}2-19 | Pt120 | Lₐ2-10 | L_{b}2-20 |
| Pt121 | Lₐ2-10 | L_{b}2-21 | Pt122 | Lₐ2-10 | L_{b}2-22 |
| Pt123 | Lₐ2-10 | L_{b}3-1 | Pt124 | Lₐ2-10 | L_{b}3-2 |
| Pt125 | Lₐ2-10 | L_{b}3-3 | Pt126 | Lₐ2-10 | L_{b}3-4 |
| Pt127 | Lₐ2-10 | L_{b}3-5 | Pt128 | Lₐ2-10 | L_{b}3-6 |
| Pt129 | Lₐ2-10 | L_{b}3-7 | Pt130 | Lₐ2-10 | L_{b}3-8 |
| Pt131 | Lₐ3-3 | L_{b}1-1 | Pt132 | Lₐ3-3 | L_{b}1-2 |
| Pt133 | Lₐ3-3 | L_{b}1-4 | Pt134 | Lₐ3-3 | L_{b}1-5 |
| Pt135 | Lₐ3-3 | L_{b}1-6 | Pt136 | Lₐ3-3 | L_{b}1-7 |
| Pt137 | Lₐ3-3 | L_{b}1-8 | Pt138 | Lₐ3-3 | L_{b}2-1 |
| Pt139 | Lₐ3-3 | L_{b}2-2 | Pt140 | Lₐ3-3 | L_{b}2-3 |
| Pt141 | Lₐ3-3 | L_{b}2-4 | Pt142 | Lₐ3-3 | L_{b}2-5 |
| Pt143 | Lₐ3-3 | L_{b}2-6 | Pt144 | Lₐ3-3 | L_{b}2-7 |
| Pt145 | Lₐ3-3 | L_{b}2-8 | Pt146 | Lₐ3-3 | L_{b}2-9 |
| Pt147 | Lₐ3-3 | L_{b}2-10 | Pt148 | Lₐ3-3 | L_{b}2-11 |
| Pt149 | Lₐ3-3 | L_{b}2-12 | Pt150 | Lₐ3-3 | L_{b}2-13 |
| Pt151 | Lₐ3-3 | L_{b}2-14 | Pt152 | Lₐ3-3 | L_{b}2-15 |
| Pt153 | Lₐ3-3 | L_{b}2-16 | Pt154 | Lₐ3-3 | L_{b}2-17 |
| Pt155 | Lₐ3-3 | L_{b}2-18 | Pt156 | Lₐ3-3 | L_{b}2-19 |
| Pt157 | Lₐ3-3 | L_{b}2-20 | Pt158 | Lₐ3-3 | L_{b}2-21 |
| Pt159 | Lₐ3-3 | L_{b}2-22 | Pt160 | Lₐ3-3 | L_{b}3-1 |
| Pt161 | Lₐ3-3 | L_{b}3-2 | Pt162 | Lₐ3-3 | L_{b}3-3 |
| Pt163 | Lₐ3-3 | L_{b}3-4 | Pt164 | Lₐ3-3 | L_{b}3-5 |
| Pt165 | Lₐ3-3 | L_{b}3-6 | Pt166 | Lₐ3-3 | L_{b}3-7 |

11. The organic electroluminescent device according to claim 1, wherein the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, an aza-aromatic ring group and any one of the following groups substituted by one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof; and
preferably, the electron withdrawing group is selected from the group consisting of: F, CF₃, OCF₃, SF₅, SO₂CF₃, a cyano group, an isocyano group, SCN, OCN, pyrimidinyl, triazinyl and combinations thereof.

12. The organic electroluminescent device according to claim 1, wherein X and Y are, at each occurrence identically or differently, selected from the group consisting of the following structures:
O, S, Se, 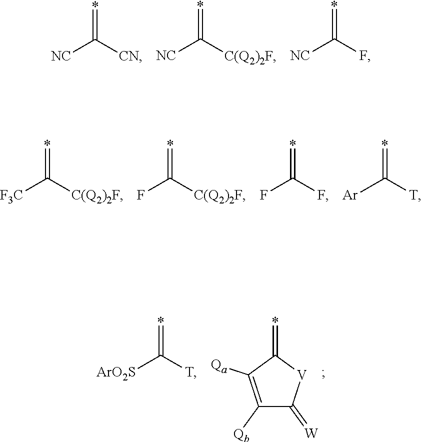
wherein V and W are, at each occurrence identically or differently, selected from CQᵥQ_{w}, NQᵥ, O, S or Se;
Ar is, at each occurrence identically or differently, selected from substituted or unsubstituted aryl having 6 to 30 carbon atoms or substituted or unsubstituted heteroaryl having 3 to 30 carbon atoms;
T, Q₂, Qₐ, Q_{b}, Qᵥ and Q_{w} are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof;
preferably, Q₂ is, at each occurrence identically or differently, selected from the group consisting of: F, CF₃, OCF₃, SFs, SO₂CF₃, a cyano group, an isocyano group, SCN, OCN, pentafluorophenyl, 4-cyanotetrafluorophenyl, tetrafluoropyridyl, pyrimidinyl, triazinyl and combinations thereof;
T is a group having at least one electron withdrawing group, and for any one of the structures, when one or more of Qₐ, Q_{b}, Qᵥ and Q_{w} are present, at least one of Qₐ, Q_{b}, Qᵥ and Q_{w} is a group having at least one electron withdrawing group; preferably, the group having the at least one electron withdrawing group is selected from the group consisting of: F, CF₃, OCF₃, SF₅, SO₂CF₃, a cyano group, an isocyano group, SCN, OCN, pentafluorophenyl, 4-cyanotetrafluorophenyl, tetrafluoropyridyl, pyrimidinyl, triazinyl and combinations thereof;
preferably, X and Y are, at each occurrence identically or differently, selected from the group consisting of the following structures:
O, S, Se, 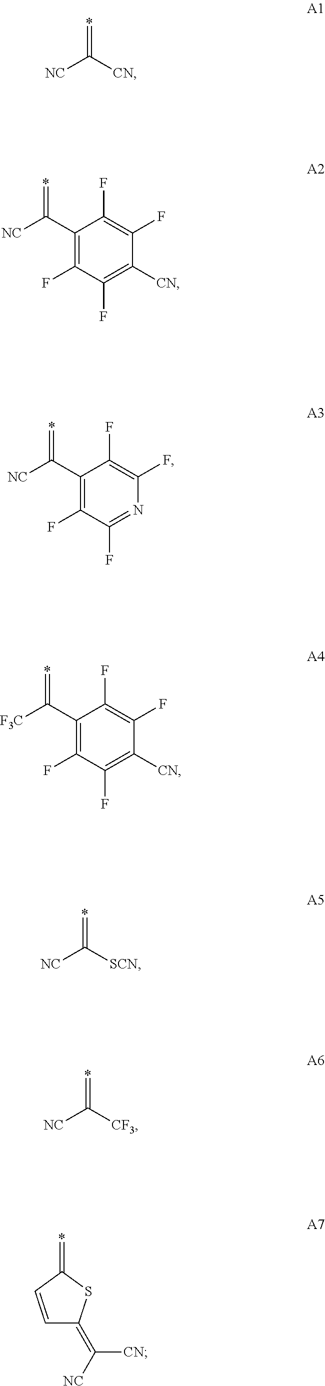
wherein “ [symbol] ” represents a position where each of the groups X and Y is joined to the five-membered ring shown in Formula 3.

13. The organic electroluminescent device according to claim 1, wherein Q is, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, unsubstituted alkyl having 1 to 20 carbon atoms, unsubstituted cycloalkyl having 3 to 20 ring carbon atoms, unsubstituted alkoxy having 1 to 20carbon atoms, unsubstituted alkenyl having 2 to 20 carbon atoms, unsubstituted aryl having 6 to 30 carbon atoms, unsubstituted heteroaryl having 3 to 30 carbon atoms and any one of the following groups substituted by one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group and a phosphoroso group:
alkyl having 1 to 20 carbon atoms, cycloalkyl having 3 to 20 ring carbon atoms, alkoxy having 1 to 20 carbon atoms, alkenyl having 2 to 20 carbon atoms, alkynyl having 2 to 20 carbon atoms, aryl having 6 to 30 carbon atoms, heteroaryl having 3 to 30 carbon atoms and combinations thereof; and
preferably, Q is, at each occurrence identically or differently, selected from the group consisting of: hydrogen, deuterium, methyl, isopropyl, NO₂, SO₂CH₃, SCF₃, C₂F5, OC₂F₅, OCH₃, diphenylmethylsilyl, phenyl, methoxyphenyl, p-methylphenyl, 2,6-diisopropylphenyl, biphenyl, polyfluorophenyl, difluoropyridyl, nitrophenyl, dimethylthiazolyl, vinyl substituted by one or more of CN or CF₃, acetenyl substituted by one of CN or CF₃, dimethylphosphoroso, diphenylphosphoroso, F, CF₃, OCF₃, SF₅, SO₂CF₃, a cyano group, an isocyano group, SCN, OCN, trifluoromethylphenyl, trifluoromethoxyphenyl, bis(trifluoromethyl)phenyl, bis(trifluoromethoxy)phenyl, 4-cyanotetrafluorophenyl, phenyl or biphenyl substituted by one or more of F, CN or CF₃, tetrafluoropyridyl, pyrimidinyl, triazinyl, diphenylboryl, oxaboraanthryl and combinations thereof.

14. The organic electroluminescent device according to claim 12, wherein Q is, at each occurrence identically or differently, selected from the group consisting of the following structures: 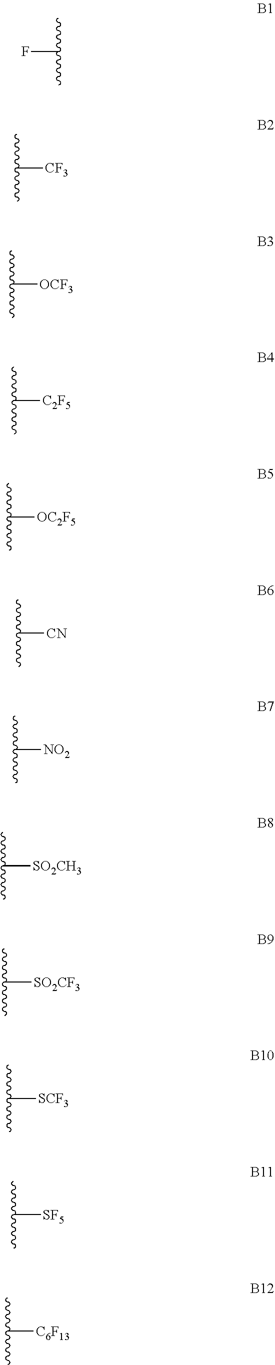 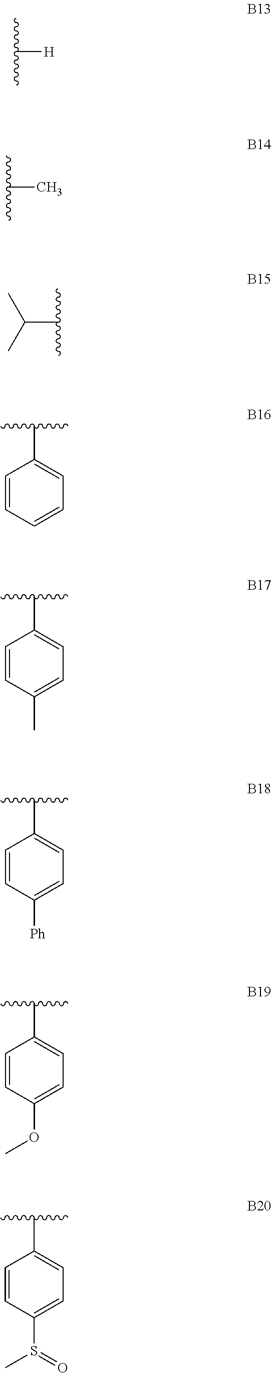 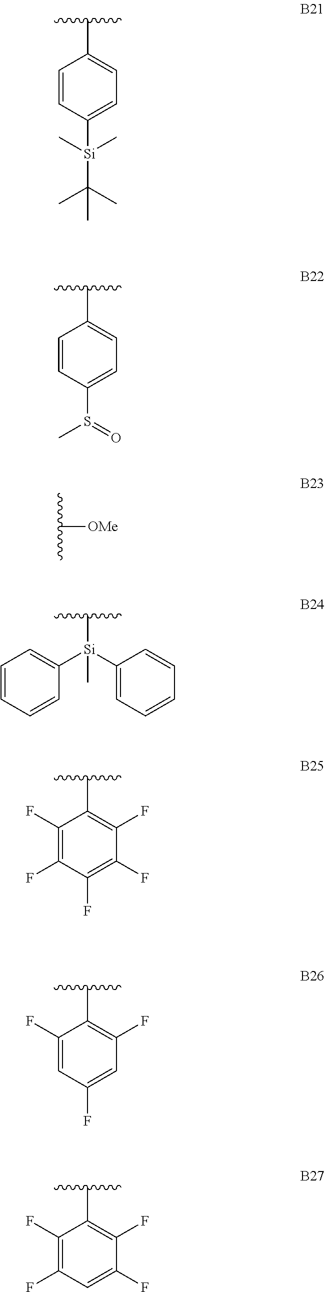 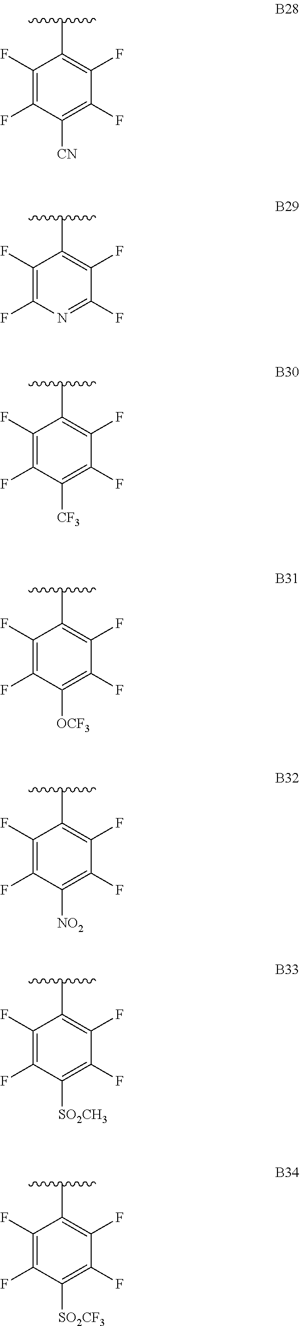 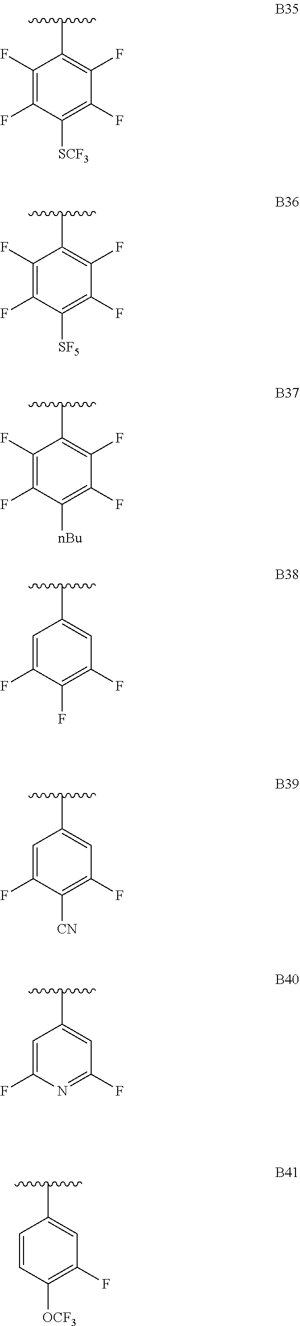 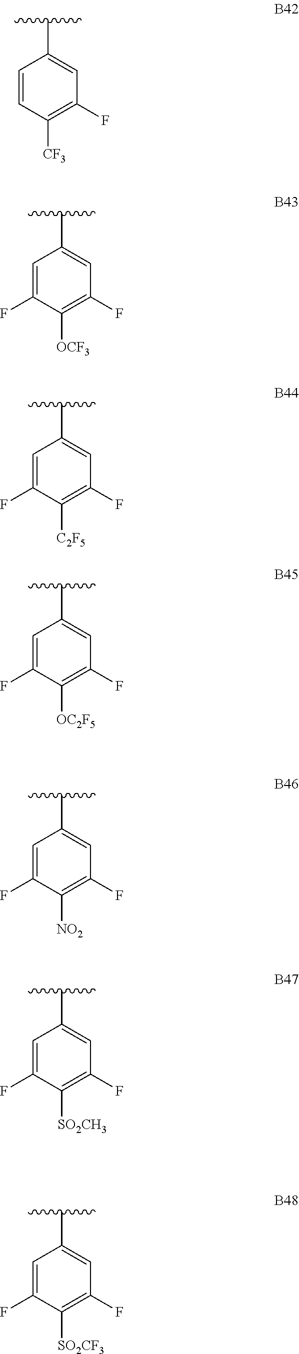 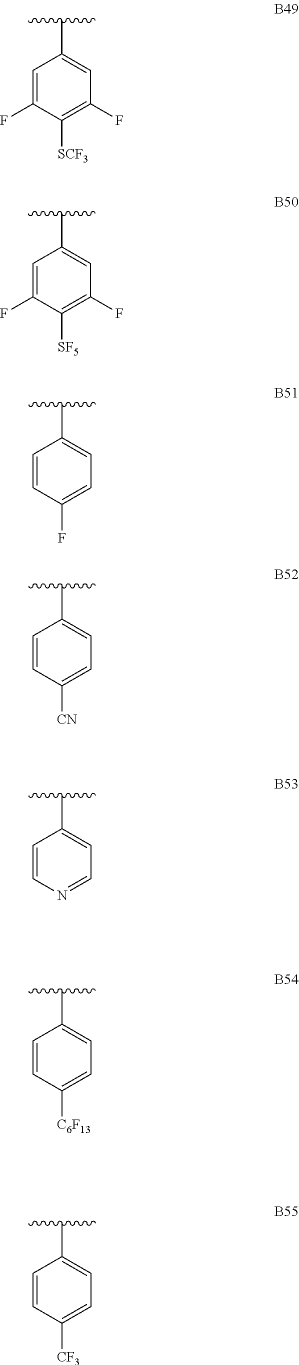 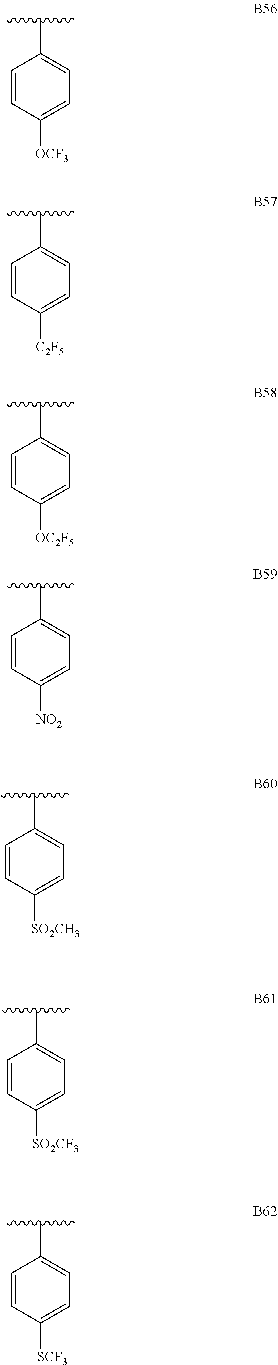 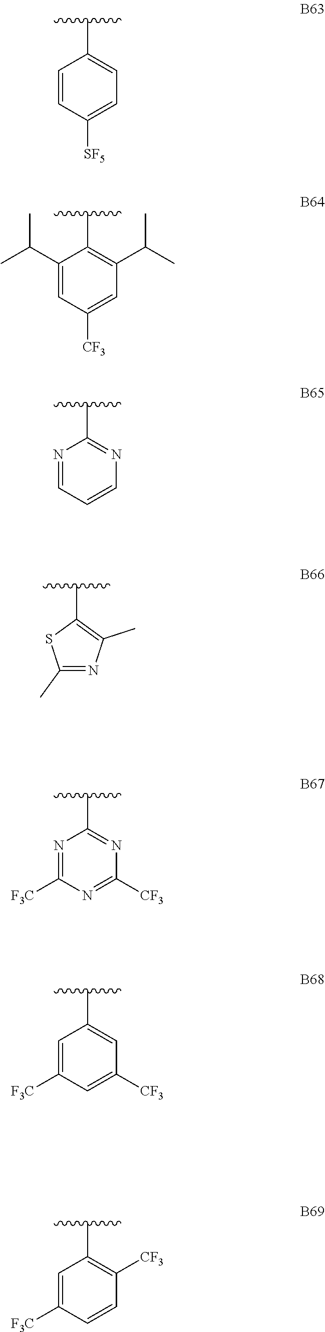 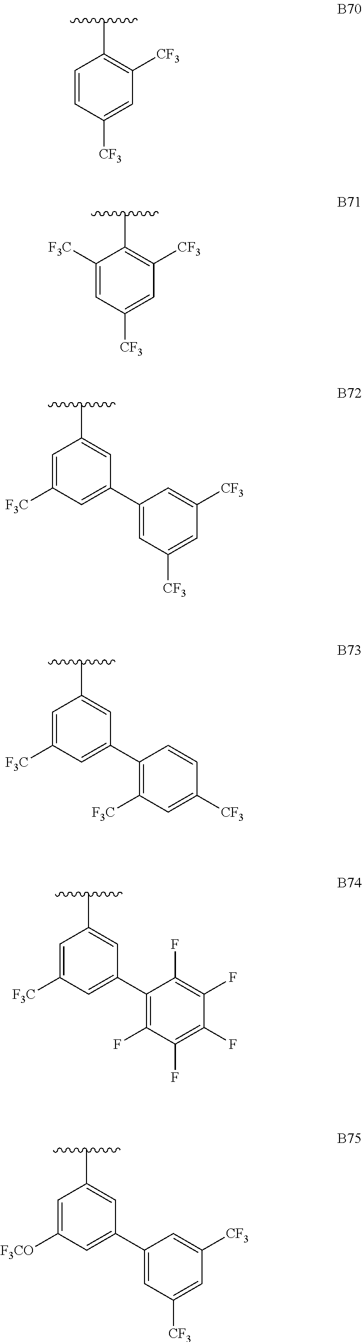 [SMILES: *c1ccc(C(F)(F)F)cc1C(F)(F)F ; *c1c(C(F)(F)F)cc(C(F)(F)F)cc1C(F)(F)F ; *c1cc(-c2cc(C(F)(F)F)cc(C(F)(F)F)c2)cc(C(F)(F)F)c1 ; *c1cc(-c2ccc(C(F)(F)F)cc2C(F)(F)F)cc(C(F)(F)F)c1 ; *c1cc(-c2c(F)c(F)c(F)c(F)c2F)cc(C(F)(F)F)c1 ; *c1cc(OC(F)(F)F)cc(-c2cc(C(F)(F)F)cc(C(F)(F)F)c2)c1] 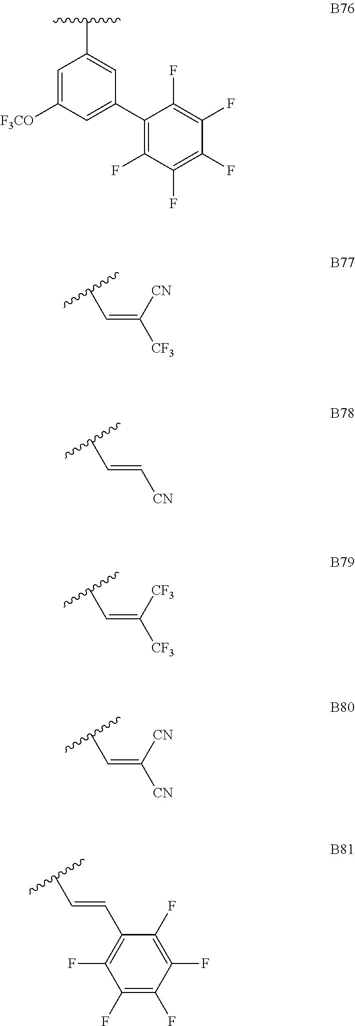 [SMILES: *c1cc(OC(F)(F)F)cc(-c2c(F)c(F)c(F)c(F)c2F)c1 ; */C=C(\C#N)C(F)(F)F ; */C=C/C#N ; *C=C(C(F)(F)F)C(F)(F)F ; *C=C(C#N)C#N ; */C=C/c1c(F)c(F)c(F)c(F)c1F] 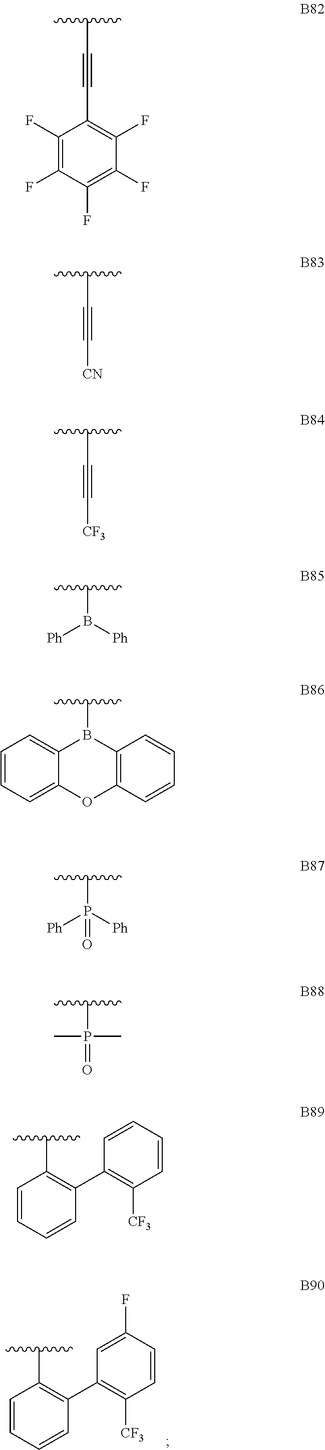
wherein preferably, two Q in the second compound represented by Formula 3 are the same; and
“ [symbol] ” represents a position where the group Q is joined to the six-membered ring shown in Formula 3.

15. The organic electroluminescent device according to claim 14, wherein the second compound is selected from the group consisting of Compound 1 to Compound 182, wherein Compound 1 to Compound 182 each have a structure represented by Formula 3-1: 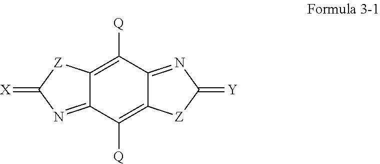
wherein in Formula 3-1, two Z have the same structure, two Q have the same structure or different structures, and Z, X, Y and Q are respectively and correspondingly selected from the atoms or the groups shown in the following table;

| Compound | | | | | | Compound | | | | | |
|---|---|---|---|---|---|---|---|---|---|---|---|
| No. | Z | X | Y | Q | Q | No. | Z | X | Y | Q | Q |
| 1 | O | A1 | A1 | B1 | B1 | 2 | O | A1 | A1 | B2 | B2 |
| 3 | O | A1 | A1 | B3 | B3 | 4 | O | A1 | A1 | B4 | B4 |
| 5 | O | A1 | A1 | B5 | B5 | 6 | O | A1 | A1 | B6 | B6 |
| 7 | O | A1 | A1 | B7 | B7 | 8 | O | A1 | A1 | B8 | B8 |
| 9 | O | A1 | A1 | B9 | B9 | 10 | O | A1 | A1 | B10 | B10 |
| 11 | O | A1 | A1 | B11 | B11 | 12 | O | A1 | A1 | B12 | B12 |
| 13 | O | A1 | A1 | B13 | B13 | 14 | O | A1 | A1 | B14 | B14 |
| 15 | O | A1 | A1 | B15 | B15 | 16 | O | A1 | A1 | B16 | B16 |
| 17 | O | A1 | A1 | B17 | B17 | 18 | O | A1 | A1 | B18 | B18 |
| 19 | O | A1 | A1 | B19 | B19 | 20 | O | A1 | A1 | B20 | B20 |
| 21 | O | A1 | A1 | B21 | B21 | 22 | O | A1 | A1 | B22 | B22 |
| 23 | O | A1 | A1 | B23 | B23 | 24 | O | A1 | A1 | B24 | B24 |
| 25 | O | A1 | A1 | B25 | B25 | 26 | O | A1 | A1 | B26 | B26 |
| 27 | O | A1 | A1 | B27 | B27 | 28 | O | A1 | A1 | B28 | B28 |
| 29 | O | A1 | A1 | B29 | B29 | 30 | O | A1 | A1 | B30 | B30 |
| 31 | O | A1 | A1 | B31 | B31 | 32 | O | A1 | A1 | B32 | B32 |
| 33 | O | A1 | A1 | B33 | B33 | 34 | O | A1 | A1 | B34 | B34 |
| 35 | O | A1 | A1 | B35 | B35 | 36 | O | A1 | A1 | B36 | B36 |
| 37 | O | A1 | A1 | B37 | B37 | 38 | O | A1 | A1 | B38 | B38 |
| 39 | O | A1 | A1 | B39 | B39 | 40 | O | A1 | A1 | B40 | B40 |
| 41 | O | A1 | A1 | B41 | B41 | 42 | O | A1 | A1 | B42 | B42 |
| 43 | O | A1 | A1 | B43 | B43 | 44 | O | A1 | A1 | B44 | B44 |
| 45 | O | A1 | A1 | B45 | B45 | 46 | O | A1 | A1 | B46 | B46 |
| 47 | O | A1 | A1 | B47 | B47 | 48 | O | A1 | A1 | B48 | B48 |
| 49 | O | A1 | A1 | B49 | B49 | 50 | O | A1 | A1 | B50 | B50 |
| 51 | O | A1 | A1 | B51 | B51 | 52 | O | A1 | A1 | B52 | B52 |
| 53 | O | A1 | A1 | B53 | B53 | 54 | O | A1 | A1 | B54 | B54 |
| 55 | O | A1 | A1 | B55 | B55 | 56 | O | A1 | A1 | B56 | B56 |
| 57 | O | A1 | A1 | B57 | B57 | 58 | O | A1 | A1 | B58 | B58 |
| 59 | O | A1 | A1 | B59 | B59 | 60 | O | A1 | A1 | B60 | B60 |
| 61 | O | A1 | A1 | B61 | B61 | 62 | O | A1 | A1 | B62 | B62 |
| 63 | O | A1 | A1 | B63 | B63 | 64 | O | A1 | A1 | B64 | B64 |
| 65 | O | A1 | A1 | B65 | B65 | 66 | O | A1 | A1 | B66 | B66 |
| 67 | O | A1 | A1 | B67 | B67 | 68 | O | A1 | A1 | B68 | B68 |
| 69 | O | A1 | A1 | B69 | B69 | 70 | O | A1 | A1 | B70 | B70 |
| 71 | O | A1 | A1 | B71 | B71 | 72 | O | A1 | A1 | B72 | B72 |
| 73 | O | A1 | A1 | B73 | B73 | 74 | O | A1 | A1 | B74 | B74 |
| 75 | O | A1 | A1 | B75 | B75 | 76 | O | A1 | A1 | B76 | B76 |
| 77 | O | A1 | A1 | B77 | B77 | 78 | O | A1 | A1 | B78 | B78 |
| 79 | O | A1 | A1 | B79 | B79 | 80 | O | A1 | A1 | B80 | B80 |
| 81 | O | A1 | A1 | B81 | B81 | 82 | O | A1 | A1 | B82 | B82 |
| 83 | O | A1 | A1 | B83 | B83 | 84 | O | A1 | A1 | B84 | B84 |
| 85 | O | A1 | A1 | B85 | B85 | 86 | O | A1 | A1 | B86 | B86 |
| 87 | O | A1 | A1 | B87 | B87 | 88 | O | A1 | A1 | B88 | B88 |
| 89 | S | A1 | A1 | B1 | B1 | 90 | S | A1 | A1 | B2 | B2 |
| 91 | S | A1 | A1 | B29 | B29 | 92 | S | A1 | A1 | B30 | B30 |
| 93 | S | A1 | A1 | B71 | B71 | 94 | S | A1 | A1 | B72 | B72 |
| 95 | S | A1 | A1 | B83 | B83 | 96 | S | A1 | A1 | B84 | B84 |
| 97 | Se | A1 | A1 | B1 | B1 | 98 | Se | A1 | A1 | B2 | B2 |
| 99 | Se | A1 | A1 | B29 | B29 | 100 | Se | A1 | A1 | B30 | B30 |
| 101 | Se | A1 | A1 | B71 | B71 | 102 | Se | A1 | A1 | B72 | B72 |
| 103 | Se | A1 | A1 | B83 | B83 | 104 | Se | A1 | A1 | B84 | B84 |
| 105 | O | A2 | A2 | B70 | B70 | 106 | O | A2 | A2 | B71 | B71 |
| 107 | S | A2 | A2 | B70 | B70 | 108 | S | A2 | A2 | B71 | B71 |
| 109 | Se | A2 | A2 | B70 | B70 | 110 | Se | A2 | A2 | B71 | B71 |
| 111 | O | A3 | A3 | B70 | B70 | 112 | O | A3 | A3 | B71 | B71 |
| 113 | S | A3 | A3 | B70 | B70 | 114 | S | A3 | A3 | B71 | B71 |
| 115 | Se | A3 | A3 | B70 | B70 | 116 | Se | A3 | A3 | B71 | B71 |
| 117 | O | A4 | A4 | B70 | B70 | 118 | O | A4 | A4 | B71 | B71 |
| 119 | S | A4 | A4 | B70 | B70 | 120 | S | A4 | A4 | B71 | B71 |
| 121 | Se | A4 | A4 | B70 | B70 | 122 | Se | A4 | A4 | B71 | B71 |
| 123 | O | A1 | A1 | B1 | B6 | 124 | O | A1 | A1 | B2 | B6 |
| 125 | O | A1 | A1 | B25 | B26 | 126 | O | A1 | A1 | B27 | B28 |
| 127 | O | A1 | A1 | B29 | B30 | 128 | O | A1 | A1 | B39 | B40 |
| 129 | O | A1 | A1 | B54 | B41 | 130 | O | A1 | A1 | B54 | B52 |
| 131 | O | A1 | A1 | B52 | B56 | 132 | O | A1 | A1 | B55 | B56 |
| 133 | O | A1 | A1 | B64 | B56 | 134 | O | A1 | A1 | B68 | B69 |
| 135 | O | A1 | A1 | B69 | B70 | 136 | O | A1 | A1 | B71 | B72 |
| 137 | O | A1 | A1 | B68 | B80 | 138 | O | A1 | A1 | B68 | B83 |
| 139 | S | A1 | A1 | B1 | B6 | 140 | S | A1 | A1 | B2 | B6 |
| 141 | S | A1 | A1 | B25 | B26 | 142 | S | A1 | A1 | B27 | B28 |
| 143 | S | A1 | A1 | B29 | B30 | 144 | S | A1 | A1 | B39 | B40 |
| 145 | S | A1 | A1 | B54 | B41 | 146 | S | A1 | A1 | B54 | B52 |
| 147 | S | A1 | A1 | B52 | B56 | 148 | S | A1 | A1 | B55 | B56 |
| 149 | S | A1 | A1 | B64 | B56 | 150 | S | A1 | A1 | B68 | B69 |
| 151 | S | A1 | A1 | B69 | B70 | 152 | S | A1 | A1 | B71 | B72 |
| 153 | S | A1 | A1 | B68 | B80 | 154 | S | A1 | A1 | B68 | B83 |
| 155 | Se | A1 | A1 | B1 | B6 | 156 | Se | A1 | A1 | B2 | B6 |
| 157 | Se | A1 | A1 | B25 | B26 | 158 | Se | A1 | A1 | B27 | B28 |
| 159 | Se | A1 | A1 | B29 | B30 | 160 | Se | A1 | A1 | B39 | B40 |
| 161 | Se | A1 | A1 | B54 | B41 | 162 | Se | A1 | A1 | B54 | B52 |
| 163 | Se | A1 | A1 | B52 | B56 | 164 | Se | A1 | A1 | B55 | B56 |
| 165 | Se | A1 | A1 | B64 | B56 | 166 | Se | A1 | A1 | B68 | B69 |
| 167 | Se | A1 | A1 | B69 | B70 | 168 | Se | A1 | A1 | B71 | B72 |
| 169 | Se | A1 | A1 | B68 | B80 | 170 | Se | A1 | A1 | B68 | B83 |
| 171 | O | A2 | A2 | B69 | B70 | 172 | O | A2 | A2 | B71 | B72 |
| 173 | S | A2 | A2 | B69 | B70 | 174 | S | A2 | A2 | B71 | B72 |
| 175 | Se | A2 | A2 | B69 | B70 | 176 | Se | A2 | A2 | B71 | B72 |
| 177 | O | A3 | A3 | B70 | B70 | 178 | O | A3 | A3 | B71 | B71 |
| 179 | S | A3 | A3 | B70 | B70 | 180 | S | A3 | A3 | B71 | B71 |
| 181 | Se | A3 | A3 | B70 | B70 | 182 | Se | A3 | A3 | B71 | B71 |
| 177 | O | A4 | A4 | B70 | B70 | 178 | O | A4 | A4 | B71 | B71 |
| 179 | S | A4 | A4 | B70 | B70 | 180 | S | A4 | A4 | B71 | B71 |
| 181 | Se | A4 | A4 | B70 | B70 | 182 | Se | A4 | A4 | B71 | B71 |
| 183 | O | A1 | A1 | B89 | B89 | 184 | O | A1 | A1 | B90 | B90. |

16. The organic electroluminescent device according to claim 1, wherein the first organic layer is a light-emitting layer, the first compound is a phosphorescent material, the second organic layer is a hole injection layer, and the second compound is a hole injection material.

17. The organic electroluminescent device according to claim 1, wherein the device emits blue light.

18. A display assembly, comprising the organic electroluminescent device according to claim 1.
